(19) United States
(12) Patent Application Publication
(10) Pub. No.: US 2026/0192406 A1
(43) Pub. Date: Jul. 9, 2026

(54) MAINTENANCE WORK SYSTEM

(71) Applicant: Tokyo Electron Limited, Tokyo (JP)

(72) Inventors: Satoru TERUUCHI, Miyagi (JP); Jun HIROSE, Miyagi (JP); Dai KITAGAWA, Miyagi (JP); Gaku IKEDA, Tokyo (JP); Takuya MORI, Tokyo (JP); Hyejin KIM, Tokyo (JP)

(21) Appl. No.: 19/560,621

(22) Filed: Mar. 9, 2026

Related U.S. Application Data
(63) Continuation of application No. PCT/JP2024/030937, filed on Aug. 29, 2024.

(30) Foreign Application Priority Data
Sep. 11, 2023 (JP) 2023-146842

(51) Int. Cl. B23Q 7/14; B23Q 7/04; G05B 19/048; H10P 72/76

(52) U.S. Cl. CPC B23Q 7/1436; B23Q 7/046; G05B 19/048; H10P 72/7602

(57) ABSTRACT

In a maintenance work system for a substrate processing plant including a device space in which a substrate processing system is installed, and a travel space in which a work body involved in maintenance work on the substrate processing system travels, the travel space being located above or below the device space, the maintenance work system includes the work body, and a vertical transfer mechanism configured to move the work body up or down between the travel space and the device space, the work body having travelled to a position above and horizontally proximate to the substrate processing system on which the maintenance work is to be performed or a position below and horizontally proximate to the substrate processing system on which the maintenance work is to be performed.

### CROSS-REFERENCE TO RELATED APPLICATIONS

This application is a continuation application of International Application No. PCT/JP 2024/030937, filed on Aug. 29, 2024, and designated the U.S., which is based upon and claims priority to Japanese Patent Application No. 2023-146842, filed on Sep. 11, 2023, the entire contents of which are incorporated herein by reference.

### TECHNICAL FIELD

The disclosures herein relate to maintenance work systems.

### BACKGROUND

Maintenance work (replacement of consumables, cleaning, etc.) of a substrate processing system is currently performed manually by a maintenance worker.

A maintenance work system that substitutes maintenance work for a robot has been developed. In this maintenance work system, it is assumed that the robot autonomously performs maintenance work.

However, even when a robot substitutes maintenance work, there are cases in which work other than maintenance work is performed during maintenance. In such a case, there is a possibility that a worker performing non-maintenance work may enter an area around the robot performing maintenance work or a travel path of the robot toward equipment on which maintenance work is to be performed.

### CITATION LIST

### Patent Literatures

[PTL 1] Japanese Laid-Open Patent Publication No. 2021-136359
[PTL 2] Japanese Laid-Open Patent Publication No. 2020-161827
[PTL 3] International Publication Pamphlet No. WO 2021/178458
[PTL 4] U.S. Patent Application Publication No. 2018/032062
[PTL 5] U.S. Patent Application Publication No. 2020/103756

### SUMMARY OF THE INVENTION

In a maintenance work system for a substrate processing plant including a device space in which a substrate processing system is installed, and a travel space in which a work body involved in maintenance work on the substrate processing system travels, the travel space being located above or below the device space, the maintenance work system includes the work body, and a vertical transfer mechanism configured to move the work body up or down between the travel space and the device space, the work body having travelled to a position above and horizontally proximate to the substrate processing system on which the maintenance work is to be performed or a position below and horizontally proximate to the substrate processing system on which the maintenance work is to be performed.

### BRIEF DESCRIPTION OF THE DRAWINGS

FIG. 1A is a first drawing illustrating a side view of a first substrate processing plant to which a maintenance work system is applied;

FIG. 1B is a second drawing illustrating a side view of the first substrate processing plant to which the maintenance work system is applied;

FIG. 1C is a third drawing illustrating a side view of the first substrate processing plant to which the maintenance work system is applied;

FIG. 1D is a top view illustrating the first substrate processing plant to which the maintenance work system is applied;

FIG. 2A is a first drawing illustrating a side view of a second substrate processing plant to which the maintenance work system is applied;

FIG. 2B is a second drawing illustrating a side view of the second substrate processing plant to which the maintenance work system is applied;

FIG. 2C is a top view illustrating the second substrate processing plant to which the maintenance work system is applied;

FIG. 3A is a first drawing illustrating an example of a layout of a device space;

FIG. 3B is a second drawing illustrating an example of the layout of the device space;

FIG. 4 is a drawing illustrating an example of a system configuration of the maintenance work system;

FIG. 5 is a drawing illustrating an example of mode transition of the substrate processing system in the maintenance work system;

FIG. 6 is a drawing illustrating an example of a functional configuration of a management system;

FIG. 7 is a drawing illustrating an example of a hardware configuration of the management system;

FIG. 8A is a first drawing illustrating an example of an operation of a travel mechanism or the like in a maintenance mode;

FIG. 8B is a second drawing illustrating an example of the operation of the travel mechanism or the like in the maintenance mode;

FIG. 8C is a third drawing illustrating an example of the operation of the travel mechanism or the like in the maintenance mode;

FIG. 9A is a fourth drawing illustrating an example of the operation of the travel mechanism or the like in the maintenance mode;

FIG. 9B is a fifth drawing illustrating an example of the operation of the travel mechanism or the like in the maintenance mode;

FIG. 9C is a sixth drawing illustrating an example of the operation of the travel mechanism or the like in the maintenance mode;

FIG. 10A is a first drawing illustrating an example of an operation of a travel mechanism or the like in an independent maintenance mode;

FIG. 10B is a second drawing illustrating an example of the operation of the travel mechanism or the like in the independent maintenance mode;

FIG. 10C is a third drawing illustrating an example of the operation of the travel mechanism or the like in the independent maintenance mode;

FIG. 11 is a drawing illustrating an example of an operation of a travel mechanism in a normal mode;

FIG. 12A is a first drawing illustrating an example of an operation of a vertical transfer mechanism or the like in the independent maintenance mode;

FIG. 12B is a second drawing illustrating an example of the operation of the vertical transfer mechanism or the like in the independent maintenance mode;

FIG. 12C is a third drawing illustrating an example of the operation of the vertical transfer mechanism or the like in the independent maintenance mode;

FIG. 12D is a fourth drawing illustrating an example of the operation of the vertical transfer mechanism or the like in the independent maintenance mode;

FIG. 13A is a first drawing illustrating an example of an operation of the vertical transfer mechanism in the maintenance mode;

FIG. 13B is a second drawing illustrating an example of an operation of the vertical transfer mechanism in the maintenance mode;

FIG. 14A is a first drawing illustrating an example of an operation of a crane mechanism in the maintenance mode;

FIG. 14B is a second drawing illustrating an example of the operation of the crane mechanism in the maintenance mode;

FIG. 14C is a third drawing illustrating an example of the operation of the crane mechanism in the maintenance mode;

FIG. 14D is a fourth drawing illustrating an example of the operation of the crane mechanism in the maintenance mode;

FIG. 15 is a sequence diagram illustrating a flow of processing related to maintenance work in the normal mode of the maintenance work system;

FIG. 16 is a sequence diagram illustrating a flow of processing related to maintenance work in the independent maintenance mode of the maintenance work system;

FIG. 17A is a first sequence diagram illustrating a flow of processing related to maintenance work in the maintenance mode of the maintenance work system;

FIG. 17B is a second sequence diagram illustrating the flow of processing related to the maintenance work in the maintenance mode of the maintenance work system;

FIG. 17C is a third sequence diagram illustrating the flow of processing related to the maintenance work in the maintenance mode of the maintenance work system;

FIG. 18A is a first drawing illustrating an outline of a replacement unit;

FIG. 18B is a second drawing illustrating the outline of the replacement unit;

FIG. 19 is a drawing illustrating an example of a functional configuration of the replacement unit;

FIG. 20A is a flowchart illustrating a flow of separation processing of the replacement unit in the independent maintenance mode;

FIG. 20B is a flowchart illustrating a flow of coupling processing of the replacement unit in the independent maintenance mode;

FIG. 21A is a first drawing illustrating details of a work robot;

FIG. 21B is a second drawing illustrating details of the work robot;

FIG. 22 is a drawing illustrating an example of a functional configuration of the work robot;

FIG. 23A is a first flowchart illustrating a flow of movement processing of the work robot in the maintenance mode;

FIG. 23B is a second flowchart illustrating a flow of the movement processing of the work robot in the maintenance mode;

FIG. 24A is a third flowchart illustrating a flow of the movement processing of the work robot in the maintenance mode;

FIG. 24B is a fourth flowchart illustrating a flow of the movement processing of the work robot in the maintenance mode;

FIG. 25 is a flowchart illustrating a flow of maintenance work processing of the work robot in the maintenance mode;

FIG. 26 is a drawing illustrating an example of a functional configuration of an inspection robot;

FIG. 27 is a flowchart illustrating a flow of inspection processing of the inspection robot in the normal mode; and

FIG. 28 is a drawing illustrating an example of a hardware configuration of a control device.

### DESCRIPTION OF THE PREFERRED EMBODIMENTS

In the following, embodiments of the present invention will be described with reference to the accompanying drawings. In the drawings, the same or corresponding constituent elements are denoted with the same reference numerals, and redundant description thereabout may be omitted.

### First Embodiment

### <Application Example of Maintenance Work System>

First, an application example of the maintenance work system according to the first embodiment will be described.

### (1) Description of First Substrate Processing Plant Part 1

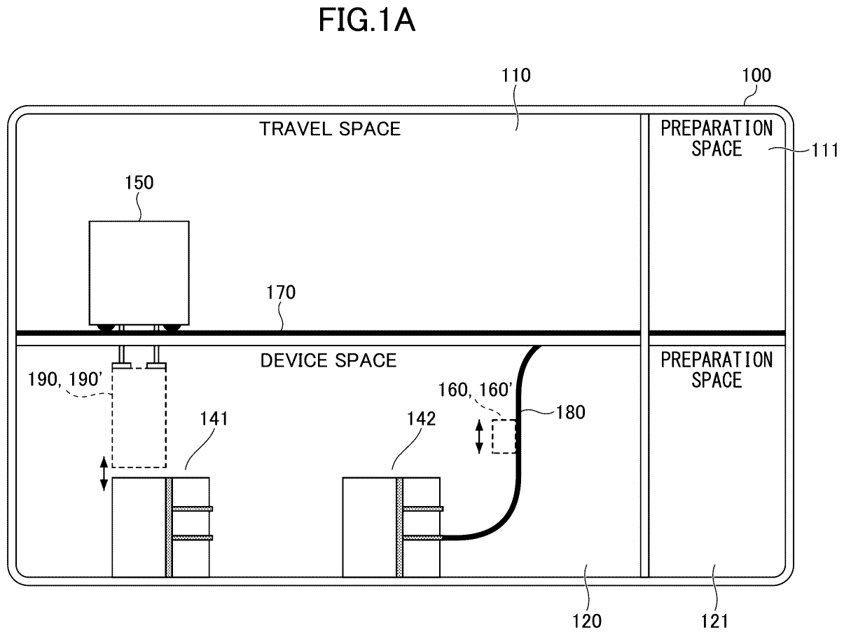

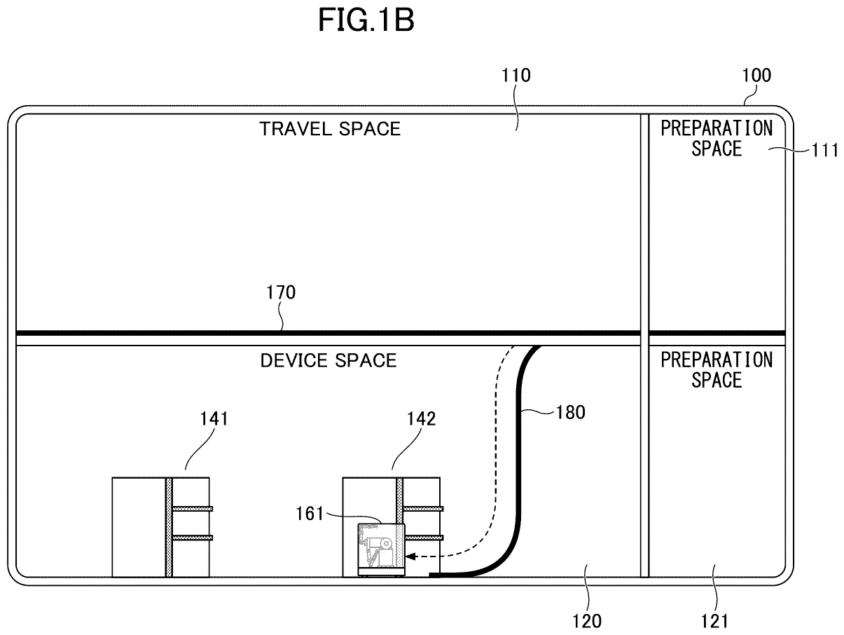

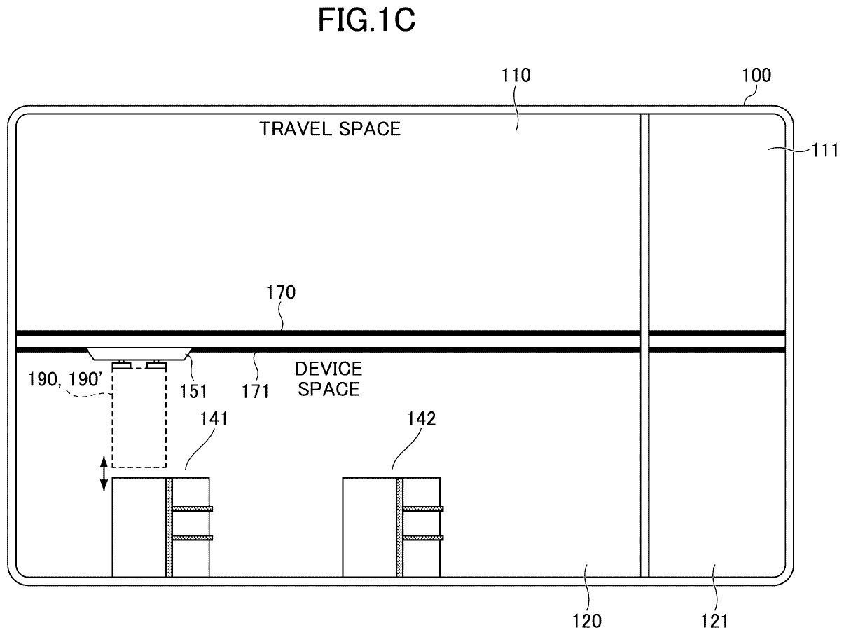

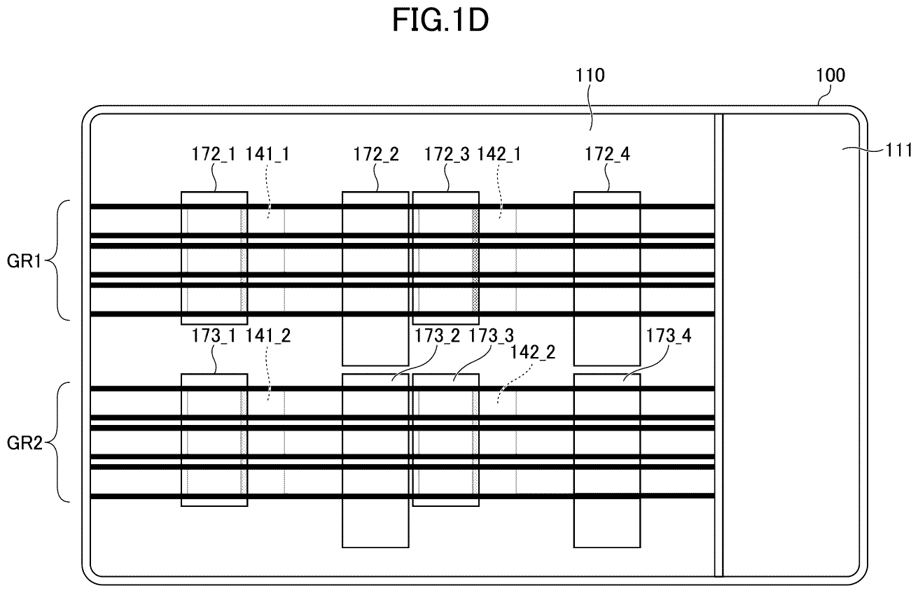

FIG. 1A is a first drawing illustrating a side view of a first substrate processing plant to which the maintenance work system is applied.

As shown in FIG. 1A, the first substrate processing plant 100 to which the maintenance work system according to the first embodiment is applied has two spaces above and below. Specifically, the first substrate processing plant 100 has a travel space 110 above and a device space 120 below. A part of the travel space 110 above may be used as a preparation space 111, and a part of the device space 120 below may be used as a preparation space 121.

The device space 120 is a space in which substrate processing systems 141, 142, and the like are installed. The travel space 110 is a space in which a work body involved in maintenance work of the substrate processing systems 141, 142, and the like travels on a rail 170.

In the first embodiment, the work body involved in maintenance work includes:
a “replacement unit” that is replaced with a part of the substrate processing systems 141, 142, and the like;
a “work robot” that performs maintenance work on the substrate processing systems 141, 142, and the like, or assists in attaching the unit to the substrate processing systems 141, 142, and the like; or removing the unit from the substrate processing systems 141, 142, and the like;
an “inspection robot” that inspects the rail 170 laid in the travel space 110; and
a “vertical transfer robot” that moves units up and down from an upper position in a vertical direction to replace some of the units of the substrate processing systems 141, 142, and the like.

In an example of FIG. 1A, replacement units 160 and 160′ and a vertical transfer robot 150 among the replacement units, the work robot, the inspection robot, and the vertical transfer robot included in the work body are in operation.

The replacement unit 160 is a detachable unit disposed at any one of stages of the substrate processing system 142. In the example shown in FIG. 1A, the substrate processing system 142 has three stages, and the detachable unit is disposed at a middle stage. When separated from the substrate processing system 142 during maintenance, the replacement unit 160 autonomously travels to the travel space 110 via the vertical transfer rail 180, and further autonomously travels on the rail 170 in the travel space 110 to reach the preparation space 111. In the substrate processing system 142, the replacement unit 160 may be, for example, a unit detachable on a chamber basis, a unit detachable on an equipment basis, or a unit detachable on a part basis.

A new replacement unit 160′ is prepared in advance in the preparation space 111, and the new replacement unit 160′ autonomously travels on the rail 170 in the travel space 110 and then moves down to the device space 120 via the vertical transfer rail 180. Thus, the new replacement unit 160′ is coupled to the position where the replacement unit 160 was coupled in the substrate processing system 142.

The vertical transfer robot 150 is a robot configured to move up and down detachable units from an upper position in the vertical direction among units detachably disposed in a substrate processing system. In the example shown in FIG. 1A, a substrate processing system is the substrate processing system 141 and detachable units are units 190, 190′. The vertical transfer robot 150 autonomously travels on the rail 170 in the travel space 110 to the upper position in the vertical direction of the unit 190 during maintenance. The vertical transfer robot 150 also moves up the detachable unit 190 to the upper position in the vertical direction in the travel space 110 and autonomously travels on a rail 170 in the travel space 110 to convey the unit 190 to the preparation space 111.

A new unit 190′ is prepared in advance in the preparation space 111, and the vertical transfer robot 150 autonomously travels on a rail 170 in the travel space 110 to convey the new unit 190′ to the upper position in the vertical direction of the substrate processing system 141. The vertical transfer robot 150 moves the new unit 190′ down toward the substrate processing system 141 and attaches the new unit 190′ to the substrate processing system 141.

Alternatively, a work robot (not shown) for performing maintenance work on the conveyed unit 190 may stand by in the preparation space 111, and the work robot may perform maintenance work on the unit 190 in the preparation space 111. In this case, the vertical transfer robot 150 autonomously travels on the rail 170 in the travel space 110 to convey the unit 190 on which the maintenance work has been performed to the upper position in the vertical direction of the substrate processing system 141. The vertical transfer robot 150 moves down the unit 190 to which the maintenance work has been performed toward the substrate processing system 141 and attaches the unit 190 to the substrate processing system 141.

### (2) Description of the First Substrate Processing Plant Part 2

FIG. 1B is a second drawing illustrating a side view of the first substrate processing plant to which the maintenance work system is applied.

In an example of FIG. 1B, the work robot 161 from among the replacement unit, the work robot, the inspection robot, and the vertical transfer robot included in the work body is in operation.

The work robot 161 is a robot that performs maintenance work on a substrate processing system. In the example of FIG. 1B, a substrate processing system is the substrate processing system 142. The work robot 161 autonomously travels on the rail 170 in the travel space 110 and then moves down to the device space 120 via the vertical transfer rail 180. Thus, the work robot 161 autonomously travels to the position of the substrate processing system 142 in the device space 120 and performs maintenance work on the substrate processing system 142. When the maintenance work is completed, the work robot 161 autonomously travels in the device space 120, autonomously travels to the travel space 110 via the vertical transfer rail 180, and further autonomously travels on the rail 170 in the travel space 110 to return to the preparation space 111.

Alternatively, the work robot 161 may assist the vertical transfer robot 150 in attaching a unit to or removing a unit from the substrate processing system (e.g., substrate processing system 141 of FIG. 1A).

### (3) Description of the First Substrate Processing Plant Part 3

FIG. 1C is a third drawing illustrating a side view of the first substrate processing plant to which the maintenance work system is applied.

In the example of FIG. 1C, the crane mechanism 151 is disposed on a ceiling of the device space 120.

The crane mechanism 151 is a robot that moves a detachable unit up and down from an upper position in a vertical direction among detachable units disposed in the substrate processing system, similar to the vertical transfer robot 150. In the example of FIG. 1C, a substrate processing system is the substrate processing system 141. Specifically, in the example of FIG. 1C, the robot moves the units 190 and 190′ up and down. During maintenance, the crane mechanism 151 travels on a rail 171 in the device space 120 to the upper position in the vertical direction of the unit 190. The crane mechanism 151 moves the detachable unit 190 up from the upper position in the vertical direction and conveys the unit 190 to the preparation space 121 by traveling on the rail 171 in the device space 120.

A new unit 190′ is prepared in advance in the preparation space 121, and the crane mechanism 151 conveys the new unit 190′ to the upper position in the vertical direction of the substrate processing system 141 by traveling on the rail 171 in the device space 120. The crane mechanism 151 moves the new unit 190′ down toward the substrate processing system 141 and attaches the new unit 190′ to the substrate processing system 141.

Alternatively, a work robot (not shown) for performing maintenance work on the conveyed unit 190 may stand by in the preparation space 121, and the work robot may perform maintenance work on the unit 190 in the preparation space 121. In this case, the crane mechanism 151 conveys the unit 190 on which the maintenance work has been performed to the upper position in the vertical direction of the substrate processing system 141 in the vertical direction by traveling on the rail 171 in the device space 120. The crane mechanism 151 moves the unit 190 on which the maintenance work has been performed down toward the substrate processing system 141 and attaches the unit 190 to the substrate processing system 141.

The work robot 161 may assist in removing the unit 190 from the substrate processing system 141 and attaching the new unit 190′ (or the unit 190 on which maintenance work has been performed) to the substrate processing system 141.

### (4) Description of the First Substrate Processing Plant Part 4

FIG. 1D is a top view illustrating the first substrate processing plant to which the maintenance work system is applied and mainly illustrates rails laid in the travel space 110 and a lid opening a floor of the travel space 110. In FIG. 1D, the substrate processing systems 141_1, 142_1, 141_2, and 142_2 are also shown so that a positional relationship with the substrate processing systems in the device space 120 can be understood.

As shown in the example of FIG. 1D, a rail group GR1 is disposed above the substrate processing systems 141_1 and 142_1 in the travel space 110 along the arrangement direction of the substrate processing systems 141_1 and 142_1. Similarly, a rail group GR2 is disposed above the substrate processing systems 141_2 and 142_2 in the travel space 110 along the arrangement direction of the substrate processing systems 142_1 and 142_2.

The rail group GR1 includes three sets of rails for allowing the replacement unit, the work robot, and the inspection robot to autonomously travel in the travel space 110. The number of sets of rails included in the rail group GR1 may be determined, for example, according to the number of replacement units (the number of replacement units in the width direction) of the substrate processing systems 141_1 and 142_1 arranged at corresponding positions in the device space 120. In the present embodiment, since the substrate processing systems 141_1 and 142_1 each have three replacement units in the width direction, the rail group GR1 includes three sets of rails.

Positions of the three sets of rails are changed by a changing mechanism (not shown). The changing mechanism changes the positions of the rails according to, for example, the positions at which the work robot moves up and down. The changing mechanism also changes the positions of the rails according to, for example, sizes of the vertical transfer robot, the replacement unit, the work robot, and the inspection robot that autonomously travel.

Similarly, the rail group GR2 includes three sets of rails for allowing the replacement unit, the work robot, and the inspection robot to autonomously travel in the travel space 110. The number of sets of rails included in the rail group GR2 may be determined, for example, according to the number of replacement units (the number of replacement units in the width direction) of the substrate processing systems 141_2 and 142_2 arranged at corresponding positions in the device space 120. In the present embodiment, since the substrate processing systems 141_2 and 142_2 each have three replacement units in the width direction, the rail group GR2 includes three sets of rails.

The positions of the three sets of rails are changed by the changing mechanism (not shown). The changing mechanism changes the positions of the rails in accordance with, for example, the position at which the work robot moves up and down. The changing mechanism also changes the positions of the rails in accordance with, for example, the sizes of the vertical transfer robot, the replacement unit, the work robot, and the inspection robot that travel autonomously.

Note that in the example of FIG. 1D, the rails included in the rail group GR1 and the rails included in the rail group GR2 are shown as linear rails. However, the rails included in the rail group GR1 and the rails included in the rail group GR2 are not limited to linear rails and may include rails other than linear rails.

As shown in the example of FIG. 1D, lids 172_1, 172_2, 172_3, and 172_4 for opening the floor are disposed in the travel space 110.

The lids 172_1 and 172_3 operate when the vertical transfer robot 150 moves detachable units up and down, which are detachably provided in substrate processing systems 141_1 and 142_1, respectively, and are detachable from an upper position in a vertical direction.

The lids 172_2 and 172_4 operate when the replacement units which are attached to and detached from the substrate processing systems 141_1 and 142_1 move up and down between the travel space 110 and the device space 120. Alternatively, the lids 172_2 and 172_4 operate when the work robot moves up and down between the travel space 110 and the device space 120.

Similarly, as shown in the example of FIG. 1D, the travel space 110 is provided with lids 173_1, 173_2, 173_3 and 173_4 which open the floor.

The lids 173_1 and 173_3 operate when the vertical transfer robot 150 moves detachable units up and down, which are detachably provided in substrate processing systems 141_2 and 142_2, respectively, and are detachable from an upper position in a vertical direction.

The lids 173_2 and 173_4 operate when the replacement units which are attached to and detached from the substrate processing systems 141_2 and 142_2 move up and down between the travel space 110 and the device space 120. Alternatively, the lids 173_2 and 173_4 operate when the work robot moves up and down between the travel space 110 and the device space 120.

### (5) Description of Second Substrate Processing Plant Part 1

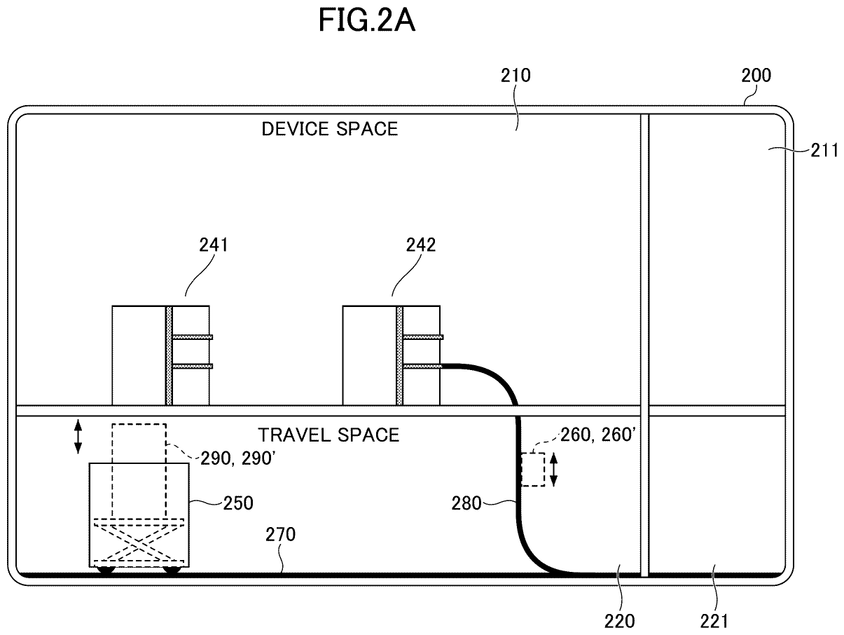

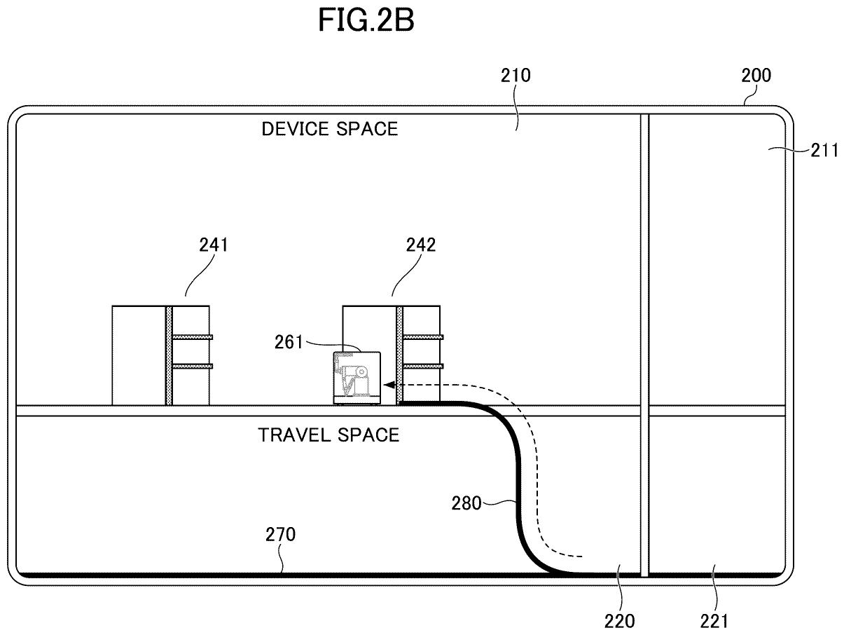

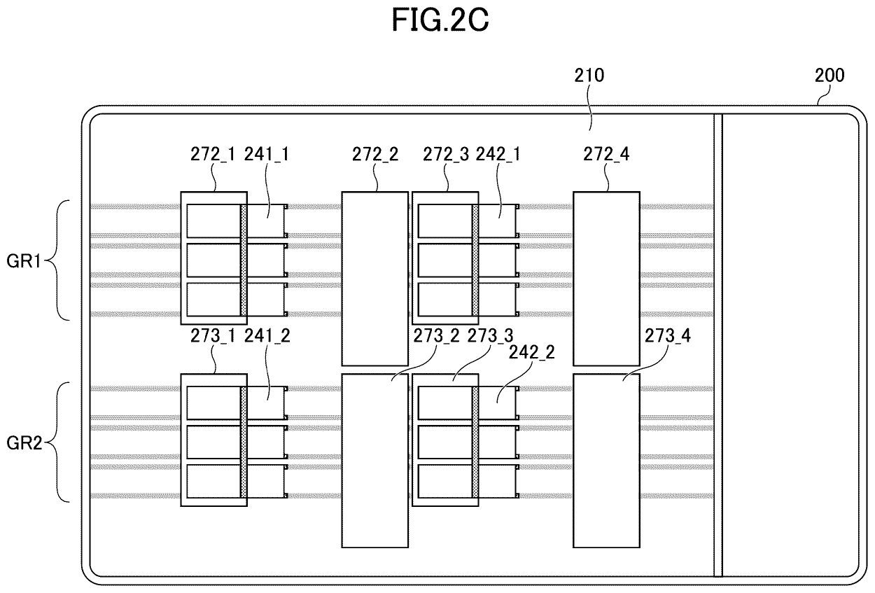

FIG. 2A is a first drawing illustrating a side view of a second substrate processing plant to which the maintenance work system is applied.

As shown in FIG. 2A, the second substrate processing plant 200 to which the maintenance work system according to the first embodiment is applied has two spaces above and below. Specifically, the second substrate processing plant 200 has a device space 210 above and a travel space 220 below. A part of the device space 210 above may be used as a preparation space 211, and a part of the travel space 220 below may be used as a preparation space 221.

The device space 210 is a space in which the substrate processing systems 241, 242, and the like are installed. The travel space 220 is a space in which a work body involved in the maintenance work of the substrate processing systems 241, 242, and the like travels on a rail 270.

The work body involved in the maintenance work in the maintenance work system applied to the second substrate processing plant 200 is substantially the same as the work body involved in the maintenance work in the maintenance work system applied to the first substrate processing plant 100. Therefore, differences will be mainly described here.

The example of FIG. 2A shows an example of the replacement units 260, 260′ and the vertical transfer robot 250 among the replacement units, the work robot, the inspection robot, and the vertical transfer robot included in the work body.

The replacement unit 260, when separated from the substrate processing system 242 during maintenance, autonomously travels to the travel space 220 via a vertical transfer rail 280, and further autonomously travels on the rail 270 in the travel space 220 to the preparation space 221.

A new replacement unit 260′ is prepared in advance in the preparation space 221, and the new replacement unit 260′ autonomously travels on the rail 270 in the travel space 220 and then moves down to the device space 210 via the vertical transfer rail 280. Thus, the new replacement unit 260′ is coupled to the position where the replacement unit 260 was coupled in the substrate processing system 242.

The vertical transfer robot 250 is a robot configured to vertically move detachable units up and down from a lower position in the vertical direction among units detachably disposed in a substrate processing system. In the example shown in FIG. 2A, a substrate processing system is the substrate processing system 241 and detachable units are units 290 and 290′. The vertical transfer robot 250 autonomously travels on the rail 270 in the travel space 220 to the lower position in the vertical direction of the unit 290 during maintenance. The vertical transfer robot 250 also moves the detachable unit 290 down to the lower position in the vertical direction in the travel space 220 and autonomously travels on the rail 270 in the travel space 220 to convey the unit 290 to the preparation space 221.

A new unit 290′ is prepared in advance in the preparation space 221, and the vertical transfer robot 250 autonomously travels on the rail 270 in the travel space 220 to convey the new unit 290′ to the lower position in the vertical direction of the substrate processing system 241. The vertical transfer robot 250 moves the new unit 290′ down toward the substrate processing system 241 and attaches the new unit 290′ to the substrate processing system 241.

Alternatively, a work robot (not shown) for performing maintenance work on the conveyed unit 290 may stand by in the preparation space 221, and the work robot may perform maintenance work on the unit 290 in the preparation space 221. In this case, the vertical transfer robot 250 autonomously travels on the rail 270 in the travel space 220 to convey the unit 290 on which the maintenance work has been performed to the lower position in the vertical direction of the substrate processing system 241. Additionally, the vertical transfer robot 250 raises the unit 290 to which the maintenance work has been performed toward the substrate processing system 241 and attaches it to the substrate processing system 241.

Although not shown in FIG. 2A, it is assumed that the vertical transfer robot 250 may interfere with an ancillary equipment of the substrate processing system 241 when moving the units 290 and 290′ up and down. Alternatively, it is assumed that the replacement units 260 and 260′ may interfere with the ancillary equipment of the substrate processing system 242 when moving up and down via the vertical transfer rail 280.

The maintenance work system according to the first embodiment may include a retracting mechanism for retracting the ancillary equipment of the substrate processing system 241 or 242, for example, in the horizontal direction. The retracting position of the ancillary equipment by the retracting mechanism may be determined, for example, according to the size of the vertical transfer robot 250 or the sizes of the replacement units 260 and 260′.

### (6) Description of the Second Substrate Processing Plant Part 2

FIG. 2B is a second drawing illustrating a side view of the second substrate processing plant to which the maintenance work system is applied.

In an example of FIG. 2B, the work robot 261, from among the replacement unit, the work robot, the inspection robot, and the vertical transfer robot included in the work body, is in operation.

The work robot 261 is a robot that performs maintenance work on a substrate processing system. In the example of FIG. 2B, a substrate processing system is the substrate processing system 242. The work robot 261 autonomously travels on the rail 270 in the travel space 220 and then moves up to the device space 210 via the vertical transfer rail 280. Thus, the work robot 261 autonomously travels to the position of the substrate processing system 242 in the device space 210 and performs maintenance work on the substrate processing system 242. When the maintenance work is completed, the work robot 261 autonomously travels in the device space 210, autonomously travels to the travel space 220 via the vertical transfer rail 280, and further autonomously travels on the rail 270 in the travel space 220 to return to the preparation space 221.

Alternatively, the work robot 261 may assist the vertical transfer robot 250 in attaching a unit to or removing a unit from the substrate processing system (e.g., substrate processing system 241 of FIG. 2A).

### (7) Description of the Second Substrate Processing Plant Part 3

FIG. 2C is a top view illustrating the second substrate processing plant to which the maintenance work system is applied and mainly illustrates lids for opening the device space 210 and rails laid in the travel space 220. In FIG. 2C, the substrate processing systems 241_1, 242_1, 241_2, and 242_2 are also shown so that the positional relationship between the lids and the rails can be understood.

As shown in the example of FIG. 2C, a rail group GR1 is disposed above the substrate processing systems 241_1 and 242_1 in the travel space 220 along the arrangement direction of the substrate processing systems 241_1 and 242_1. Similarly, a rail group GR2 is disposed above the substrate processing systems 241_2 and 242_2 in the travel space 220 along the arrangement direction of the substrate processing systems 241_2 and 242_2.

Since the details of the rail groups GR1 and GR2 have already been described with reference to FIG. 1D, a description thereof is omitted here.

As shown in the example of FIG. 2C, the device space 210 is provided with lids 272_1, 272_2, 272_3, and 272_4 for opening the floor.

The lids 272_1 and 272_3 operate when the vertical transfer robot 250 moves detachable units up and down, which are detachably provided in substrate processing systems 241_1 and 242_1, respectively, and are detachable from a lower position in a vertical direction.

The lids 272_2 and 272_4 operate when the replacement units which are attached to and detached from the substrate processing systems 241_1 and 242_1 move up and down between the device space 210 and the travel space 220. Alternatively, the lids 272_2 and 272_4 operate when the work robot moves up and down between the device space 210 and the travel space 220.

Similarly, as shown in the example of FIG. 2C, the device space 210 is provided with lids 273_1, 273_2, 273_3, and 273_4 which open a floor.

The lids 273_1 and 273_3 operate when the vertical transfer robot 250 moves detachable units up and down, which are detachably provided in substrate processing systems 241_2 and 242_2, respectively, and are detachable from a lower position in a vertical direction.

The lids 273_2 and 273_4 operate when the replacement units which are attached to and detached from the substrate processing systems 241_2 and 242_2 move up and down between the device space 210 and the travel space 220. Alternatively, the lids 273_2 and 273_4 operate when the work robot moves up and down between the device space 210 and the travel space 220.

### <Layout Inside Device Space>

Next, a layout (mechanisms installed in the device space mainly for travel of the work robot) inside the device space will be described. Hereinafter, a case where the maintenance work system is applied to the first substrate processing plant 100 will be mainly described, but a case where the maintenance work system is applied to the second substrate processing plant 200 will also be described.

(1) Layout inside the Device Space Part 1

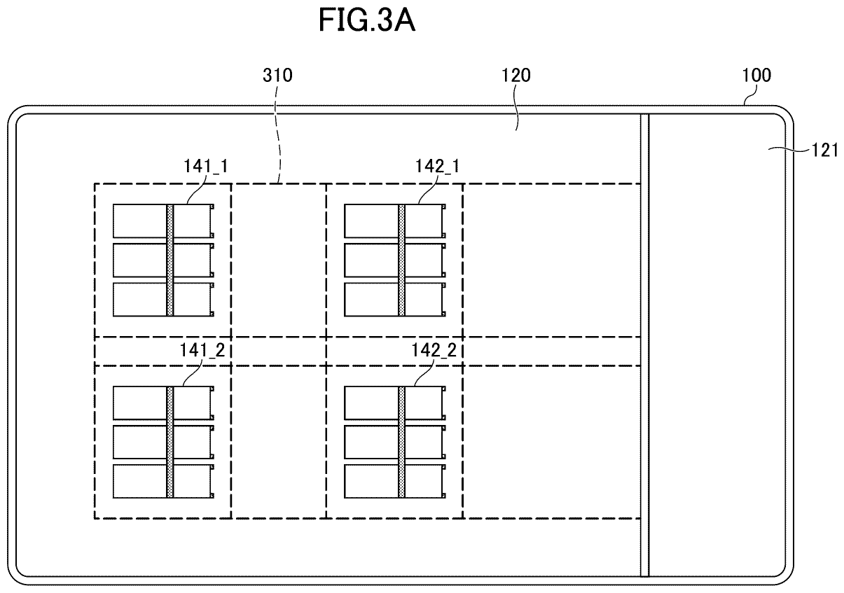

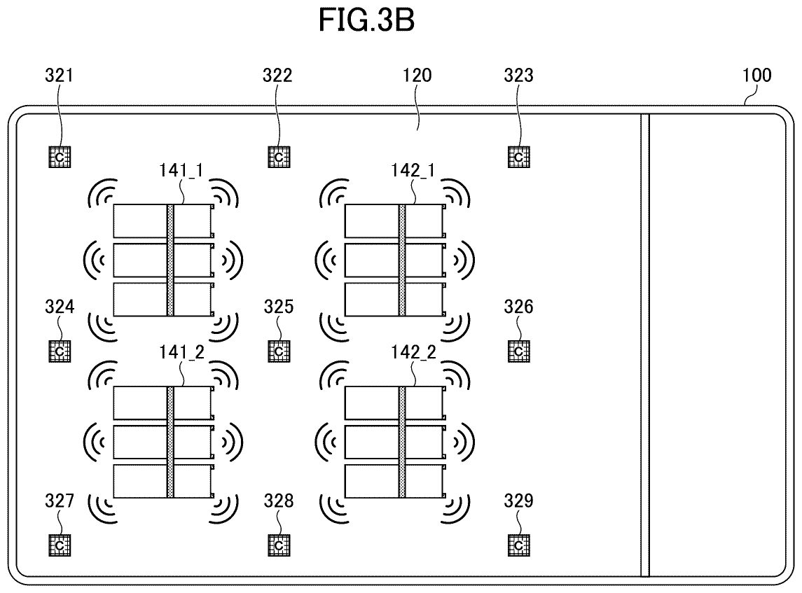

FIG. 3A is a first drawing illustrating an example of a layout of a device space and illustrating the inside of the device space 120 as seen from the top. As shown in FIG. 3A, a light emitting unit 310 is installed on the floor of the device space 120.

When the work robot travels in the device space 120, the light emitting unit 310 is turned on to guide the work robot to a predetermined travel path. A plurality of the light emitting units 310 are installed at predetermined intervals along a travel path on the outer periphery of the substrate processing systems 141_1, 142_1, 141_2, and 142_2. A plurality of the light emitting units 310 are installed at predetermined intervals along a travel path extending from the substrate processing systems 141_1, 142_1, 141_2, and 142_2.

### (2) Layout Inside the Device Space Part 2

FIG. 3B is a second drawing illustrating an example of the layout of the device space and illustrating the inside of the device space 120 as seen from the top. Instead of installing the light emitting units 310 on the floor of the device space 120, as shown in FIG. 3B, markers 321 to 329 are installed on the ceiling of the device space 120.

The markers 321 to 329 are photographed by the work robot when the work robot autonomously travels in the device space 120. The positional coordinates in the device space 120 where the markers 321 to 329 are installed are previously recognized by the work robot, and the work robot analyzes image data obtained by capturing images of one or more of the markers 321 to 329. Thus, the work robot calculates the current position in the device space 120 during autonomous travel.

In addition, although the example of FIG. 3B shows a case where the markers 321 to 329 are installed at a vertex of a rectangular region surrounding the substrate processing systems 141_1, 142_1, 141_2, and 142_2, the installation position of the marker 321 to 329 is not limited to this.

The method for calculating the current position in the device space 120 during autonomous travel of the work robot is not limited to this. For example, a transmitter may be installed in each unit of the substrate processing systems 141_1, 142_1, 141_2, and 142_2.

The position coordinates of the installed transmitter in the device space 120 are recognized in advance by the work robot, and the work robot calculates the current position in the device space 120 during autonomous travel by analyzing signals from any one or a plurality of transmitters.

### <System Configuration of Maintenance Work System>

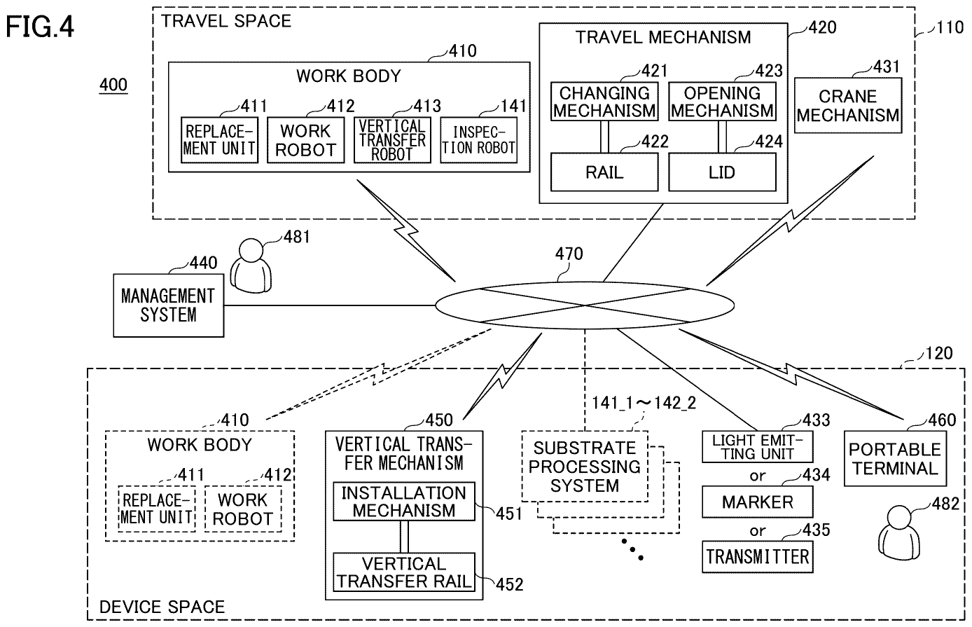

Next, a system configuration of the maintenance work system according to the first embodiment will be described. FIG. 4 is a drawing illustrating an example of the system configuration of the maintenance work system.

As shown in FIG. 4, a maintenance work system 400 according to the first embodiment includes:
a work body 410;
a travel mechanism 420;
a crane mechanism 431;
a management system 440;
a vertical transfer mechanism 450;
a light emitting unit 433, a marker 434, or a transmitter 435; and
a portable terminal 460.

In the maintenance work system 400, the management system 440 is communicably connected to the work body 410, the travel mechanism 420, the crane mechanism 431, the vertical transfer mechanism 450, the light emitting unit 433, and the portable terminal 460 via a network 470.

Further, the management system 440 is communicably connected to the substrate processing systems 141_1 to 142_2 on which the maintenance work is performed by the maintenance work system 400, via the network 470.

Of the work body 410, at least the replacement unit 411, the work robot 412, and the vertical transfer robot 413 are connected to the substrate processing systems 141_1 to 142_2 by short-range wireless communication.

Of elements provided in the maintenance work system 400 shown in FIG. 4, the elements already described in the application examples shown in FIGS. 1A to 3B will be described in correspondence with those in FIG. 4 and will not be described here.

As shown in FIG. 4, the work body 410 includes the replacement unit 411, the work robot 412, the vertical transfer robot 413, and the inspection robot 414.

Among them, a specific example of the replacement unit 411 included in the work body 410 shown in FIG. 4 is the replacement unit 160 shown in FIG. 1A, and a specific example of the work robot 412 included in the work body 410 shown in FIG. 4 is the work robot 161 shown in FIG. 1B.

A specific example of the vertical transfer robot 413 included in the work body 410 shown in FIG. 4 is the vertical transfer robot 150 shown in FIG. 1A.

As shown in FIG. 4, the travel mechanism 420 includes a changing mechanism 421, a rail 422, an opening mechanism 423, and a lid 424.

The changing mechanism 421 changes the position of the rail 422. Specific examples of the rail 422 are the rail 170 in FIG. 1A or the rail groups GR1 and GR2 shown in FIG. 1D.

The opening mechanism 423 opens and closes the floor of the travel space 110 by changing the position among the lids 424. Specific examples among the lids 424 are the lids 172_1 to 173_4 in FIG. 1D.

A specific example of the crane mechanism 431 in FIG. 4 is the crane mechanism 151 shown in FIG. 1C.

As shown in FIG. 4, the vertical transfer mechanism 450 has an installation mechanism 451 and a vertical transfer rail 452. An installation mechanism 451 installs the vertical transfer rail 452 at a predetermined position. A specific example of the vertical transfer rail 452 is the vertical transfer rail 180 shown in FIG. 1B.

A specific example of the light emitting unit 433 or the marker 434 in FIG. 4 is the light emitting unit 310 in FIG. 3A or the marker 321 to 329 in FIG. 3B.

The management system 440 acquires information from the work body 410, the travel mechanism 420, and the crane mechanism 431 in order to achieve maintenance work for the substrate processing systems 141_1 to 142_2. The management system 440 acquires information from the vertical transfer mechanism 450, the substrate processing systems 141_1 to 142_2, and the portable terminal 460 in order to achieve maintenance work for the substrate processing systems 141_1 to 142_2. The management system 440 issues various instructions, monitored by an administrator 481, to the work body 410, the travel mechanism 420, the crane mechanism 431, the vertical transfer mechanism 450, the substrate processing systems 141_1 to 142_2, the light emitting unit 433, and the portable terminal 460 based on acquired information.

The portable terminal 460 is a portable terminal held by a worker 482 (an example of an apparatus administrator who administers the substrate processing systems 141_1 to 142_ 2) performing a predetermined work in the device space 120. Here, the portable terminal 460 includes any portable information terminal. The portable information terminal includes, for example, a notebook PC (Personal Computer), a tablet terminal, a smartphone, a smartwatch, and an HMD (Head Mounted Display).

### <Mode in Maintenance Work System>

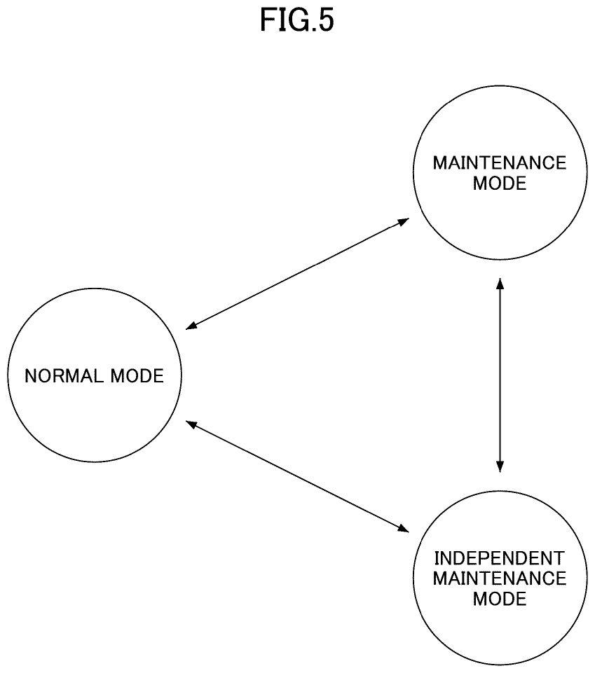

Next, mode transition in the maintenance work system 400 will be described. FIG. 5 is a drawing illustrating an example of mode transition of the substrate processing system in the maintenance work system. As shown in FIG. 5, the substrate processing systems 141_1 to 142_2 execute respective processes under any of the modes while making mode transition among a normal mode, a maintenance mode, and an independent maintenance mode.

The normal mode indicates a state in which the substrate processing systems 141_1 to 142_2 normally perform substrate processing. In a normal mode, the maintenance work system 400 acquires information for determining the necessity of maintenance work from the substrate processing systems 141_1 to 142_2. When determining that maintenance work is necessary, the maintenance work system 400 determines, as a maintenance schedule, such as:
a substrate processing system and a unit on which maintenance work is to be performed;
maintenance task; and
maintenance work timing.

In the maintenance mode, substrate processing performed by any one or more substrate processing systems among the substrate processing systems 141_1 to 142_2 is stopped, and maintenance work is performed on the substrate processing systems in which the substrate processing is stopped.

In the independent maintenance mode, substrate processing performed by any one of the substrate processing systems 141_1 to 142_2 is temporarily stopped, and maintenance work is performed.

### <Example of Functional Configuration of Management System>

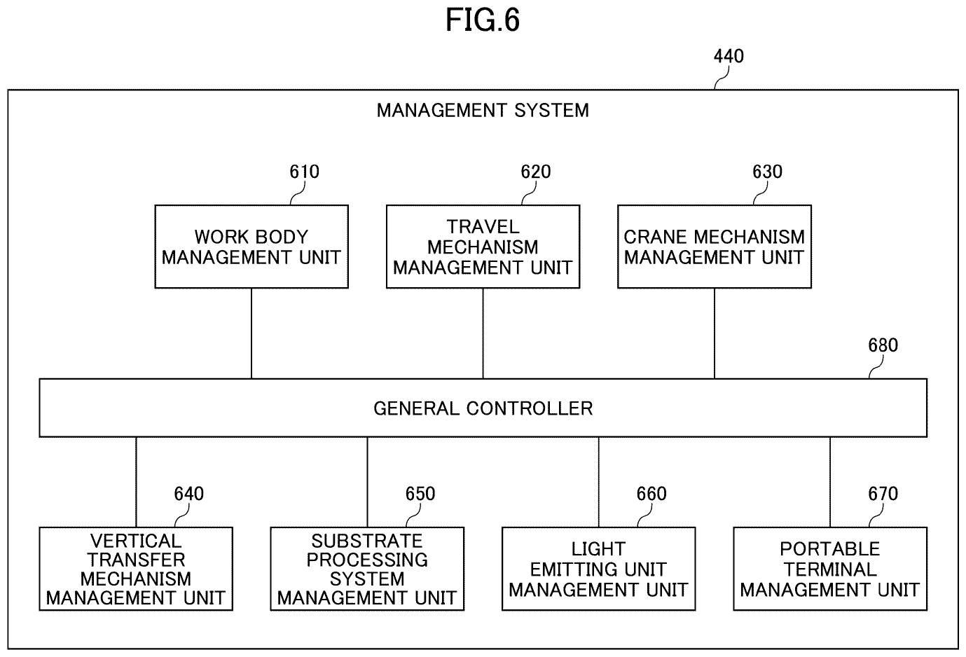

Next, the functional configuration of the management system 440 will be described. FIG. 6 is a drawing illustrating an example of a functional configuration of a management system. A management program is installed in the management system 440. When the program is executed, the management system 440 functions as a work body management unit 610, a travel mechanism management unit 620, and a crane mechanism management unit 630. When the program is executed, the management system 440 functions as a vertical transfer mechanism management unit 640, a substrate processing system management unit 650, a light emitting unit management unit 660, and a portable terminal management unit 670.

The work body management unit 610 manages the operation of the work body 410. Specifically, the work body management unit 610 transmits instructions corresponding to a task to one of the work bodies 410 at a predetermined timing regarding:
maintenance work in the maintenance mode or the independent maintenance mode; or
inspection work in the normal mode.
The instructions corresponding to the task include information based on a maintenance schedule, such as:
information for determining a substrate processing system and a unit on which inspection work is to be performed;
information for determining a rail on which inspection work is to be performed;
travel paths to a unit on which maintenance work is to be performed (outward and inward paths);
a travel path when inspecting the rail on which inspection work is to be performed;
a procedure of maintenance work for the unit on which maintenance work is to be performed; and
a procedure of inspection work for the rail on which maintenance work is to be performed.

The work body management unit 610 transmits a travel start instruction to the work body 410. The work body management unit 610 receives the work history of the maintenance work or the inspection result of the inspection work by the work body 410. The work body management unit 610 also receives various pieces of information from the work body 410, such as completion of separation or coupling, completion of travel, completion of maintenance work, and detection of a worker.

The travel mechanism management unit 620 manages the operation of the travel mechanism 420. Specifically, the travel mechanism management unit 620 transmits instructions corresponding to a task to the travel mechanism management unit 620 at a predetermined timing regarding:
maintenance work in the maintenance mode or the independent maintenance mode; or
inspection work in the normal mode.
The instructions corresponding to the task include information based on a maintenance schedule, such as:
information for determining the work body 410 traveling in the travel space 110;
travel path in the travel space 110 of the work body 410 traveling in the travel space 110;
opening position of the travel space 110;
information for determining a rail on which inspection work is to be performed; and
information for determining a substrate processing system and a unit on which maintenance work is to be performed.

The crane mechanism management unit 630 manages the operation of the crane mechanism 431. Specifically, the crane mechanism management unit 630 transmits instructions corresponding to a task to the crane mechanism 431 at a predetermined timing regarding:
maintenance work in the maintenance mode or the independent maintenance mode.
   The instructions corresponding to the task include information based on a maintenance schedule, such as:
information for determining a substrate processing system and a unit on which maintenance work is to be performed.

The vertical transfer mechanism management unit 640 manages the operation of the vertical transfer mechanism 450. Specifically, the vertical transfer mechanism management unit 640 transmits instructions corresponding to a task to the vertical transfer mechanism 450 at a predetermined timing regarding:
maintenance work in the maintenance mode or the independent maintenance mode. ·The instructions corresponding to the task include information based on a maintenance schedule, such as:
information for determining the work body 410 which moves up and down;
opening position of the travel space 110; and
information for determining connection destinations of two ends of the vertical transfer rail.
   The vertical transfer mechanism management unit 640 transmits a storage instruction to the vertical transfer mechanism 450.

The substrate processing system management unit 650 manages the state of the substrate processing systems 141_1 to 142_2. Specifically, the substrate processing system management unit 650 performs processing such as:
receiving information on a degree of wear of components or information on components requiring replacement is received from the substrate processing systems 141_1 to 142_2 and notifying to a general controller 680 in the normal mode;
receiving a determination result of replacement necessity from the general controller 680 in response to notification to the general controller 680 and notifying the substrate processing systems 141_1 to 142_2 in the normal mode;
transmitting a maintenance schedule notified from the general controller 680 to the substrate processing systems 141_1 to 142_2 in the normal mode;
receiving a determination result of transition propriety into a maintenance mode or an independent maintenance mode from the substrate processing systems 141_1 to 142_2 and notifying the general controller 680 in the normal mode;
transmitting a transition instruction notified from the general controller 680 to the substrate processing systems 141_1 to 142_2 in the normal mode; and
receiving alert information to a worker 482 from the general controller 680 and transmitting the substrate processing systems 141_1 to 142_2 in the maintenance mode or the independent maintenance mode.

The light emitting unit management unit 660 manages the operation of the light emitting unit 433. Specifically, the light emitting unit management unit 660 transmits a light emission start instruction and a light emission stop instruction corresponding to a task to the light emitting unit 433 at a predetermined timing regarding:
maintenance work in the maintenance mode.
   The instructions corresponding to the task include information based on a maintenance schedule, such as:
travel path in the travel space 110 of the work body 410 traveling in the travel space 110.

The portable terminal management unit 670 transmits and receives various types of information to and from the portable terminal 460. The various types of information here include, for example:
maintenance Schedule;
alert information to the worker 482 holding the portable terminal 460; and
instruction information (including voice instruction information) from the worker 482 holding the portable terminal 460.

The general controller 680 manages entirety of the management system 440. Specifically, the general controller 680 performs processing such as:
determining replacement necessity and notifying the substrate processing system management unit 650 when the substrate processing system management unit 650 notifies information on a degree of wear of components or information on components that needs replacement in the normal mode;
generating a maintenance schedule in response to the determination of whether replacement is necessary in the normal mode and notifying the work body management unit 610, the travel mechanism management unit 620, and the crane mechanism management unit 630;
generating a maintenance schedule in response to the determination of whether replacement is necessary in the normal mode and notifying the vertical transfer mechanism management unit 640, the substrate processing system management unit 650, the light emitting unit management unit 660, and the portable terminal management unit 670;
ordering components to be used for the maintenance work based on the maintenance schedule after specifying the components to be used for the maintenance work and inquiring about inventory of the components in the normal mode (inventory information held either internally or externally may be accessed);
notifying the substrate processing system management unit 650 of a transition instruction when a transition into the maintenance mode or the independent maintenance mode becomes possible; and
notifying the substrate processing system management unit 650 of the alert information, identifying the corresponding worker, and notifying the portable terminal management unit 670 of the alert information when the worker detection information is notified from the work body management unit 610 in the maintenance mode.

### <Hardware Configuration of Management System>

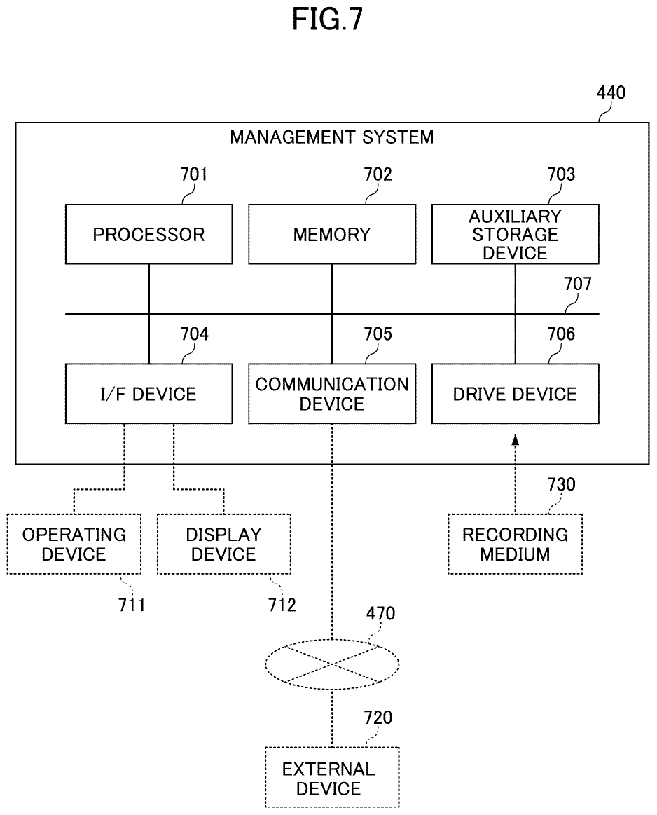

Next, a hardware configuration of the management system 440 will be described. FIG. 7 is a drawing illustrating an example of the hardware configuration of the management system.

As shown in FIG. 7, the management system 440 includes a processor 701, a memory 702, an auxiliary storage device 703, an I/F (interface) device 704, a communication device 705, and a drive device 706. The hardware components included in the management system 440 are connected to each other via a bus 707.

The processor 701 has various computing devices such as a CPU (Central Processing Unit) and a GPU (Graphics Processing Unit). The processor 701 reads various programs (e.g., a management program) from the memory 702 and executes them.

The memory 702 has a main storage device such as a ROM (Read Only Memory) and a RAM (Random Access Memory). The processor 701 and the memory 702 form what is called a computer, and the computer achieves various functions by executing various programs read from the memory 702 by the processor 701.

The auxiliary storage device 703 stores various programs and various information used when the various programs are executed by the processor 701.

The I/F device 704 is a connection device for connecting to external devices (e.g., operating device 711, display device 712). The I/F device 704 accepts an operation of the management system 440 by the administrator 481 via the operating device 711. The operating device 711 includes a keyboard, a mouse, a touch panel, and the like. The I/F device 704 outputs the processing result by the management system 440 to the administrator 481 via the display device 712.

The communication device 705 is a communication device for communicating with the external device 720 via the network 470. The external device 720 includes the work body 410, the travel mechanism 420, the crane mechanism 431, the vertical transfer mechanism 450, the substrate processing systems 141_1 to 142_2, the light emitting unit 433, the portable terminal 460, and the like.

The drive device 706 is a device for setting a recording medium 730. The recording medium 730 includes a medium for optically, electrically, or magnetically recording information such as a CD-ROM, a flexible disk, a magneto-optical disk, and the like. The recording medium 730 may include a semiconductor memory for electrically recording information such as a ROM and a flash memory.

The various programs installed in the auxiliary storage device 703 are installed, for example, when the distributed recording medium 730 is set in the drive device 706 and the various programs recorded in the recording medium 730 are read out by the drive device 706. Alternatively, the various programs installed in the auxiliary storage device 703 may be installed by being downloaded from the network 470 via the communication device 705.

### <First Operation Example of Travel Mechanism in Maintenance Mode>

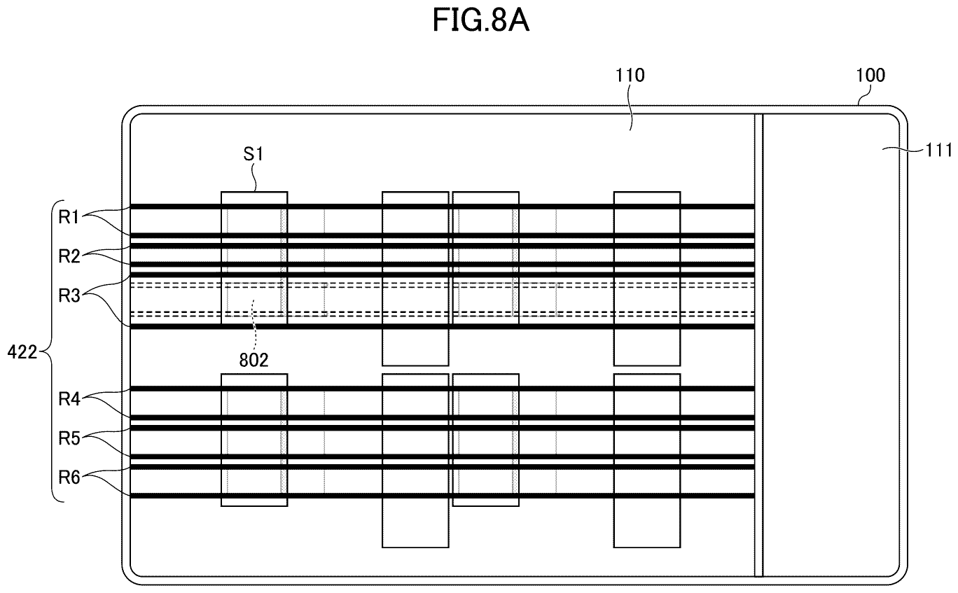

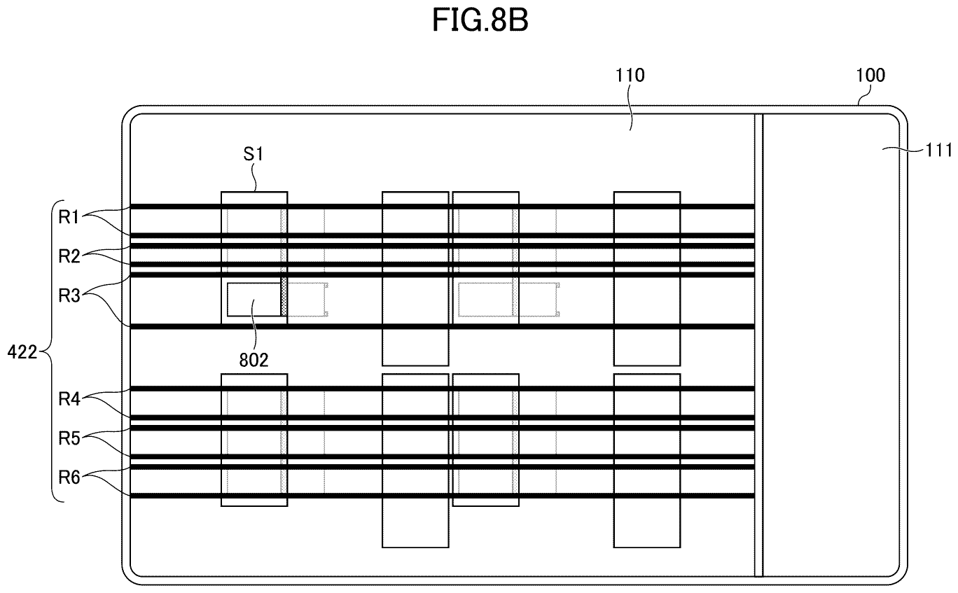

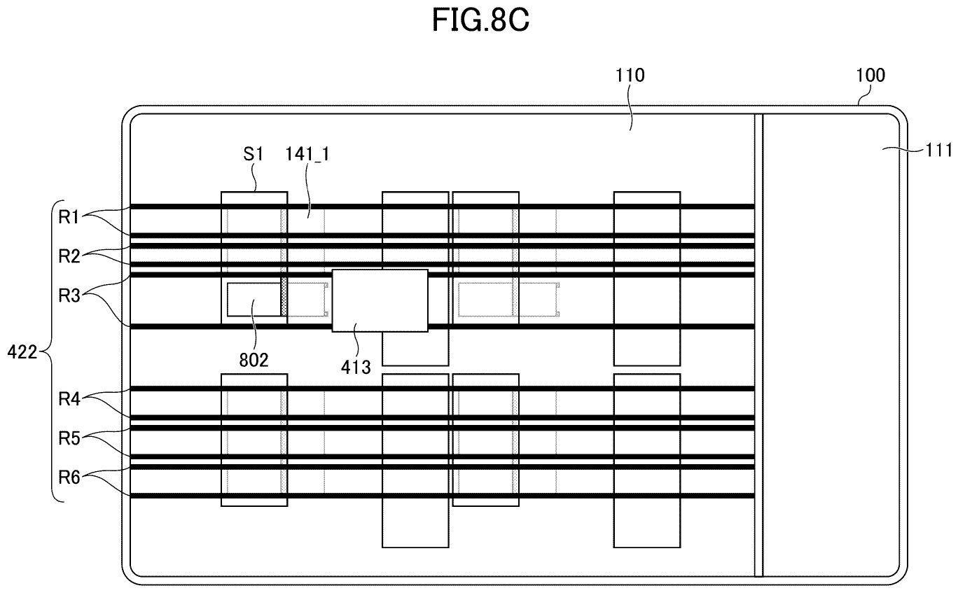

Next, as the operation of the travel mechanism 420 in the maintenance mode, the operation when the vertical transfer robot 413 travels will be described. FIGS. 8A to 8C are drawings illustrating first to third examples of operation of a travel mechanism or the like in a maintenance mode.

The travel mechanism 420 receives instructions according to the tasks from the travel mechanism management unit 620, such as:
information for specifying the work body 410 traveling in the travel space 110: the vertical transfer robot 413;
a travel path in the travel space 110 of the work body 410 traveling in the travel space 110: a travel path along the rail 422 identified by R3, the travel path extending from a preparation space 111 to the lid identified by S1 among the lids 424;
an opening position of the travel space 110: a lid identified by S1 among the lids 424 (a lid at an upper position in the vertical direction of the unit 802); and
a substrate processing system on which maintenance work is to be performed for performing maintenance work; information for specifying the unit: the substrate processing system 141_1 and the unit 802.

Thus, the changing mechanism 421 of the travel mechanism 420 changes the rail width of the rail identified by R3 among the rails 422 so that the rail width corresponds to the size of the vertical transfer robot 413. At this time, if the position of the rail after the change interferes with the position of the adjacent rail, the changing mechanism 421 of the travel mechanism 420 also changes the position of the adjacent rail.

FIG. 8A shows a state in which the rail width of the rail identified by R3 is increased so that the rail width corresponds to the size of the vertical transfer robot 413. In FIG. 8A, the position of the rail indicated by a dotted line is the position of the rail identified by R3 and indicates the position of the rail before the rail width is increased.

FIG. 8A shows a state in which the position of the adjacent rail (the rail identified by R2) is also changed because the position of the rail after the change interferes with the position of the adjacent rail (the rail identified by R2).

Subsequently, the opening mechanism 423 of the travel mechanism 420 opens the floor of the travel space 110 by sliding the lid identified by S1 among the lids 424 so that the opening size corresponds to the size of the unit 802.

FIG. 8B shows a state in which the floor of the travel space 110 is opened so that the opening size corresponds to the size of the unit 802.

Subsequently, the vertical transfer robot 413 receives an instruction according to the task from the work body management unit 610:
information for specifying the substrate processing system and the unit on which maintenance work is to be performed: the substrate processing system 141_1 and the unit 802,
travel paths to a unit on which maintenance work is to be performed (outward and inward paths): a travel path to travel from the preparation space 111 to the lid identified by S1 on the rail identified by R3 of the rail 422, and a travel path to travel from the lid identified by S1 to the preparation space 111;
procedure of maintenance work for the unit on which maintenance work is to be performed: a working procedure to remove the unit 802 from the substrate processing system 141_1 and to attach a new unit 802′ (not shown) to the substrate processing system 141_1.

FIG. 8C shows a state in which the vertical transfer robot 413 autonomously travels from the preparation space 111 to the lid identified by S1 on the rail identified by R3 in order to remove the unit 802 of the substrate processing system 141_1.

### <Second Operation Example of Travel Mechanism in Maintenance Mode>

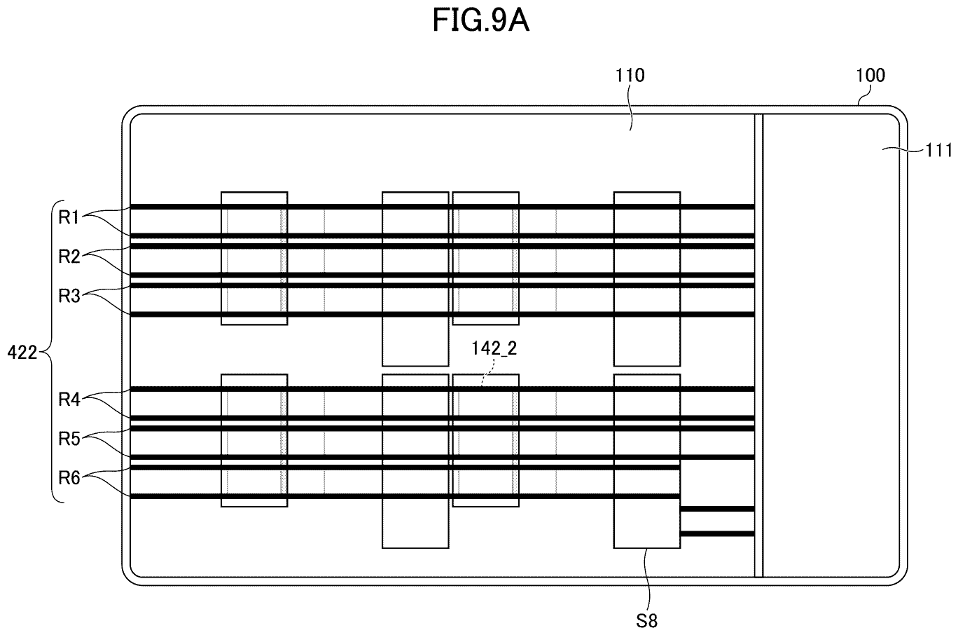

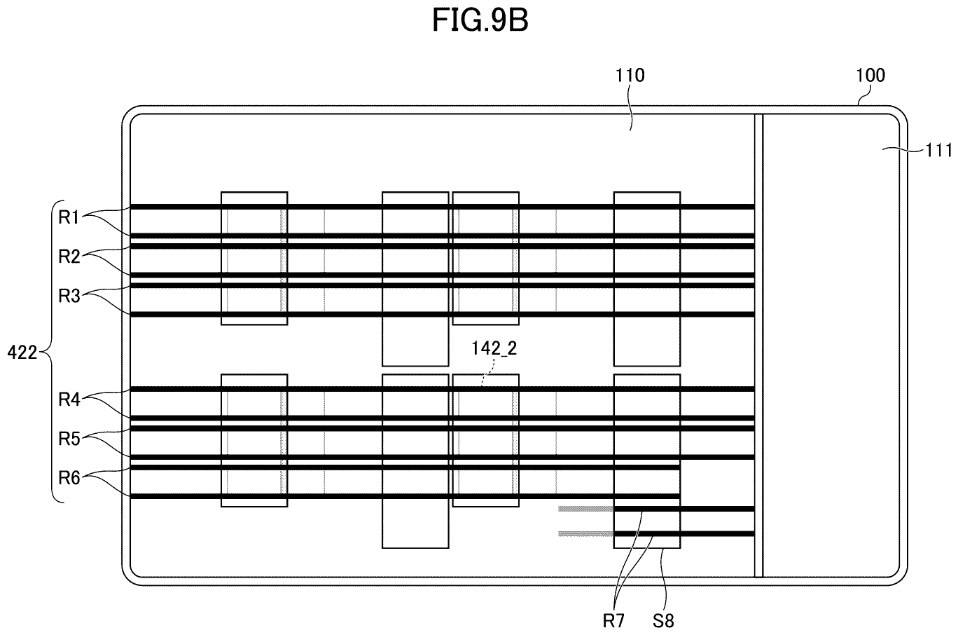

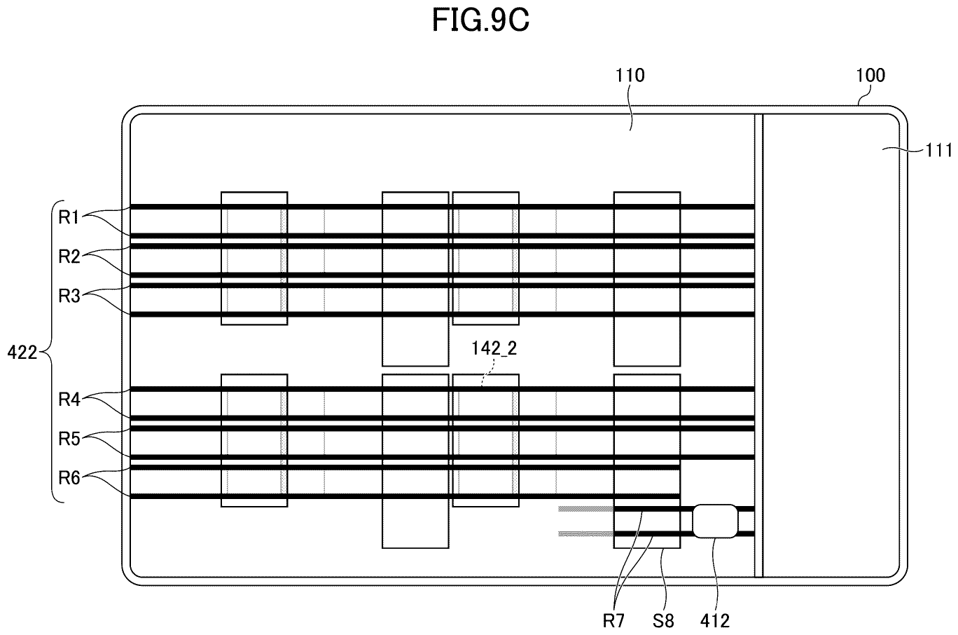

Next, as the operation of the travel mechanism 420 in the maintenance mode, the operation when the work robot 412 travels will be described. FIGS. 9A to 9C are drawings illustrating fourth to sixth examples of operation of a travel mechanism or the like in a maintenance mode.

The travel mechanism 420 receives instructions according to the tasks from the travel mechanism management unit 620, such as:
information for specifying the work body 410 traveling in the travel space 110: the work robot 412;
a travel path in the travel space 110 of the work body 410 traveling in the travel space 110: a travel path along a rail identified by R6 among the rails 422, the travel path extending from a preparation space 111 to the lid identified by S8 among the lids 424;
an opening position of the travel space 110: a lid identified by S8 among the lids 424 (a lid in the device space 120 at a position right above the travel path extending from the substrate processing system 142_2); and
information for specifying a substrate processing system and a unit on which maintenance work is to be performed: the substrate processing system 142_2 and a unit.

Thus, the changing mechanism 421 of the travel mechanism 420 changes the rail width of the rail identified by R6 among the rails 422 so that the rail width corresponds to the size of the work robot 412. Further, the changing mechanism 421 of the travel mechanism 420 moves, among the rails identified by R6, a rail in a range from the preparation space 111 to the lid identified by S8 among the lids 424 to the opening position. Further, the opening mechanism 423 of the travel mechanism 420 opens the floor of the travel space 110 by sliding the lid (lid in the device space 120 at a position right above the travel path extending from the substrate processing system 142_2) identified by S8 among the lids 424.

FIG. 9A shows a state in which, among the rails identified by R6, a rail in a range from the preparation space 111 to the lid identified by S8 is moved to the opening position. FIG. 9A shows a state in which the rail width of the rail identified by R6 is adjusted so that the rail width corresponds to the size of the work robot 412. FIG. 9A shows a state in which the lid identified by S8 is slid and the floor of the travel space 110 is opened.

Subsequently, the vertical transfer mechanism 450 receives, as an instruction corresponding to the task, from the vertical transfer mechanism management unit 640:
information for specifying the work body 410 moving up and down: the work robot 412;
opening position of the travel space 110: a lid identified by S8 among the lids 424 (lid in the device space 120 at a position right above the travel path extending from the substrate processing system 142_2); and
information for determining connection destinations of two ends of the vertical transfer rail: the rail identified by R6 of the rail 422; and a travel path extending from the substrate processing system 142_2 in the device space 120.

Thus, the vertical transfer mechanism 450 adjusts the rail width of the vertical transfer rail identified by R7 of the vertical transfer rail 452 to a rail width corresponding to the size of the work robot 412 and connects:
a rail extending from the preparation space 111 to the lid identified by S8 and moved to the opening position among the rails identified by R6; and
a travel path extending from the substrate processing system 142_2.

FIG. 9B shows a state in which the rails moved to the opening position and the travel path in the device space 120 are connected by the vertical transfer rails identified by R7 adjusted to the rail width corresponding to the size of the work robot 412.

FIG. 9C shows a state in which the work robot 412 autonomously travels from the preparation space 111 toward the travel path in the device space 120 on the rails identified by R6 and the vertical transfer rails identified by R7 in the device space 120.

### <Operation Example of Travel Mechanism in Independent Maintenance Mode>

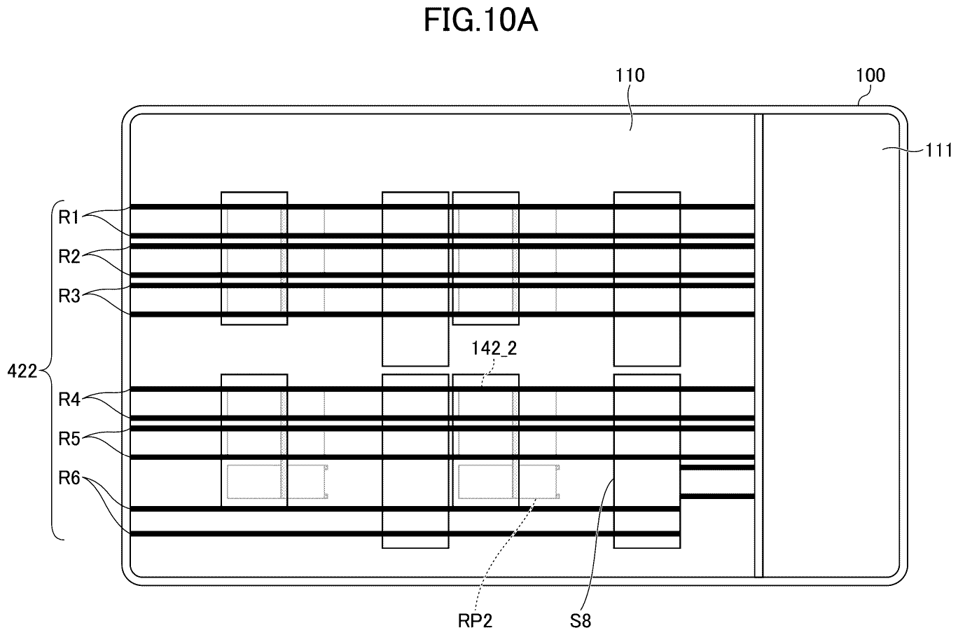

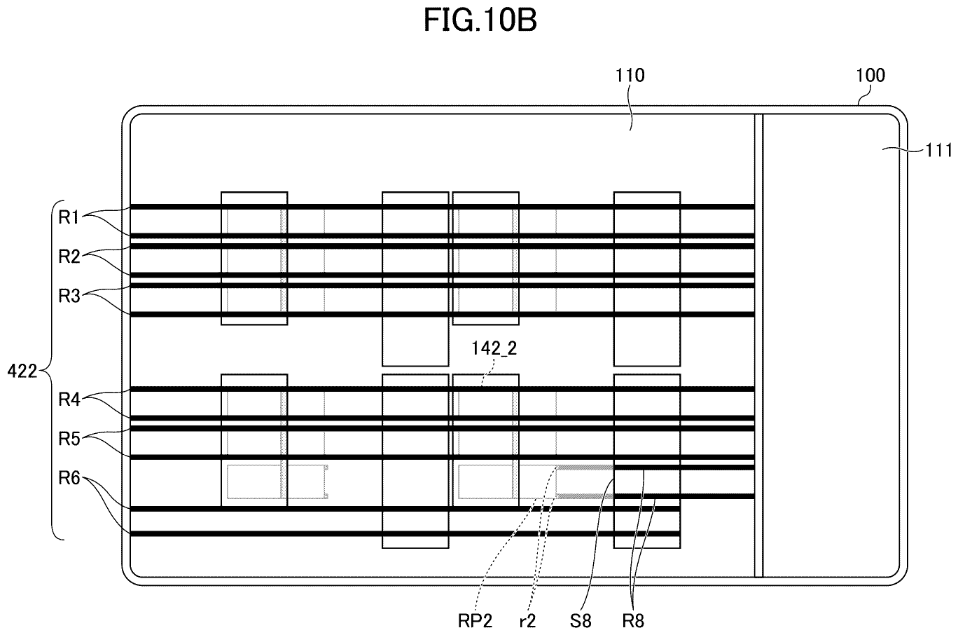

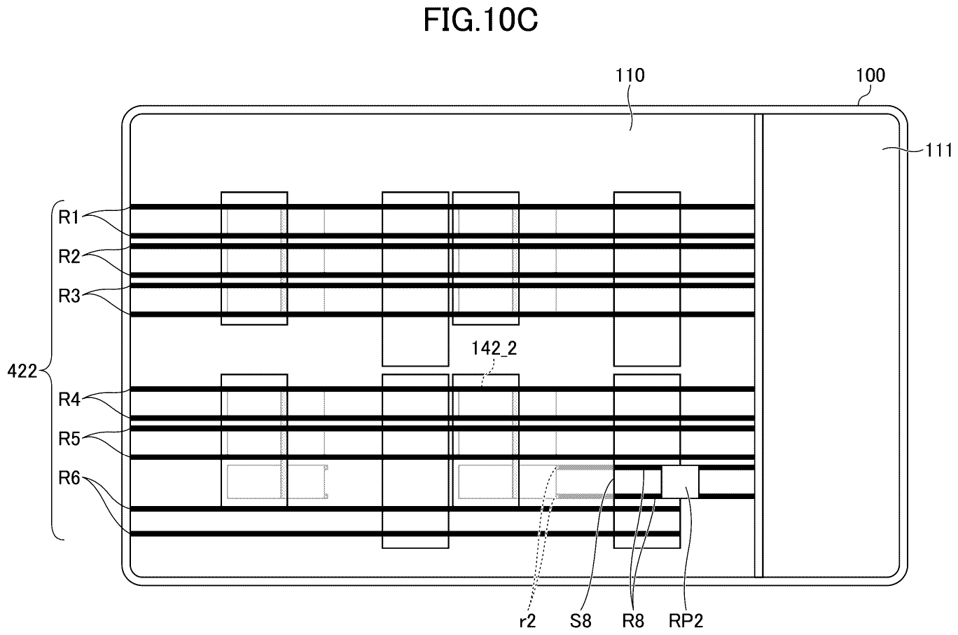

Next, as an operation of the travel mechanism 420 in the independent maintenance mode, an operation when the replacement unit 411 travels will be described. FIGS. 10A to 10C are first to third drawings illustrating an example of operation of the travel mechanism or the like in the independent maintenance mode.

The travel mechanism 420 receives instructions according to the tasks from the travel mechanism management unit 620, such as:
information for specifying the work body 410 traveling in the travel space 110: a replacement unit identified by RP2 among the replacement units 411;
a travel path in the travel space 110 of the work body 410 traveling in the travel space 110: a travel path along a rail identified by R6 among the rails 422, the travel path extending from a preparation space 111 to the lid identified by S8 among the lids 424;
an opening position of the travel space 110: a lid identified by S8 among the lids 424 (in the device space 120, a position connected to the replacement unit identified by RP2 among the replacement units 411 of the substrate processing system 142_2); and
information for specifying a substrate processing system and a unit on which maintenance work is to be performed: a replacement unit identified by RP2 among the replacement units 411 of the substrate processing system 142_2.

Thus, the changing mechanism 421 of the travel mechanism 420 changes the rail width of the rail identified by R6 so that the rail width corresponds to the size of the replacement unit 411. Further, the changing mechanism 421 of the travel mechanism 420 moves the rails other than the range from the preparation space 111 to the lid identified by S8 among the rails identified by R6 to a position other than the opening position. Further, the opening mechanism 423 of the travel mechanism 420 opens the floor of the travel space 110 by sliding the lid identified by S8 among the lids 424.

FIG. 10A shows how the rails other than the range from the preparation space 111 to the lid identified by S8 among the rails identified by R6 are moved to a position other than the opening position. FIG. 10A shows how the rail width of the rails identified by R6 is adjusted so that the rail width corresponds to the size of the replacement unit 411. Further, FIG. 10A shows how the lid identified by S8 is slid to open the floor of the travel space 110.

Subsequently, the vertical transfer mechanism 450 receives, as an instruction corresponding to the task, from the vertical transfer mechanism management unit 640:
information for specifying the work body 410 moving up and down: a replacement unit identified by RP2 among the replacement units 411;
an opening position of the travel space 110: a lid identified by S8 among the lids 424 (a position to be connected with a replacement unit identified by RP2 among the replacement units 411 of the substrate processing system 142_2 in the device space 120); and
information for determining connection destinations of two ends of the vertical transfer rail: a rail identified by R6 among the rails 422 and a support rail r2 for supporting a replacement unit identified by RP2 among replacement units 411 of the substrate processing system 142_2 in the device space 120.

Thus, the vertical transfer mechanism 450 adjusts the rail width of the vertical transfer rail identified by R8 to a rail width corresponding to the size of the replacement unit 411 and connects:
a rail extending from the preparation space 111 to the lid identified by S8 among the rails identified by R6; and
a support rail r2 for supporting the replacement unit identified by RP2 among the replacement units 411 of the substrate processing system 142_2.

FIG. 10B shows a vertical transfer rail identified by R8 which is adjusted to a rail width corresponding to the size of the replacement unit 411 connecting:
a rail extending to the lid identified by S8 among the rails identified by R6; and
a support rail r2 for supporting the replacement unit identified by RP2.

FIG. 10C shows a state in which the replacement unit identified by RP2 is separated from the substrate processing system 142_2 of the device space 120, and autonomously travels toward the preparation space 111 on the vertical transfer rail identified by R8 and the rail identified by R6.

### <Operation Example of Travel Mechanism in Normal Mode>

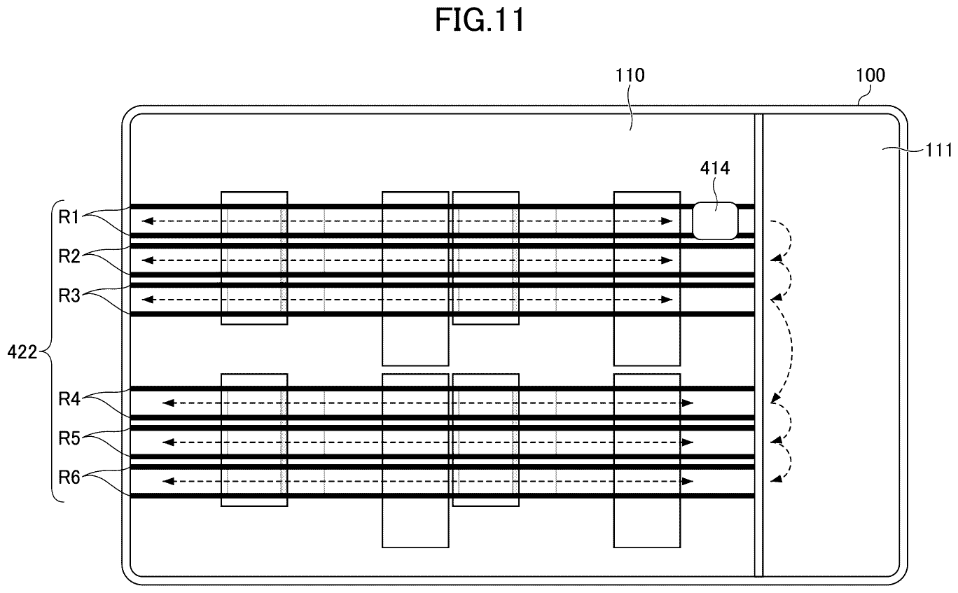

Next, as an operation of the travel mechanism 420 in the normal mode, an operation when the inspection robot 414 travels will be described. FIG. 11 is a drawing illustrating an example of operation of the travel mechanism in the normal mode.

The travel mechanism 420 receives instructions according to the tasks from the travel mechanism management unit 620, such as:
information for Specifying a Rail on Which Inspection Is Performed: Rails Identified by R1 to R6 among the rails 422.

Thus, the changing mechanism 421 of the travel mechanism 420 changes the rail width of the rails identified by R1 to R6 among the rails so that the rail width corresponds to the size of the inspection robot 414.

Subsequently, the inspection robot 414 receives instructions according to the tasks from the work body management unit 610, such as:
information for determining a substrate processing system and a unit on which inspection work is to be performed: rails identified by R1 to R6 among the rails 422;
a travel path when inspecting the rail on which inspection work is to be performed: R1→R2→R3→R4→R5→R6; and
a procedure of inspection work for the rail on which maintenance work is to be performed: procedure for reciprocating while capturing images of the rail on which inspection work is to be performed and inspecting the image data for abnormalities.

Thus, the inspection robot 414 sequentially reciprocates from the rail 422 identified by R1 to inspect each rail identified by R1 to R6 for abnormalities.

FIG. 11 shows a state in which, after each rail identified by R1 to R6 is changed to a rail width corresponding to the size of the inspection robot 414, the inspection robot 414 sequentially reciprocates from R1 while capturing images of the rails to inspect the image data for abnormalities.

### <Operation Example of Vertical Transfer Mechanism in Independent Maintenance Mode>

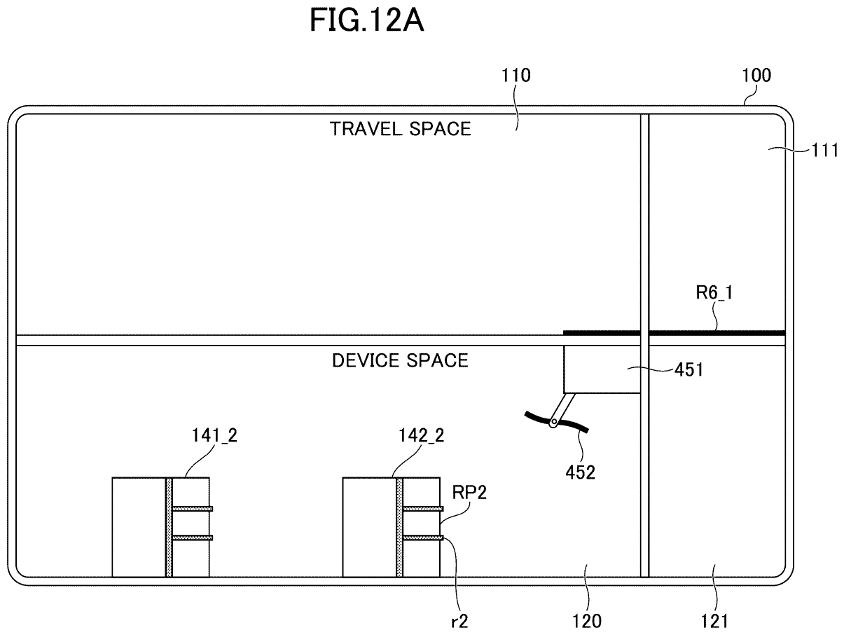

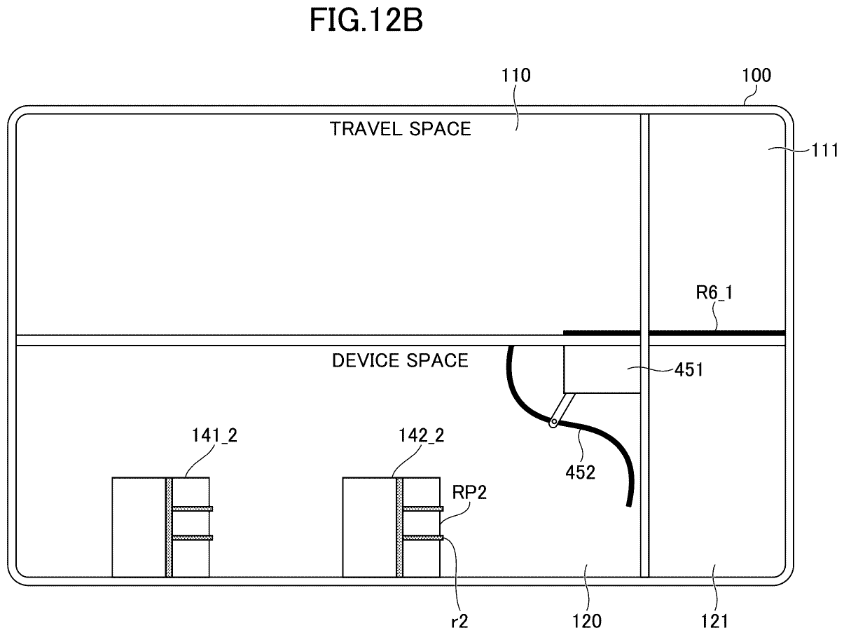

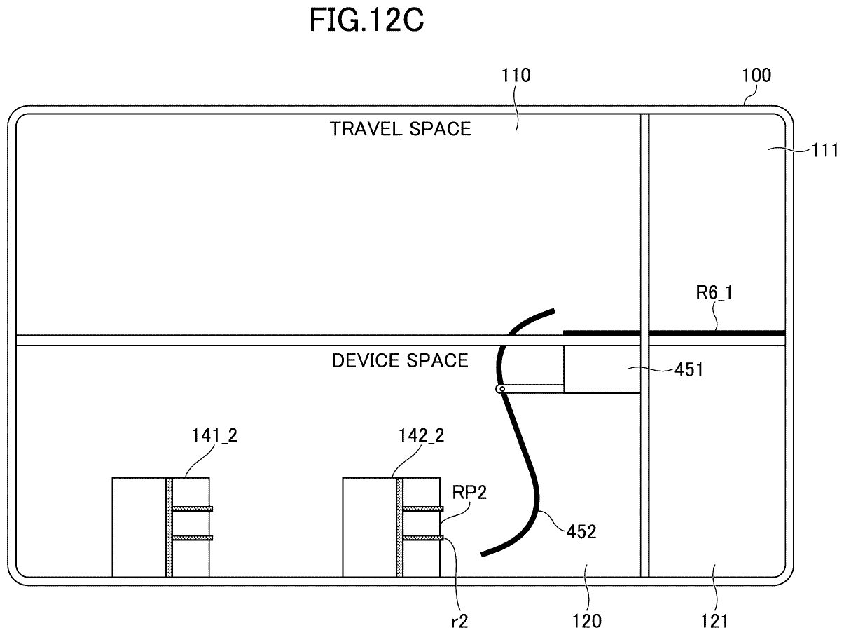

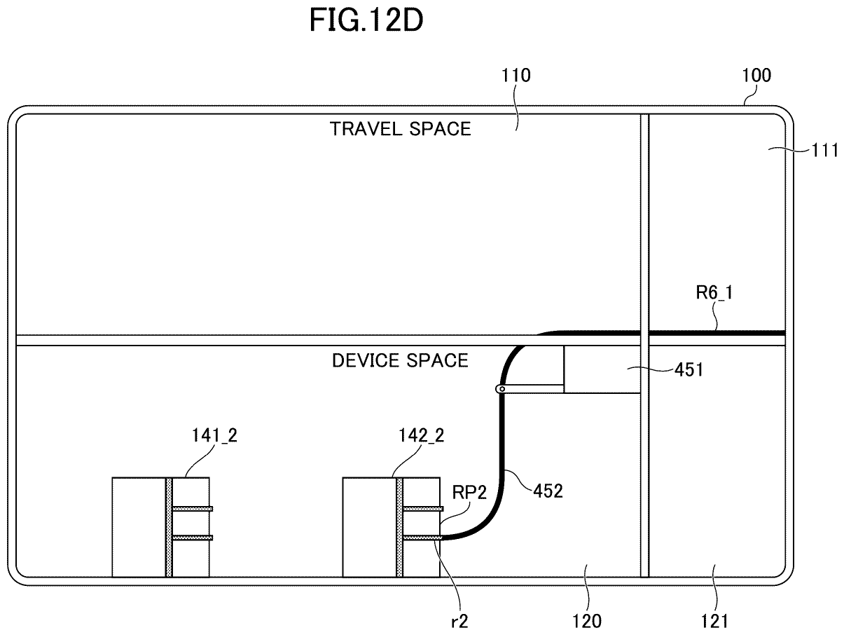

Next, as an operation of the vertical transfer mechanism 450 in the independent maintenance mode, an operation when the replacement unit 411 autonomously travels will be described. FIGS. 12A to 12D are first to fourth drawings illustrating an example of operation of the vertical transfer mechanism in the independent maintenance mode.

The vertical transfer mechanism 450 receives instructions according to the tasks from the vertical transfer mechanism management unit 640, such as:
information for specifying the work body 410 which moves up and down: a replacement unit identified by RP2 among the replacement units 411;
an opening position of the travel space 110: a lid identified by S8 among the lids 424 (in the device space 120, a position connected to the replacement unit identified by RP2 among the replacement units 411 of the substrate processing system 142_2); and
information for determining connection destinations of two ends of the vertical transfer rail: a rail identified by R6 among the rails 422 and a supporting rail r2 for supporting a replacement unit identified by RP2 among the replacement units 411 of the substrate processing system 142_2 in the device space 120.

Thus, the vertical transfer mechanism 450 adjusts the rail width to a rail width corresponding to the size of the replacement unit 411 after moving to a position of a lid identified by S8 and taking out the vertical transfer rail 452, and connects:
a rail R6_1 extending from the preparation space 111 to the lid identified by S8 among the rails identified by R6; and
a support rail r2 for supporting the replacement unit identified by RP2.

FIG. 12A shows a state in which the installation mechanism 451 of the vertical transfer mechanism 450 is moved to the position of the lid specified in step S8 in response to the reception of an instruction corresponding to the tasks by the vertical transfer mechanism 450, and then the stored vertical transfer rail 452 is taken out.

In FIG. 12A, it is assumed that the installation mechanism 451 is configured to be movable in the depth direction of the paper. It is also assumed that the vertical transfer rail 452 is stored in the installation mechanism 451 in a folded state.

FIG. 12B shows a state in which the vertical transfer rail 452 taken out of the installation mechanism 451 is adjusted to a rail width corresponding to the size of the replacement unit 411.

FIG. 12C shows a state in which the vertical transfer rail 452 is extended and adjusted to a length suitable for connecting:
a rail R6_1 extending from the preparation space 111 to the lid identified by S8 among the rails identified by R6; and
a support rail r2 for supporting the replacement unit identified by RP2.

FIG. 12C shows a state in which the position and attitude of the vertical transfer rail 452 are controlled such that:
one end of the vertical transfer rail 452 is connected to the rail R6_1 that is among rails identified by R6 and extends from a preparation space 111 to a lid identified by S8; and
the other end of the vertical transfer rail 452 is connected to the support rail r2 for supporting the replacement unit identified by RP2.

Additionally, FIG. 12D shows a state in which the replacement unit 411 can travel autonomously by:
connecting one end of the vertical transfer rail 452 and the rail R6_1 that is among rails identified by R6 and extends from a preparation space 111 to a lid identified by S8; and
connecting the other end of the vertical transfer rail 452 and the support rail r2 for supporting the replacement unit identified by RP2.

### <Operation Example of Vertical Transfer Mechanism in Independent Maintenance Mode>

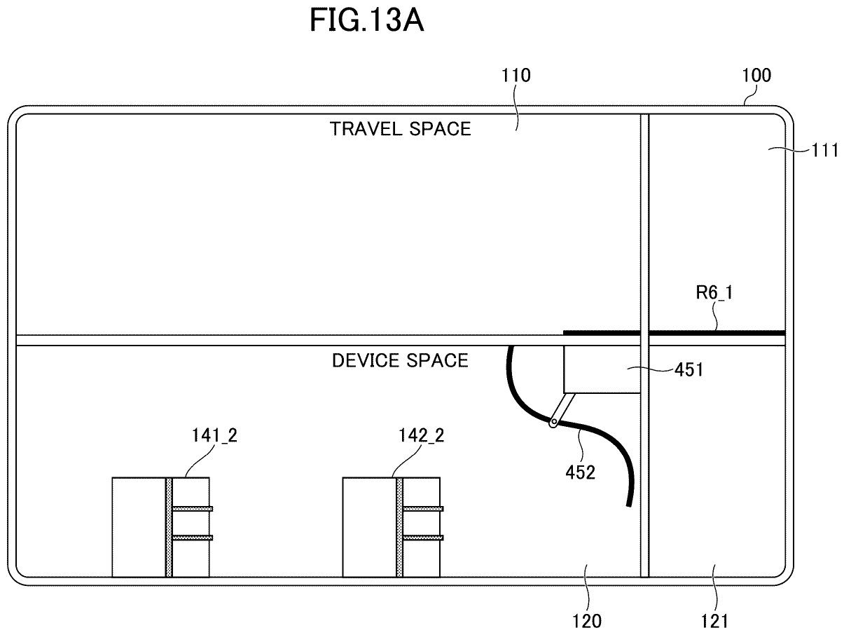

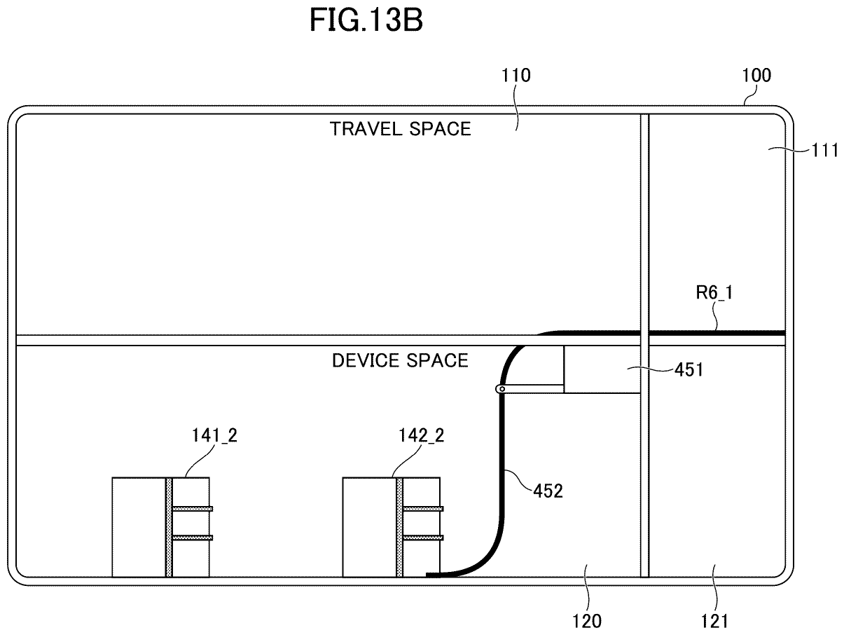

Next, as an operation of the vertical transfer mechanism 450 in the maintenance mode, an operation when the work robot 412 travels will be described. FIGS. 13A and 13B are first and second drawings illustrating an example of operation of the vertical transfer mechanism in the independent maintenance mode.

The vertical transfer mechanism 450 receives instructions according to the tasks from the vertical transfer mechanism management unit 640, such as:
information for specifying the work body 410 which moves up and down: a work robot 412;
an opening position of the travel space 110: a lid identified by S8 among the lids 424 (lid in the device space 120 at a position right above the travel path extending from the substrate processing system 142_2); and
information for determining connection destinations of two ends of the vertical transfer rail: a rail identified by R6 among the rails 422 and a travel path extending from the substrate processing system 142_2 in the device space 120.

Thus, the vertical transfer mechanism 450 adjusts the rail width of the vertical transfer rail 452 to a rail width corresponding to the size of the work robot 412 after moving to a position of a lid identified by S8, and connects:
a rail R6_1 extending from the preparation space 111 to the lid identified by S8 among the rails identified by R6; and
a travel path extending from the substrate processing system 142_2.

FIG. 13A shows a state in which the installation mechanism 451 of the vertical transfer mechanism 450 is moved to the position of the lid specified in step S8 in response to the reception of an instruction corresponding to the tasks by the vertical transfer mechanism 450. FIG. 13A also shows a state in which the installation mechanism 451 of the vertical transfer mechanism 450 takes out the stored vertical transfer rail 452 and extends the rail while adjusting the rail width.

FIG. 13B shows a state in which:
the vertical transfer rail 452 is adjusted to a length suitable for connecting, among the rails identified by R6, the rail R6_1 in a range from the preparation space 111 to the lid identified by S8 and the travel path extending from the substrate processing system 142_2;
the vertical transfer rail 452 is adjusted to a rail width corresponding to the size of the work robot 412;
one end of the vertical transfer rail 452 is connected to the rail R6_1 extending from the preparation space 111 to the lid identified by S8; and
the other end of the vertical transfer rail 452 is connected to the travel path extending from the substrate processing system 142_2.

### <Operation Example Of Crane Mechanism in Maintenance Mode>

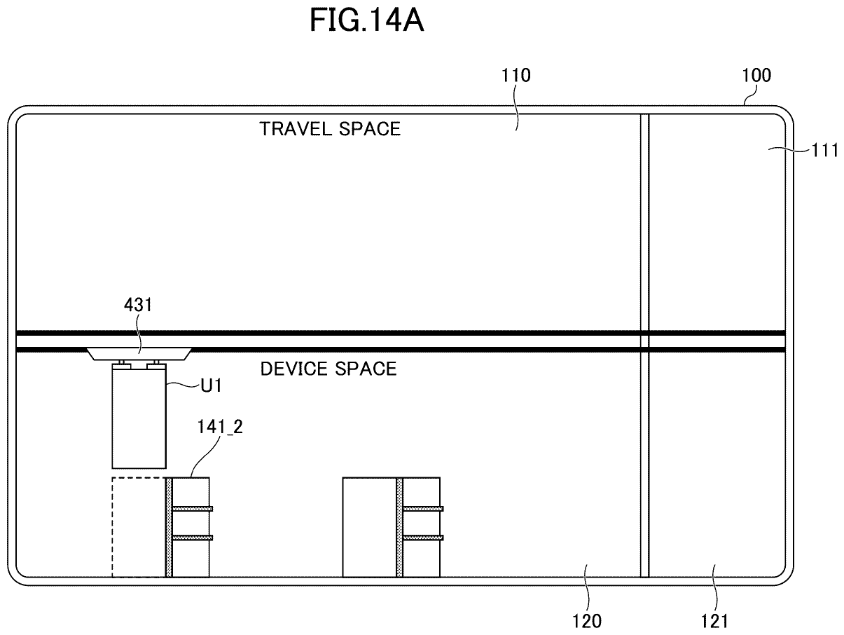

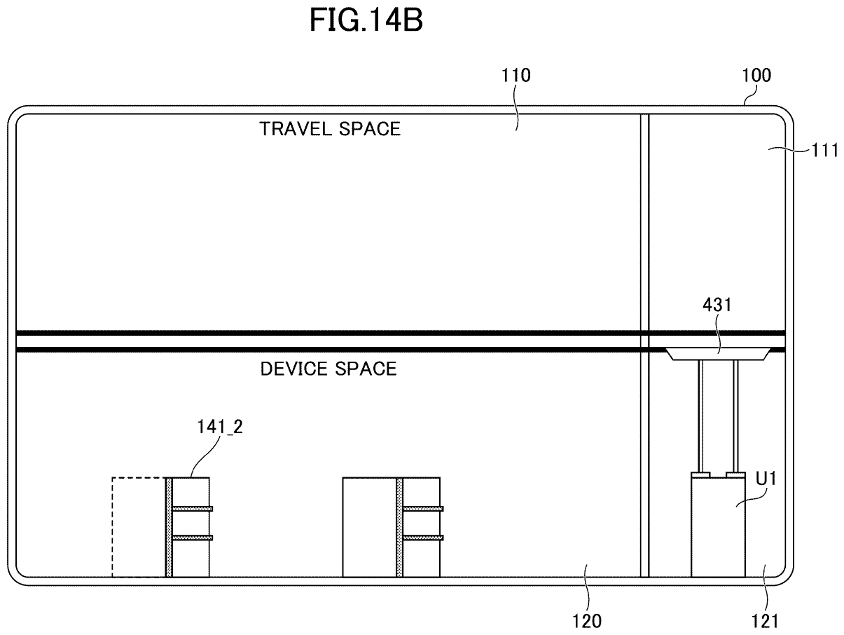

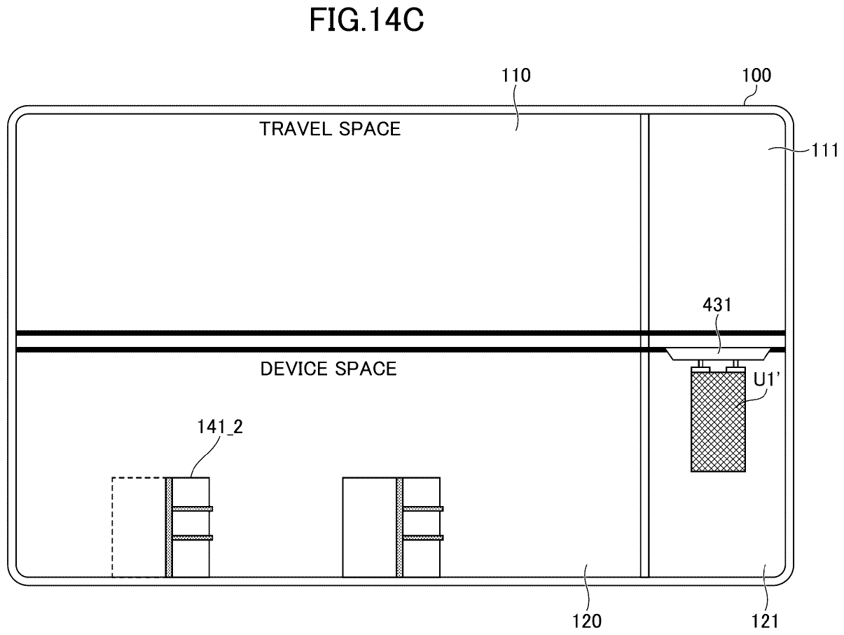

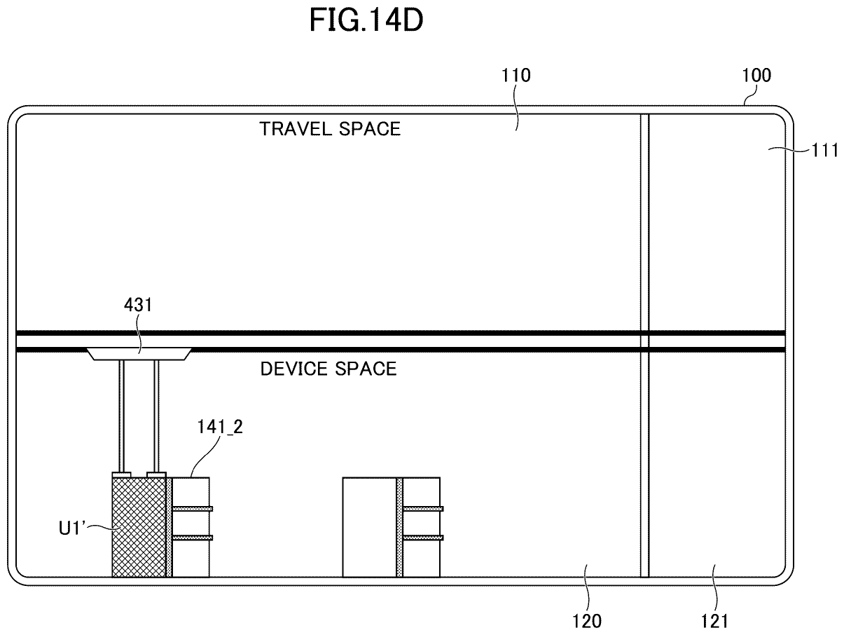

Next, as an operation of the crane mechanism 431 in the maintenance mode, the operation in the case of conveying a detachable unit of the substrate processing system 141_2 from an upper position in the vertical direction will be described. FIGS. 14A to 14D are first to fourth drawings illustrating an example of the operation of the crane mechanism in the maintenance mode.

The crane mechanism 431 receives instructions according to the tasks from a crane mechanism management unit 630 such as:
information for specifying a substrate processing system and a unit on which maintenance work is to be performed: a unit identified by U1 among units attachable and detachable from an upper position in the vertical direction in the substrate processing system 141_2.

Thus, the crane mechanism 431 moves to the substrate processing system 141_2 of a conveyance destination and removes the unit identified by U1 among units attachable and detachable from the upper position in the vertical direction from the substrate processing system 141_2.

FIG. 14A shows a state in which the unit identified by U1 is lifted upward by the crane mechanism 431 after the unit is removed from the substrate processing system 141_2.

Subsequently, the crane mechanism 431 conveys the unit identified by U1 to the preparation space 121. FIG. 14B shows a state in which the unit identified by U1 is conveyed to the preparation space 121 by the crane mechanism 431 and placed in the preparation space 121.

Subsequently, the crane mechanism 431 conveys a unit newly attached to the substrate processing system 141_2 and detachable at an upper position in the vertical direction to the substrate processing system 141_2.

FIG. 14C shows a state in which the unit identified by U1′ as the unit newly attached to the substrate processing system 141_2 is lifted by the crane mechanism 431 and conveyed to the substrate processing system 141_2.

Subsequently, the crane mechanism 431 conveys the unit identified by U1′ to the position of the substrate processing system 141_2 and lowers it in the vertical direction from a position right above the conveyed substrate processing system 141_2. Thus, the unit identified by U1′ is attached to the substrate processing system 141_2.

FIG. 14D shows a state in which the unit identified by U1′ conveyed by the crane mechanism 431 is attached to the substrate processing system 141_2.

### <Processing Flow in Normal Mode of Maintenance Work System>

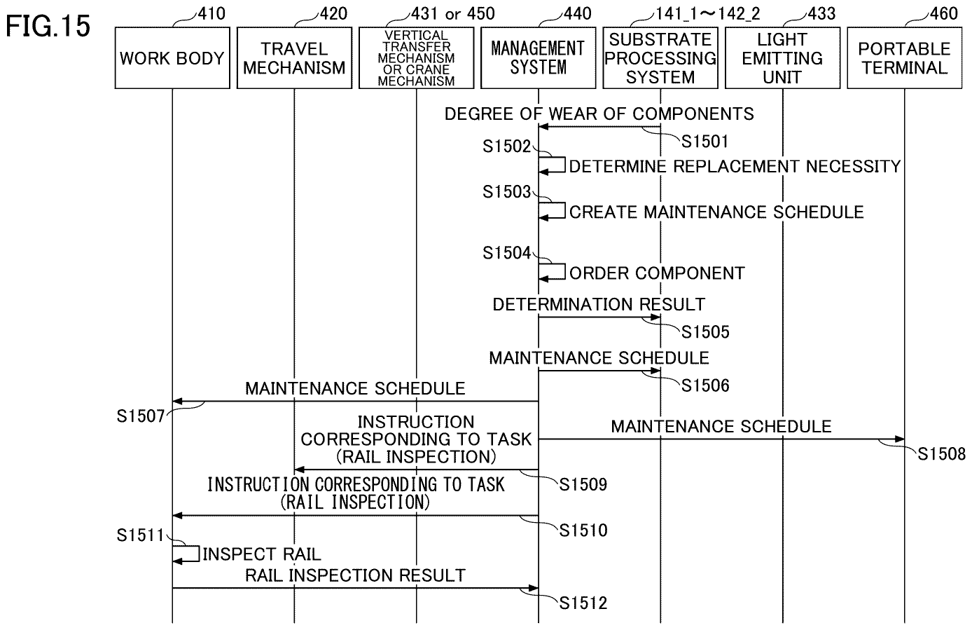

Next, a processing flow in the maintenance work system 400 according to the first embodiment will be described. FIG. 15 is a sequence diagram illustrating a flow of processing related to maintenance work in the normal mode of the maintenance work system.

In step S1501, each of the substrate processing systems 141_1 to 142_2 measures a degree of wear of the components at predetermined intervals, and transmits, to the management system 440, information related to the measured degree of wear or information on components that need to be replaced.

In step S1502, the management system 440 determines replacement necessity based on the received information related to the degree of wear or the like.

In step S1503, the management system 440 creates a maintenance schedule for the substrate processing system that has determined that replacement of the components is necessary. The management system 440 determines, as a maintenance schedule, such as:
a substrate processing system and a unit on which maintenance work is to be performed;
maintenance tasks; and
maintenance work timing for each maintenance task.

In step S1504, the management system 440 manages the inventory of components used for the maintenance work and orders the components used for the maintenance work based on the maintenance schedule.

In step S1505, the management system 440 transmits the result of the determination in step S1502 to the substrate processing systems 141_1 to 142_2.

In step S1506, the management system 440 transmits a maintenance schedule to a substrate processing system that has been determined to require component replacement.

In step S1507, the management system 440 transmits a maintenance schedule to the work body 410 related to the maintenance work.

In step S1508, the management system 440 transmits a maintenance schedule to the portable terminal 460.

In step S1509, the management system 440 transmits an instruction corresponding to the tasks regarding the inspection of the rail 422 to the travel mechanism 420.

In step S1510, the management system 440 transmits an instruction corresponding to the task regarding the inspection of the rail 422 to the inspection robot 414 of the work body 410.

In step S1511, the inspection robot 414 of the work body 410 inspects the rail 422.

In step S1512, the inspection robot 414 of the work body 410 transmits the inspection result of the rail 422 to the management system 440.

In the example of FIG. 15, the rail 422 is inspected in steps S1509 to S1512 as processing in the normal mode, but the inspection of the rail 422 need not be executed every time in the normal mode. For example, the inspection may be executed when it is determined to be required.

### <Processing Flow in Independent Maintenance Mode of Maintenance Work System>

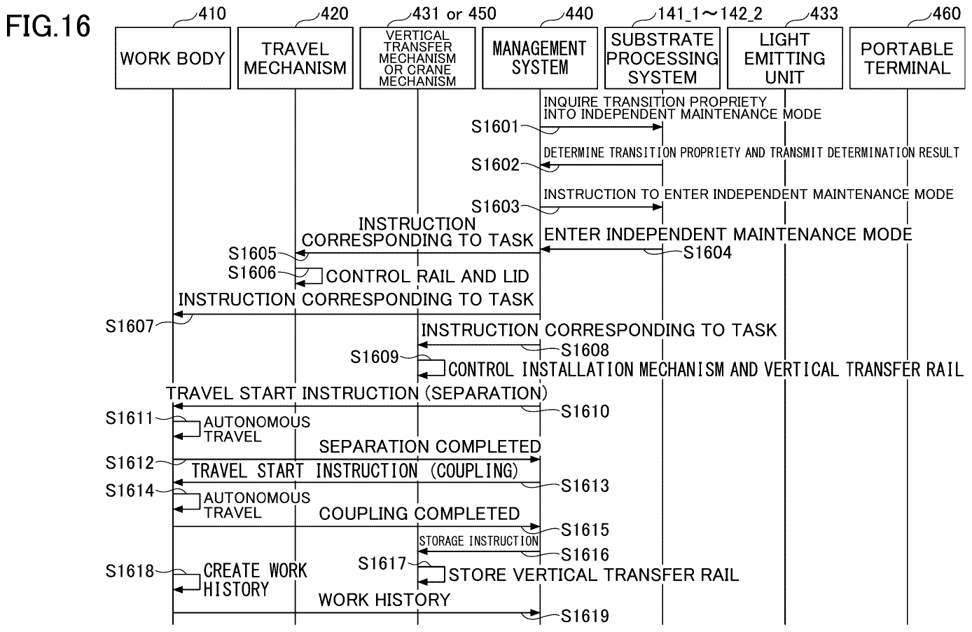

Next, a process flow in the independent maintenance mode of the maintenance work system 400 according to the first embodiment will be described. FIG. 16 is a sequence diagram illustrating a flow of processing related to maintenance work in the independent maintenance mode of the maintenance work system.

In step S1601, the management system 440 inquires of the substrate processing systems 141_1 to 142_2 transition propriety into the independent maintenance mode.

In step S1602, the substrate processing systems 141_1 to 142_2 determines transition propriety into the independent maintenance mode and transmits the determination result to the management system 440.

In step S1603, the management system 440 receives the determination result of transition propriety into the independent maintenance mode and transmits an instruction to enter the independent maintenance mode to the substrate processing system capable of transitioning.

In step S1604, the substrate processing system that has received a transition instruction enters an independent maintenance mode and notifies the management system 440 that the transition has been completed.

In step S1605, the management system 440 transmits an instruction corresponding to the task of the maintenance work determined in the maintenance schedule to the travel mechanism 420.

In step S1606, the changing mechanism 421 and the opening mechanism 423 of the travel mechanism 420 control the rail 422 and the lid 424 according to instructions corresponding to the tasks.

In step S1607, the management system 440 transmits instructions corresponding to the tasks to the replacement unit identified by RP2 and the replacement unit identified by RP2′ among the replacement units 411 of the work body 410.

In step S1608, the management system 440 transmits instructions corresponding to the tasks to the vertical transfer mechanism 450.

In step S1609, the installation mechanism 451 of the vertical transfer mechanism 450 moves according to instructions corresponding to the tasks, and then controls the vertical transfer rail 452.

In step S1610, the management system 440 transmits a travel start instruction (separation) to the replacement unit identified by RP2 among the replacement units 411 of the work body 410.

In step S1611, the replacement unit identified by RP2 among the replacement units 411 of the work body 410 (replacement unit of the substrate processing system 142_2 entered the independent maintenance mode) is separated from the substrate processing system 142_2. Then, the replacement unit identified by RP2 starts autonomous travel to the preparation space 111 to reach the preparation space.

In step S1612, the replacement unit identified by RP2 among the replacement units 411 of the work body 410 transmits the completion of separation to the management system 440.

In step S1613, the management system 440 transmits a travel start instruction (coupling) to the replacement unit identified by RP2 among the replacement units 411 of the work body 410 newly coupled to the substrate processing system.

In step S1614, the replacement unit identified by RP2 among the replacement units 411 of the work body 410 starts autonomous travel, moves from the preparation space 111 to the travel space 110, travels in the travel space 110, and then moves to the device space 120. The replacement unit identified by RP2 among the replacement units 411 of the work body 410 is coupled to the substrate processing system 142_2 that entered the independent maintenance mode in the device space 120.

In step S1615, the replacement unit identified by RP2 of the replacement units 411 of the work body 410 transmits to the management system 440 that the coupling is completed when the coupling to the substrate processing system 142_2 entered the independent maintenance mode is completed.

In step S1616, the management system 440 instructs the vertical transfer mechanism 450 to return to the state before the instruction corresponding to the task is transmitted.

In step S1617, the installation mechanism 451 of the vertical transfer mechanism 450 returns to the state before the instruction corresponding to the task is transmitted by storage the vertical transfer rail 452.

In step S1618, the replacement unit identified by RP2 of the replacement units 411 of the work body 410 creates work history information.

In step S1619, the replacement unit identified by RP2 of the replacement units 411 of the work body 410 transmits the work history information to the management system 440.

In the example of FIG. 16, the case where the transition into the independent maintenance mode is triggered by an inquiry by the management system 440 has been described, but the transition into the independent maintenance mode may be triggered by a request from the substrate processing systems 141_1 to 142_2.

Examples of cases where the transition into the maintenance mode is triggered by a request from the substrate processing systems 141_1 to 142_2 include:
when trouble occurs;
when an autonomous device action occurs; and
when coordinated operation with a work robot becomes necessary.

### <Processing Flow in Maintenance Mode of Maintenance Work System (1)>

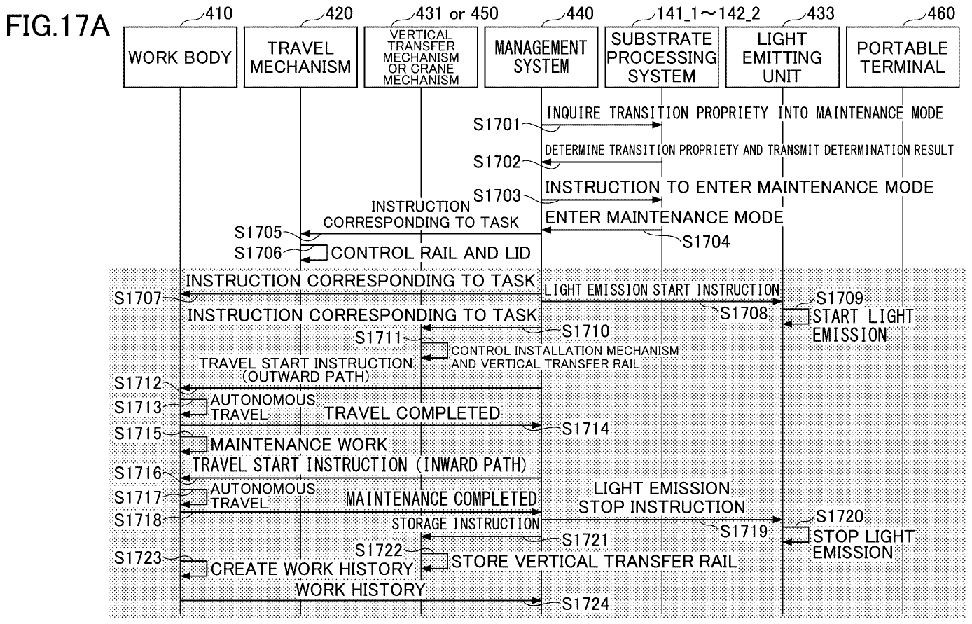

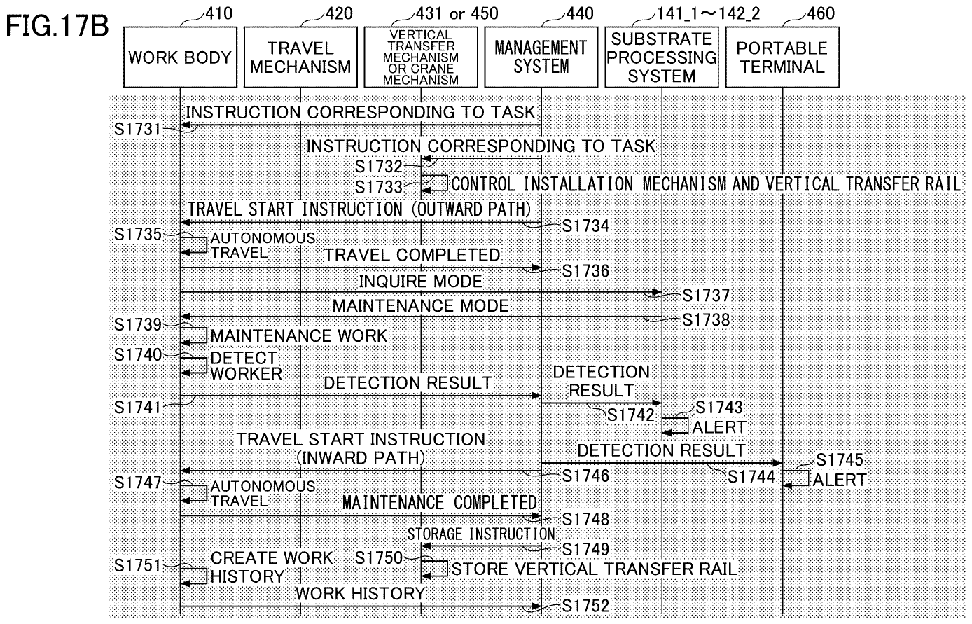

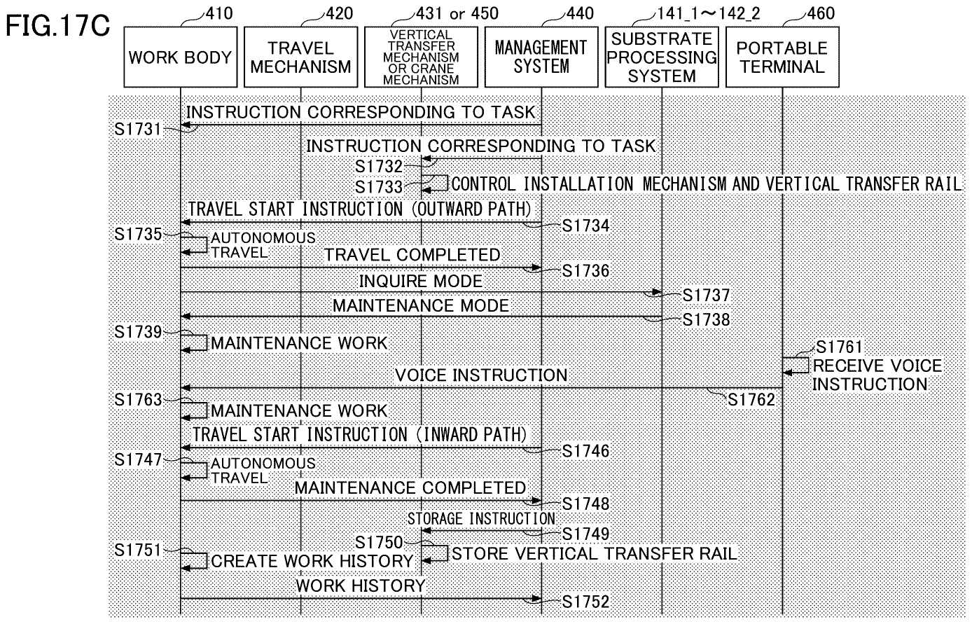

Next, a flow of processing in the maintenance mode of the maintenance work system 400 according to the first embodiment will be described. FIG. 17A is a first sequence diagram illustrating a flow of processing related to maintenance work in the maintenance mode of the maintenance work system.

In step S1701, the management system 440 inquires of the substrate processing systems 141_1 to 142_2 transition propriety into the maintenance mode.

In step S1702, the substrate processing systems 141_1 to 142_2 determines transition propriety into the maintenance mode and transmits the determination result to the management system 440.

In step S1703, the management system 440 receives the determination result of transition propriety into the maintenance mode and transmits an instruction to enter the independent maintenance mode to the substrate processing system capable of transitioning.

In step S1704, the substrate processing system that has received a transition instruction enters an independent maintenance mode and notifies the management system 440 that the transition has been completed.

In step S1705, the management system 440 transmits an instruction corresponding to the task of the maintenance work determined in the maintenance schedule to the travel mechanism 420.

In step S1706, the changing mechanism 421 and the opening mechanism 423 of the travel mechanism 420 control the rail 422 and the lid 424 according to instructions corresponding to the tasks.

In step S1707, the management system 440 transmits an instruction corresponding to the tasks to the work robot 412 of the work body 410.

In step S1708, the management system 440 transmits a light emission start instruction to the light emitting unit 433. The light emission start instruction transmitted to the light emitting unit 433 includes information regarding the travel path of the work robot 412 in the travel space 110.

In step S1709, the light emitting unit 433 emits light in accordance with the travel path of the work robot 412 in the travel space 110. Thus, the light emitting unit 433 can guide the work robot 412 in the device space 120 in the direction of the substrate processing system on which maintenance work is to be performed.

In step S1710, the management system 440 transmits an instruction corresponding to the tasks to the vertical transfer mechanism 450.

In step S1711, the installation mechanism 451 of the vertical transfer mechanism 450 controls the vertical transfer rail 452 after moving in accordance with the instruction corresponding to the tasks.

In step S1712, the management system 440 transmits a travel start instruction (outward path) to the work robot 412 of the work body 410.

In step S1713, the work robot 412 of the work body 410 autonomously travels in the travel space 110 and moves to the device space 120 via the vertical transfer rail 452. The work robot 412 moved to the device space 120 travels in the device space 120 in accordance with the guidance of the light emitting unit 433 in the device space 120, and moves to the position of the substrate processing system on which maintenance work is to be performed.

In step S1714, the work robot 412 notifies the management system 440 that the autonomous travel is completed.

In step S1715, the work robot 412 of the work body 410 performs maintenance work on the substrate processing system on which maintenance work is to be performed. When the maintenance work on the substrate processing system on which maintenance work is to be performed is completed, the process proceeds to step S1716.

In step S1716, the management system 440 transmits a travel start instruction (inward path) to the work robot 412 of the work body 410.

In step S1717, the work robot 412 of the work body 410 travels in the device space 120 according to the guidance of the light emitting unit 433 in the device space 120, and moves to the position of the vertical transfer rail 452. The work robot 412 moves to the travel space 110 via the vertical transfer rail 452 and moves to the preparation space 111 by autonomously traveling in the travel space 110.

In step S1718, the work robot 412 of the work body 410 transmits to the management system 440 that the maintenance work is completed.

In step S1719, the management system 440 transmits a light emission stop instruction to the light emitting unit 433.

In step S1720, the light emitting unit 433 stops light emission in accordance with the light emission stop instruction from the management system 440.

In step S1721, the management system 440 instructs the vertical transfer mechanism 450 to return to the state before the instruction corresponding to the task is transmitted.

In step S1722, the installation mechanism 451 of the vertical transfer mechanism 450 returns to the state before the instruction corresponding to the task is transmitted by storage the vertical transfer rail 452.

In step S1723, the work robot 412 of the work body 410 creates work history information.

In step S1724, the work robot 412 of the work body 410 transmits the work history information to the management system 440.

In the example of FIG. 17A, a case where the transition into the maintenance mode is triggered by an inquiry by the management system 440 has been described, but the transition into the maintenance mode may be triggered by a request from the substrate processing systems 141_1 to 142_2.

### <Processing Flow in Maintenance Mode of Maintenance Work System (2)>

Next, another flow of processing in the maintenance mode of the maintenance work system 400 according to the first embodiment will be described. Here, a case will be described in which the work robot 412 autonomously travels in the device space 120 based on the marker 434 or based on a signal from the transmitter 435 of the substrate processing systems 141_1 to 142_2. Further, a case will be described in which the work robot 412 communicates with the substrate processing system on which maintenance work is to be performed before the maintenance work. Further, a case will be described in which the worker 482 approaching the work robot 412 during the maintenance work is alerted.

FIG. 17B is a second sequence diagram illustrating the flow of processing related to the maintenance work in the maintenance mode of the maintenance work system. Since processes other than the hatched portion of FIG. 17A are common, only processes corresponding to the hatched portion of FIG. 17A are shown in FIG. 17B.

In step S1731, the management system 440 transmits an instruction corresponding to the tasks to the work robot 412 of the work body 410.

In step S1732, the management system 440 transmits an instruction corresponding to the tasks to the vertical transfer mechanism 450.

In step S1733, the installation mechanism 451 of the vertical transfer mechanism 450 controls the vertical transfer rail 452 after moving in accordance with an instruction corresponding to the tasks.

In step S1734, the management system 440 transmits a travel start instruction (outward path) to the work robot 412 of the work body 410.

In step S1735, the work robot 412 of the work body 410 autonomously travels in the travel space 110 and moves to the device space 120 via the vertical transfer rail 452. The work robot 412 moved to the device space 120 autonomously travels in the device space 120 while calculating its current position by capturing images of the marker 434 or receiving a signal from the transmitter 435. As a result, the work robot 412 moves to the position of the substrate processing system on which maintenance work is to be performed.

In step S1736, the work robot 412 notifies the management system 440 that the autonomous travel is completed.

In step S1737, the work robot 412 of the work body 410 communicates with the substrate processing system on which maintenance work is to be performed to inquire whether or not the current mode of the substrate processing system on which maintenance work is to be performed has already entered the maintenance mode.

In step S1738, the substrate processing system on which maintenance work is to be performed notifies the inquiry from the work robot 412 that the current mode has already entered the maintenance mode.

In step S1739, the work robot 412 of the work body 410 performs maintenance work to the substrate processing system on which maintenance work is to be performed. During the maintenance work, the work robot 412 of the work body 410 monitors presence of the worker 482 the work area.

In step S1740, the work robot 412 of the work body 410 detects the presence of the worker 482 in the work area.

In step S1741, the work robot 412 of the work body 410 transmits the detection result to the management system 440.

In step S1742, the management system 440 specifies the substrate processing system under maintenance work by the work robot 412 of the work body 410, and transmits the detection result indicating presence of the worker in the work area of the work robot 412 to the specified substrate processing system.

In step S1743, based on a detection result transmitted from the management system 440, the substrate processing system, for example by lighting an LED, alerts and warns the worker 482 that the worker 482 is present in a work area of the work robot 412.

In step S1744, the management system 440 specifies the worker 482 in a work area of the work robot 412, and transmits the detection result indicating that the worker is in the work area of the work robot 412 to the portable terminal 460 of the specified worker 482.

In step S1745, based on a detection result transmitted from the management system 440, the portable terminal 460 alerts and warns the worker 482 that the worker 482 is present in a work area of the work robot 412 of the work body 410.

Subsequently, when the maintenance work for the substrate processing system on which maintenance work is to be performed is completed, the process proceeds to step S1746.

In step S1746, the management system 440 transmits a travel start instruction (inward path) to the work robot 412 of the work body 410.

In step S1747, the work robot 412 of the work body 410 autonomously travels in the device space 120 and moves to the position of the vertical transfer rail 452. The work robot 412 also moves to the travel space 110 via the vertical transfer rail 452 and autonomously travels in the travel space 110 to move to the preparation space 111.

In step S1748, the work robot 412 of the work body 410 transmits to the management system 440 that the maintenance work is completed.

In step S1749, the work robot 412 instructs the vertical transfer mechanism 450 to return to the state before the instruction corresponding to the task is transmitted.

In step S1750, the installation mechanism 451 of the vertical transfer mechanism 450 returns to the state before the instruction corresponding to the task is transmitted by storage the vertical transfer rail 452.

In step S1751, the work robot 412 of the work body 410 creates work history information.

In step S1752, the work robot 412 of the work body 410 transmits the work history information to the management system 440.

### <Processing Flow in Maintenance Mode of Maintenance Work System (3)>

Next, another flow of processing in the maintenance mode of the maintenance work system 400 according to the first embodiment will be described. Here, a case where the work robot 412 communicates with the portable terminal 460 of the worker 482 and receives a voice instruction from the worker 482 during maintenance work will be described.

FIG. 17C is a third sequence diagram illustrating the flow of processing related to the maintenance work in the maintenance mode of the maintenance work system. Since processes other than the hatched portion of FIG. 17A are also common in FIG. 17C, only processes corresponding to the hatched portion of FIG. 17A are shown in FIG. 17C. Further, among the processes shown in FIG. 17C, the processes same as those of FIG. 17B are denoted with the same reference numerals, and redundant description thereabout is omitted. Among the processes shown in FIG. 17C, processes different from those shown in FIG. 17B are steps S1761 to S1763.

When the worker 482 changes the tasks of the work robot 412 during maintenance work of the work robot 412 (including, for example, stopping maintenance work), the worker 482 gives voice instructions to the portable terminal 460.

In step S1761, the portable terminal 460 receives voice instructions from the worker 482.

In step S1762, the portable terminal 460 transmits a voice instruction from the worker 482 to the work robot 412 of the work body 410.

In step S1763, the work robot 412 changes the tasks of the maintenance work according to the voice instruction from the worker 482, and executes the maintenance work according to the changed tasks.

### <Description Of Replacement Unit>

Next, the Replacement Unit 411 Will Be Described.

### (1) Overview of Replacement Unit

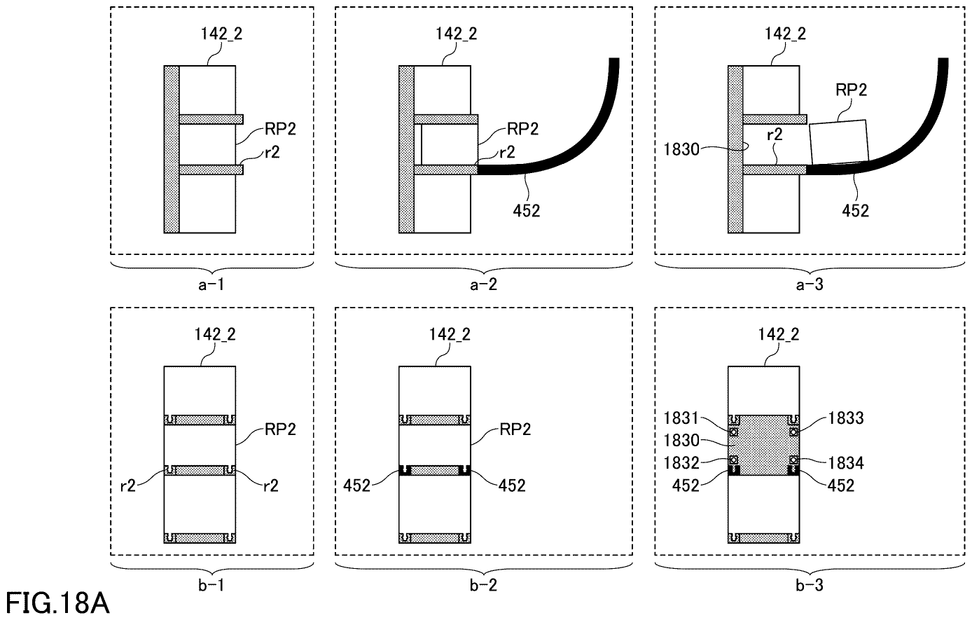

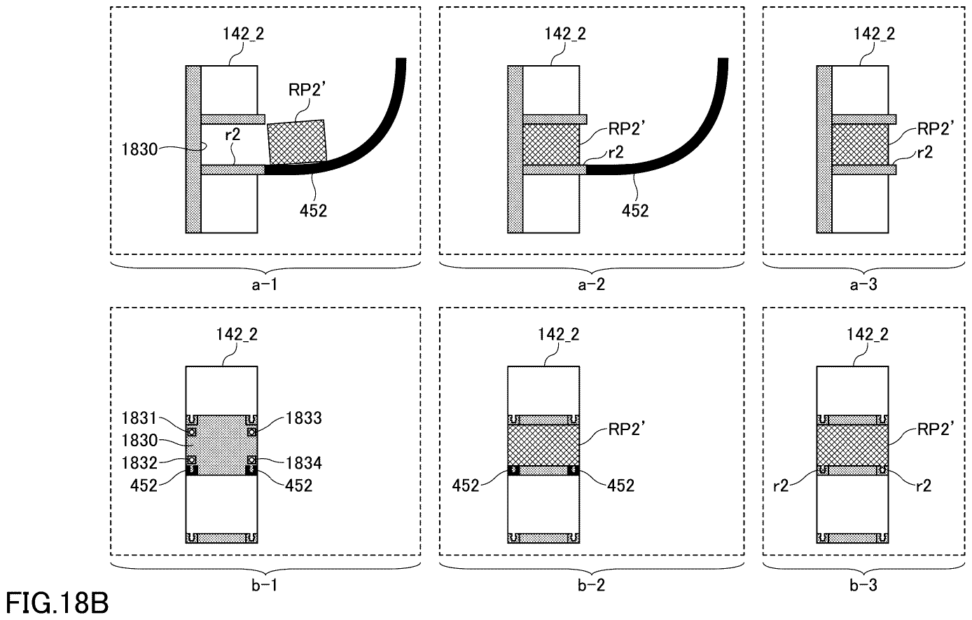

First, an overview of the replacement unit 411 will be described. FIG. 18A is a first drawing illustrating an outline of a replacement unit. FIG. 18A shows a scene in which the replacement unit 411 coupled to the substrate processing system 142_2 is separated.

A portion (a-1) of FIG. 18A is a side view illustrating a state in which the replacement unit identified by RP2 of the replacement units 411 is coupled to the substrate processing system 142_2. A portion (b-1) of FIG. 18A is a front view illustrating a state in which the replacement unit identified by RP2 of the replacement units 411 is coupled to the substrate processing system 142_2.

As shown in the portion (a-1) or (b-1) of FIG. 18A, when coupled to the substrate processing system 142_2, the replacement unit identified by RP2 of the replacement units 411 is supported by the support rail r2.

A portion (a-2) of FIG. 18A is a side view illustrating a state in which the vertical transfer rail 452 is connected to the support rail r2 for supporting the replacement unit identified by RP2 of the replacement units 411. A portion (b-2) of FIG. 18A is a front view illustrating a state in which the vertical transfer rail 452 is connected to the support rail r2 for supporting the replacement unit identified by RP2 of the replacement units 411.

As shown in the portion (a-2) or (b-2) of FIG. 18A, when the vertical transfer rail 452 is connected, the replacement unit identified by RP2 of the replacement units 411 is separated from the substrate processing system 142_2.

A portion (a-3) of FIG. 18A is a side view illustrating a state in which the replacement unit identified by RP2 of the replacement units 411 starts autonomous travel and moves to the travel space 110 via the vertical transfer rail 452. A portion (b-3) of FIG. 18A is a front view illustrating a state in which the replacement unit identified by RP2 of the replacement units 411 starts autonomous travel and moves to the travel space 110 via the vertical transfer rail 452.

As shown in the portion (a-3) or (b-3) of FIG. 18A, when the replacement unit identified by RP2 of the replacement units 411 starts autonomous travel, the rear wall 1830 in the substrate processing system 142_2 is exposed. As shown in the portion (b-3) of FIG. 18A, the rear wall 1830 is provided with a mounting portion for fixing a replacement unit identified by RP2 of the replacement units 411.

FIG. 18B is a second drawing illustrating the outline of the replacement unit. The example of FIG. 18B shows a scene in which the replacement unit identified by RP2′ is coupled as a new replacement unit 411 to the substrate processing system 142_2 from which the replacement unit identified by RP2 of the replacement units 411 has been separated.

A portion (a-1) of FIG. 18B is side view illustrating a state in which a replacement unit identified by RP2′ as a new replacement unit 411 has descended from the travel space 110 along the vertical transfer rail 452 with the vertical transfer rail 452 connected. A portion (b-1) of FIG. 18B is a front view illustrating a state in which a replacement unit identified by RP2′ as a new replacement unit 411 has descended from the travel space 110 along the vertical transfer rail 452 with the vertical transfer rail 452 connected.

A portion (a-2) of FIG. 18B is a side view illustrating a state in which a replacement unit identified by RP2′ as a new replacement unit 411 has moved along the support rail r2 and is fixed to mounting portions 1831 to 1834. A portion (b-2) of FIG. 18B is a front view illustrating a state in which a replacement unit identified by RP2′ as a new replacement unit 411 has moved along the support rail r2 and is fixed to the mounting portion 1831 to 1834.

A portion (a-3) of FIG. 18B is side view illustrating a state in which the vertical transfer rail 452 has been removed from the substrate processing system 142_2 to which the replacement unit identified by RP2′ has been connected as the replacement unit 411. A portion (b-3) of FIG. 18B is a front view illustrating a state in which the vertical transfer rail 452 has been removed from the substrate processing system 142_2 to which the replacement unit identified by RP2′ has been connected as the replacement unit 411.

### (2) Functional Configuration of Replacement Unit

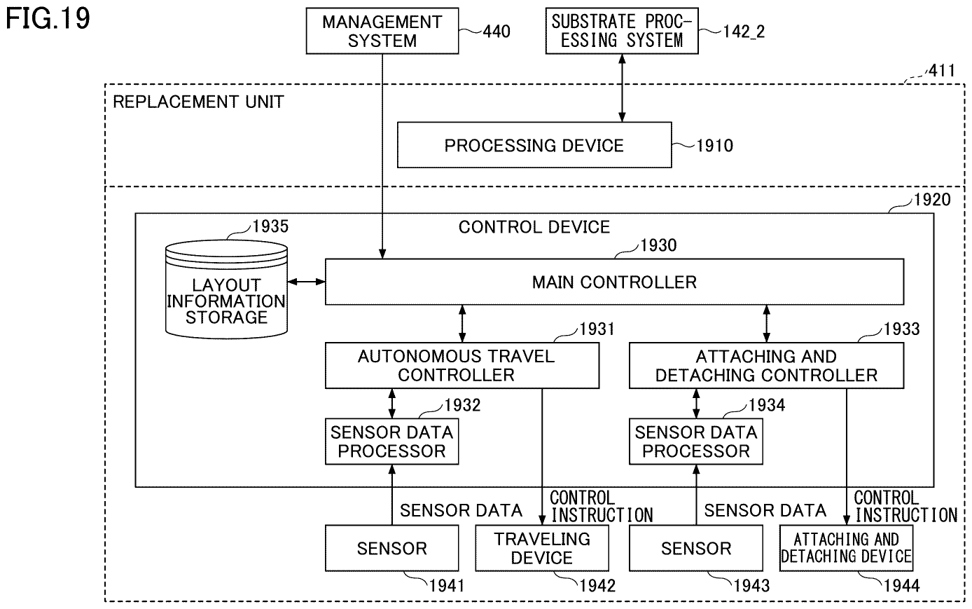

Next, a functional configuration of the replacement unit 411 will be described. FIG. 19 is a drawing illustrating an example of the functional configuration of the replacement unit. As shown in FIG. 19, the replacement unit 411 includes a processing device 1910, a control device 1920, a sensor 1941, a traveling device 1942, a sensor 1943, and an attaching and detaching device 1944.

When the substrate processing system 142_2 performs substrate processing in a normal mode while the replacement unit 411 is coupled to the substrate processing system 142_2, for example, the processing device 1910 executes part of the substrate processing while communicating with the substrate processing system 142_2.

The control device 1920 functions when the replacement unit 411 is separated from the substrate processing system 142_2, for example, or autonomously travels from the substrate processing system 142_2 to the preparation space 111 after separation. The control device 1920 functions when the replacement unit 411 autonomously travels from the preparation space 111 to the substrate processing system 142_2 before coupling to the substrate processing system 142_2, for example, or when coupling to the substrate processing system 142_2.

The sensors 1941 include various sensors (e.g., an imaging device, a laser range finder) used when the replacement unit 411 autonomously travels and transmits measured sensor data (e.g., image data, distance data) to the control device 1920. The traveling device 1942 moves the replacement unit 411 based on a control instruction from the control device 1920.

The sensors 1943 are various sensors used when the replacement unit 411 is coupled to or separated from the substrate processing system 142_2 and transmit sensor data indicating coupling or separation to the control device 1920. The attaching and detaching device 1944 separates the replacement unit 411 from the substrate processing system 142_2 or couples the replacement unit 411 to the substrate processing system 142_2 based on a control instruction from the control device 1920.

A control program is installed in the control device 1920. The control device 1920 functions as a main controller 1930, an autonomous travel controller 1931, a sensor data processor 1932, an attaching and detaching controller 1933, and a sensor data processor 1934 by executing the program.

The main controller 1930 controls entirety of the control device 1920 while communicating with the management system 440.

When the main controller 1930 receives an instruction corresponding to the tasks from the management system 440, the autonomous travel controller 1931 generates a control instruction for causing the replacement unit 411 to autonomously travel based on:
information notified from the sensor data processor 1932; and
layout information of the first substrate processing plant 100 stored in a layout information storage 1935.
   The autonomous travel controller 1931 transmits the generated control instruction to the traveling device 1942. Upon completion of the autonomous travel, the autonomous travel controller 1931 transmits completion of separation to the management system 440 via the main controller 1930.

The sensor data processor 1932 specifies the rail 422 (or the vertical transfer rail 452) during travel by processing the sensor data (e.g., image data, distance data) notified from the sensor 1941 and notifies the autonomous travel controller 1931 thereof. The sensor data processor 1932 specifies the position on the rail 422 (or the vertical transfer rail 452) during travel by processing the sensor data (e.g., image data, distance data) notified from the sensor 1941 and notifies the autonomous travel controller 1931 thereof.

The attaching and detaching controller 1933 transmits a control instruction for separating the replacement unit 411 from the substrate processing system 142_2 to the attaching and detaching device 1944. The attaching and detaching controller 1933 recognizes that the replacement unit 411 is separated from the substrate processing system 142_2 based on information notified from the sensor data processor 1934 in response to the transmission of the control instruction for separation.

The attaching and detaching controller 1933 transmits a control instruction for coupling the replacement unit 411 to the substrate processing system 142_2 to the attaching and detaching device 1944. The attaching and detaching controller 1933 recognizes that the replacement unit 411 is coupled to the substrate processing system 142_2 based on information notified from the sensor data processor 1934 in response to the transmission of the control instruction for coupling. The attaching and detaching controller 1933 transmits the completion of coupling to the management system 440 via the main controller 1930.

The sensor data processor 1934 detects, for example, an attachment and detachment state of the substrate processing system 142_2 to attachment units 1831 to 1834 by processing the sensor data notified from the sensor 1943 and notifies the attaching and detaching controller 1933.

### (3) Separation Processing of Replacement Unit

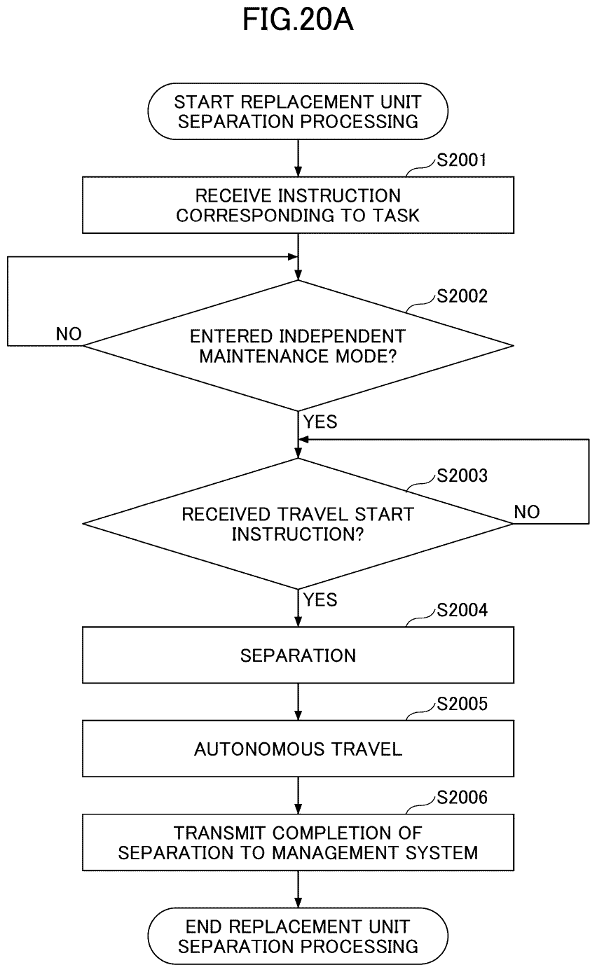

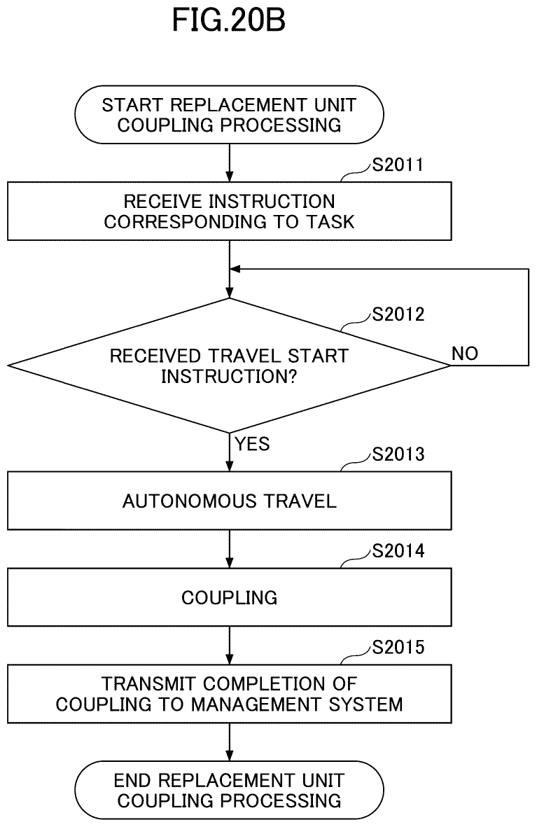

Next, a flow of processing when the replacement unit 411 is separated from the substrate processing system 142_2 and autonomously travels to the preparation space 111 will be described. FIG. 20A is a flowchart illustrating the flow of separation processing of the replacement unit in the independent maintenance mode.

In step S2001, the replacement unit 411 receives an instruction corresponding to the tasks from the management system 440.

In step S2002, the replacement unit 411 determines whether or not the substrate processing system 142_2 has entered the independent maintenance mode. If it is determined in step S2002 that the system has not entered the independent maintenance mode (NO in step S2002), the process waits until the system transitions to the independent maintenance mode. Conversely, if it is determined in step S2002 that the system has entered the independent maintenance mode (YES in step S2002), the process proceeds to step S2003.

In step S2003, the replacement unit 411 determines whether or not a travel start instruction (separation) has been received from the management system 440. If it is determined in step S2003 that the travel start instruction (separation) has not been received (NO in step S2003), the controller waits until the travel start instruction (separation) is received. Conversely, if it is determined in step S2003 that the travel start instruction (separation) has been received (YES in step S2003), the process proceeds to step S2004.

In step S2004, the replacement unit 411 releases the coupling with the mounting portion 1831 to 1834 and separates from the substrate processing system 142_2.

In step S2005, the replacement unit 411 autonomously travels on the vertical transfer rail 452 and the rail 422 and moves to the preparation space 111.

In step S2006, the replacement unit 411 notifies the management system 440 that the separation is completed.

### (4) Coupling Processing of Replacement Unit

Next, a flow of processing until the replacement unit 411 is coupled to the substrate processing system 142_2 will be described. FIG. 20B is a flowchart illustrating the flow of coupling processing of the replacement unit in the independent maintenance mode.

In step S2011, the replacement unit 411 receives an instruction corresponding to the tasks from the management system 440.

In step S2012, the replacement unit 411 determines whether or not a travel start instruction (coupling) has been received from the management system 440. If it is determined in step S2012 that the travel start instruction (coupling) has not been received (NO in step S2012), it waits until the travel start instruction (coupling) has been received. Conversely, if it is determined in step S2012 that the travel start instruction (coupling) has been received (YES in step S2012), the process proceeds to step S2013.

In step S2013, the replacement unit 411 autonomously travels on the rails 422 and the vertical transfer rails 452 and moves from the preparation space 111 to the substrate processing system 142_2.

In step S2014, the replacement unit 411 is coupled to the mounting portion 1831 to 1834 of the substrate processing system 142_2. Thus, the replacement unit 411 is fixed to the substrate processing system 142_2.

In step S2015, the replacement unit 411 notifies the management system 440 that the coupling is completed.

### <Description of Work Robot>

Next, the work robot 412 will be described.

(1) Configuration of Work Robot during Maintenance Work

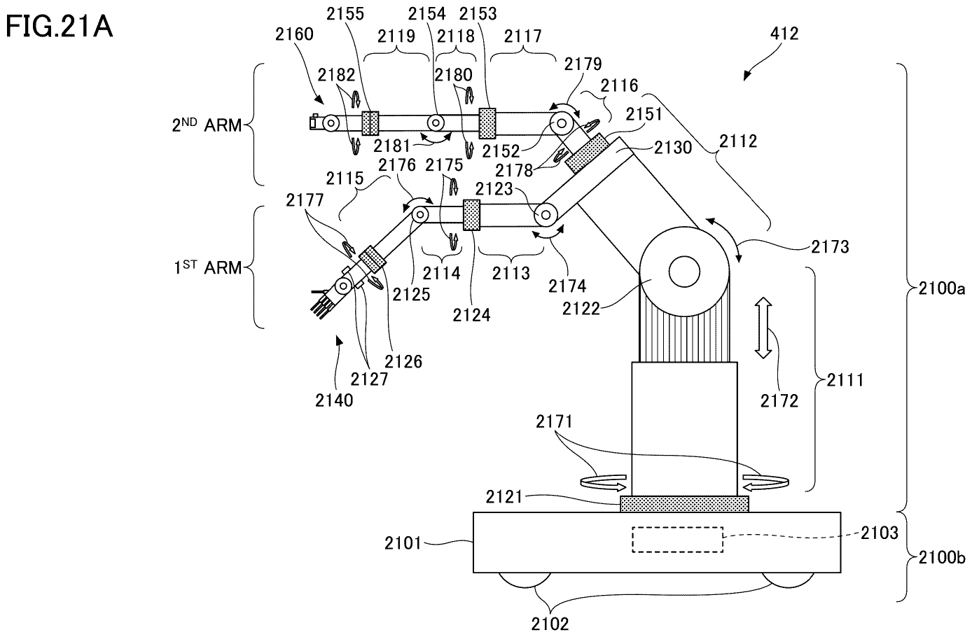

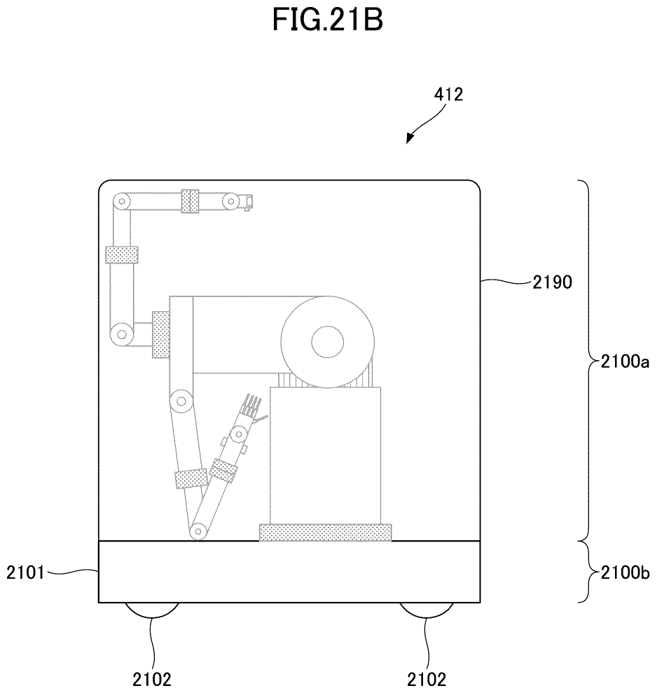

First, a configuration of the work robot 412 during maintenance work will be described. FIG. 21A is a first drawing illustrating details of a work robot. As shown in FIG. 21A, the work robot 412 has a manipulator 2100a and a moving body 2100b.

The moving body 2100b moves the work robot 412 and controls the position and attitude of entirety of the work robot 412. The moving body 2100b has a support pedestal 2101, a moving unit 2102, and a control device 2103.

The support pedestal 2101 is a base for supporting the manipulator 2100a. The moving unit 2102 is controlled based on image data and distance data from an image pickup device and a laser range finder (not shown) attached to the support pedestal 2101. Thus, the moving unit 2102 can move the work robot 412 to an arbitrary position (e.g., the location of substrate processing system 142_2). The control device 2103 controls the operation of the manipulator 2100a and the operation of the moving unit 2102.

The manipulator 2100a mainly performs replacement of consumables and cleaning of the substrate processing systems 141_1 to 142_2 in maintenance work. The manipulator 2100a also performs measurement of work quality after replacement of consumables and cleaning.

As shown in FIG. 21A, the manipulator 2100a has a plurality of links (links 2111 to 2119).

One end of the link 2111 is attached to the moving body 2100b via a rotating unit 2121 rotating in the direction of an arrow 2171. The link 2111 has a vertical transfer mechanism for moving up and down in the direction of an arrow 2172, and one end of the link 2112 is attached to the other end via a rotating unit 2122 rotating in the direction of arrow 2173.

A branch 2130 is formed at the other end of the link 2112, and a first arm for mainly replacing consumables and cleaning and a second arm for measuring work quality after replacing consumables and cleaning are attached to the branch 2130.

In the first arm, one end of the link 2113 is attached to the branch 2130 via a rotating unit 2123 rotating in the direction of arrow 2174, and the other end is attached to the link 2114 via a rotating unit 2124 rotating in the direction of arrow 2175. Further, one end of the link 2115 is attached to the other end of the link 2114 via a rotating unit 2125 rotating in the direction of arrow 2176. Further, an end effector 2140 is attached to the other end of the link 2115 via a rotating unit 2126 rotating in the direction of arrow 2177.

The end effector 2140 has a sensor (e.g., imaging device 2127) for measuring the tip direction of the end effector 2140. Thus, the posture of the first arm is controlled, the operation of the end effector 2140 is controlled, and the consumables are replaced and cleaned.

Although the example of FIG. 21A shows an example in which a five-finger type end effector is attached as the end effector 2140, the type of the end effector 2140 is not limited to this, and an end effector of an appropriate type is replaced according to a work item. Specifically, the work robot 412 selects and replaces an end effector corresponding to a work item from among a plurality of types of end effectors stocked in its own robot. The end effector 2140 is detachably attached at the position of the rotating unit 2126.

In the second arm, one end of the link 2116 is attached to the branch 2130 via a rotating unit 2151 rotating in the direction of an arrow 2178, and the other end is attached to the link 2117 via a rotating unit 2152 rotating in the direction of arrow 2179. Further, one end of the link 2118 is attached to the other end of the link 2117 via a rotating unit 2153 rotating in the direction of the arrow 2180. Further, one end of the link 2119 is attached to the other end of the link 2118 via a rotating unit 2154 rotating in the direction of arrow 2181. Further, a multi-sensor unit 2160 is attached to the other end of the link 2119 via a rotating unit 2155 rotating in the direction of arrow 2182.

The multi-sensor unit 2160 is an example of a measurement part and has various sensors (e.g., imaging apparatus, laser range finder). Thereby, the posture of the second arm is controlled and the work quality of the consumable replacement and cleaning performed by the end effector 2140 is measured.

### (2) Configuration of Work Robot During Traveling

Next, a configuration of the work robot 412 during traveling will be described. FIG. 21B is a second drawing illustrating details of the work robot. As shown in FIG. 21B, the work robot 412 has a storage 2190 for storage the manipulator 2100a. Before travel, the work robot 412 travels with the manipulator 2100a stored in the storage 2190 and the manipulator 2100a stored in the storage 2190.

The storage 2190 is openable and closable, and when the work robot 412 reaches the position of the substrate processing system on which maintenance work is to be performed, the storage 2190 is opened and the manipulator 2100a is operated.

### (3) Functional Configuration of Work Robot

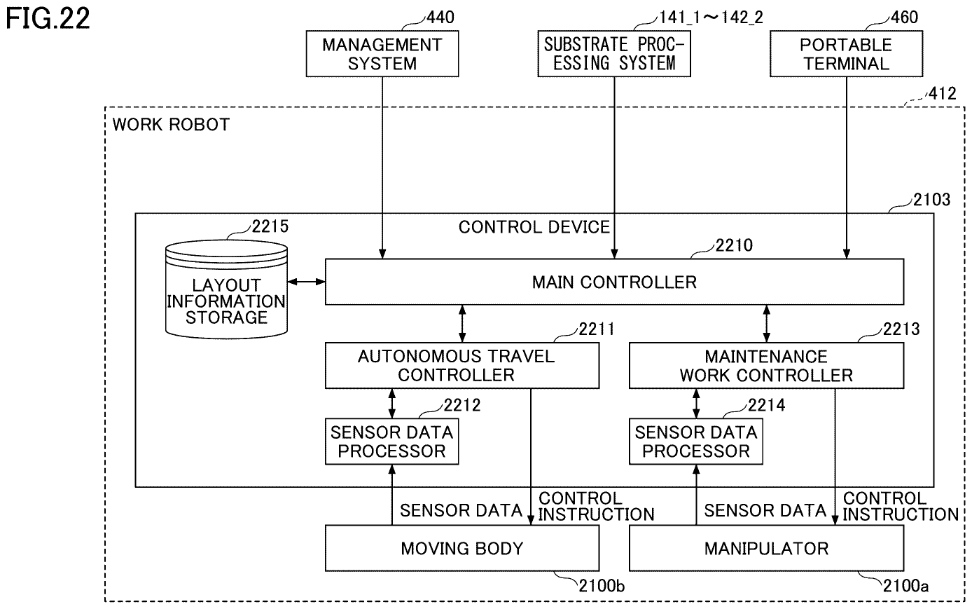

Next, the functional configuration of the control device 2103 of the work robot 412 will be described. FIG. 22 is a drawing illustrating an example of a functional configuration of the work robot. As described above, the work robot 412 has a manipulator 2100a and a moving body 2100b, and the control device 2103 is arranged in the moving body 2100b, but in the example of FIG. 22, it is shown outside the moving body 2100b for convenience of explanation. Therefore, in the example of FIG. 22, the moving body 2100b refers to a moving body excluding the control device 2103.

A control program is installed in the control device 2103. When the control program is executed, the control device 2103 functions as the main controller 2210, the autonomous travel controller 2211, the sensor data processor 2212, the maintenance work controller 2213, and the sensor data processor 2214, as shown in FIG. 22.

The main controller 2210 controls entirety of the work robot 412 while communicating with the management system 440, the substrate processing systems 141_1 to 142_2, and the portable terminal 460.

For example, the main controller 2210 communicates with the substrate processing system on which maintenance work is to be performed to determine whether the maintenance work can be started, and when it is determined that the maintenance work can be started, instructs the maintenance work controller 2213 to start the maintenance work.

The main controller 2210 communicates with the portable terminal 460 and instructs the maintenance work controller 2213 to perform the maintenance work according to the voice instruction when the voice instruction is given by the worker during the maintenance work.

The autonomous travel controller 2211 generates a control instruction for causing the work robot 412 to autonomously travel (or travel along the light emitting unit 433) to the position of the substrate processing system on which maintenance work is to be performed based on:
an instruction according to the task received by the main controller 2210 from the management system 440;
sensor data notified from the sensor data processor 2212; and
layout information of the first substrate processing plant 100 stored in a layout information storage 2215.
   The autonomous travel controller 2211 transmits the generated control instruction to the moving body 2100b.

The autonomous travel controller 2211 transmits completion of autonomous travel to the management system 440 via the main controller 1930.

The sensor data processor 2212 processes the sensor data notified from the sensor of the moving body 2100b to, for example, specify the current position or detect the light emitting unit 433, and notifies the autonomous travel controller 2211. The sensor data processor 2212 processes the sensor data notified from the sensor of the moving body 2100b to, for example, acquire obstacle information and notify the autonomous travel controller 2211. The sensor of the moving body 2100b is, for example, an image pickup device and a laser range finder (not shown) mounted on the support pedestal 2101, and the sensor data notified from the sensor refers to image data, distance data, and the like.

The maintenance work controller 2213 generates control instructions or the like for the work robot 412 to perform maintenance work based on such as:
instructions according to the tasks received by the main controller 2210 from the management system 440; and
information indicating the state of the maintenance work notified from the sensor data processor 2214.
   The maintenance work controller 2213 transmits the generated control instruction or the like to the manipulator 2100a. Further, the maintenance work controller 2213 transmits the completion of the maintenance work and the work history information to the management system 440 via the main controller 1930. The maintenance work controller 2213 generates the work history information on the basis of the generated control instruction for performing maintenance work and the notified sensor data.

The sensor data processor 2214 generates information indicating the maintenance work status of the manipulator 2100a by processing the sensor data notified from the sensor of the manipulator 2100a and notifies the maintenance work controller 2213.

### (4) Moving Processing of Work Robot

Next, the flow of processing until the work robot 412 moves to the position of the substrate processing system 142_2 as a maintenance work object will be described. Processing until the work robot 412 moves to a position of the substrate processing system 142_2 on which maintenance work is to be performed can be mainly classified, in the device space 120, into the following cases:
a case where the work robot 412 travels in accordance with guidance of a light-emitting unit 433; and
a case where the work robot 412 autonomously travels while calculating its current position. Hereinafter, the movement processing of the two cases will be described.
   (4-1) Movement Processing in the Case where Work Robot Travels in Accordance with Guidance of Light Emitting Unit

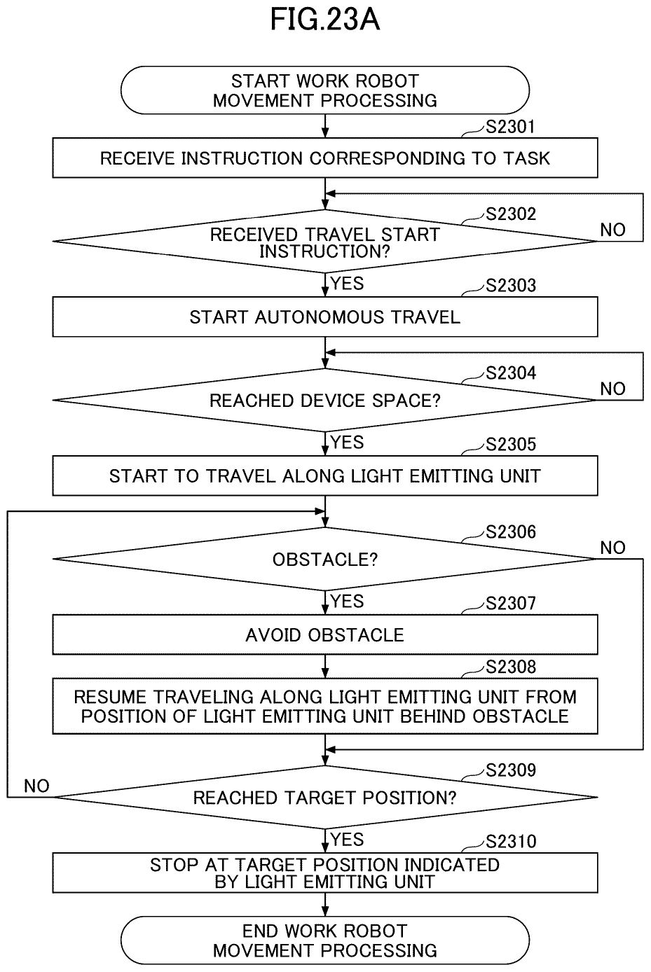

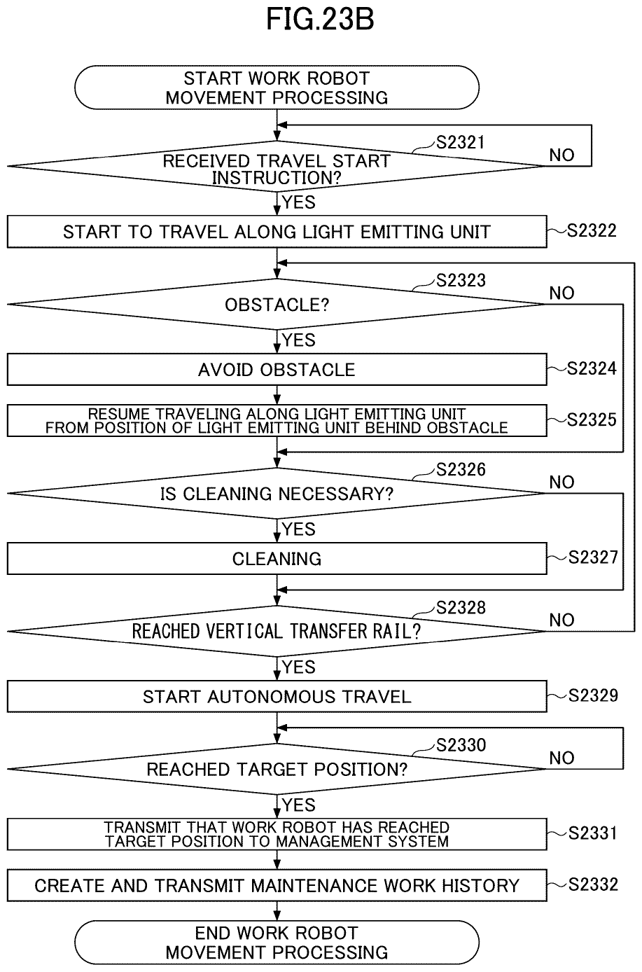

FIG. 23A is a first flowchart illustrating a flow of movement processing of the work robot in the maintenance mode and a first flowchart illustrating a flow of the movement processing in the case where the work robot moves from the preparation space 111 to the substrate processing system 142_2 on which maintenance work is to be performed.

In step S2301, the work robot 412 receives an instruction corresponding to the tasks from the management system 440.

In step S2302, the work robot 412 determines whether or not the travel start instruction (outward path) has been received from the management system 440. In step S2302, if it is determined that the travel start instruction (outward path) has not been received (NO in step S2302), the robot waits until the travel start instruction (outward path) is received. Conversely, in step S2302, if it is determined that the travel start instruction (outward path) has been received (YES in step S2302), the process proceeds to step S2303.

In step S2303, the work robot 412 autonomously travels on the rail 422 in the travel space 110 and moves to the device space 120 via the vertical transfer rail 452.

In step S2304, it is determined whether or not the work robot 412 has reached the device space 120. If it is determined in step S2304 that the device space 120 has not been reached (NO in step S2304), the autonomous travel is continued. Conversely, if it is determined in step S2304 that the device space 120 has been reached (YES in step S2304), the process proceeds to step S2305.

In step S2305, the work robot 412 detects the light emitting unit 310 which is the light emitting unit 310 installed on the floor of the device space 120 and is turned on. Further, the work robot 412 starts to travel along the light emitting unit 310 which is turned on.

In step S2306, the work robot 412 determines whether or not an obstacle is placed on the travel path. If it is determined in step S2306 that no obstacle is placed (NO in step S2306), the travel continues and the process proceeds to step S2309.

Conversely, if it is determined in step S2306 that an obstacle is placed (YES in step S2306), the process proceeds to step S2307.

In step S2307, the work robot 412 travels so as to avoid the obstacle.

In step S2308, the work robot 412 detects the light emitting unit 310 which is turned on at the position behind the avoided obstacle. Further, the work robot 412 resumes traveling along the light emitting unit 310 which is turned on.

In step S2309, the work robot 412 determines whether or not the target position has been reached. If it is determined in step S2309 that the target position has not been reached (NO in step S2309), the process returns to step S2306 to continue traveling along the light emitting unit 310. Conversely, if it is determined in step S2309 that the target position has been reached (YES in step S2309), the process proceeds to step S2310.

It should be noted that the work robot 412 determines that the target position has been reached when it detects the position of the end point of the light emitting unit 310 that is turned on. The position of the end point of the light emitting unit 310 that is turned on corresponds to the position of the substrate processing system 142_2 on which maintenance work is to be performed. However, if the substrate processing system 142_2 on which maintenance work is to be performed is included in the work area of the worker 482, the position of the end point of the light emitting unit 310 that is turned on is located in front of the work area.

In step S2310, the work robot 412 stops traveling at the target position indicated by the light emitting unit 310. Further, the work robot 412 transmits the completion of traveling to the management system 440.

FIG. 23B is a second flowchart illustrating a flow of the movement processing of the work robot in the maintenance mode and a flowchart illustrating the flow of the moving processing when returning from the substrate processing system 142_2 on which maintenance work is to be performed, to the preparation space 111.

In step S2321, the work robot 412 determines whether or not a traveling start instruction (inward path) has been received from the management system 440. If it is determined in step S2321 that the traveling start instruction (inward path) has not been received (NO in step S2321), the process waits until the traveling start instruction (inward path) is received. Conversely, if it is determined in step S2321 that the traveling start instruction (inward path) has been received (YES in step S2321), the process proceeds to step S2322.

In step S2322, the work robot 412 detects the light emitting unit 310 which is the light emitting unit 310 installed on the floor of the device space 120 and is turned on. Further, the work robot 412 starts traveling along the light emitting unit 310 which is turned on.

In step S2323, the work robot 412 determines whether or not an obstacle is placed on the travel path. If it is determined in step S2323 that no obstacle is placed (NO in step S2323), the travel continues and the process proceeds to step S2326.

Conversely, if it is determined in step S2323 that an obstacle is placed (YES in step S2323), the process proceeds to step S2324.

In step S2324, the work robot 412 travels so as to avoid the obstacle.

In step S2325, the work robot 412 detects the light emitting unit 310 which is turned on at the position behind the avoided obstacle. Further, the work robot 412 resumes traveling along the light emitting unit 310 which is turned on.

In step S2326, the work robot 412 determines whether cleaning on or around the travel path is necessary. If it is determined in step S2326 that cleaning is unnecessary (NO in step S2326), the process proceeds to step S2328.

Conversely, if it is determined in step S2327 that cleaning is necessary (YES in step S2326), the process proceeds to step S2327.

In step S2327, the work robot 412 moves while cleaning on or around the travel path while traveling in accordance with the guidance of the light emitting unit 310. As described above, the work robot 412 cleans when traveling in the device space 120 on the way back to the preparation space 111 after the completion of the maintenance work, and removes dust and dirt caused by the maintenance work.

In step S2328, the work robot 412 determines whether or not it has reached the position of the vertical transfer rail 452. If it is determined in step S2328 that it has not reached the position of the vertical transfer rail 452 (NO in step S2329), the process returns to step S2323. Conversely, if it is determined in step S2328 that it has reached the position of the vertical transfer rail 452 (YES in step S2328), the process proceeds to step S2329.

In step S2329, the work robot 412 moves to the travel space 110 via the vertical transfer rail 452 and then moves to the preparation space 111 by autonomously traveling on the rail 422 in the travel space 110.

In step S2330, the work robot 412 determines whether or not it has reached the preparation space 111. If it is determined in step S2330 that it has not reached the preparation space 111 (NO in step S2330), the autonomous traveling is continued.

Conversely, if it is determined in step S2330 that the work robot has reached the preparation space 111 (YES in step S2330), the process proceeds to step S2331.

In step S2331, the work robot 412 transmits to the management system 440 that the maintenance work is completed.

(4-2) The Case of Traveling while Calculating Current Position

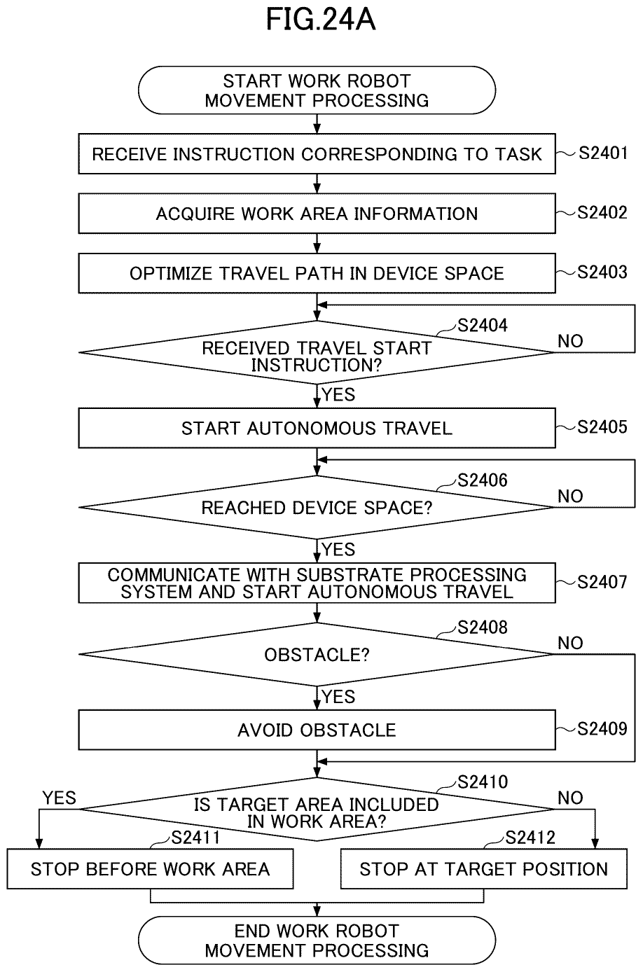

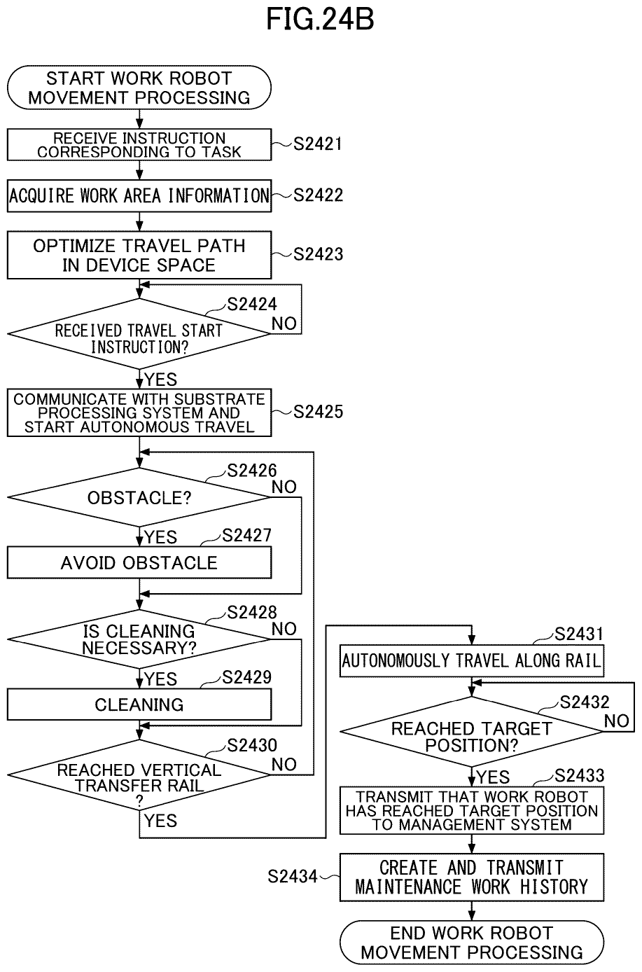

FIG. 24A is a third flowchart illustrating a flow of the movement processing of the work robot in the maintenance mode and a flowchart showing the flow of the movement processing when the work robot moves from the preparation space 111 to the substrate processing system 142_2 on which maintenance work is to be performed.

In step S2401, the work robot 412 receives an instruction corresponding to the task from the management system 440.

In step S2402, the work robot 412 acquires information about the work area of the worker 482 from the instruction corresponding to the task. The instruction corresponding to the task received by the work robot 412 in step S2401 includes a travel path (outward path) to the substrate processing system 142_2 of the maintenance work object. The travel path (outward path) also includes information about the work area of the worker 482 as an incidental state.

In step S2403, the work robot 412 optimizes the travel path in the device space 120. More specifically, as a travel path from the position descending to the device space 120 via the vertical transfer rail 452 to the position of the substrate processing system on which maintenance work is to be performed, a path that takes the shortest time while avoiding the work area of the worker 482 is searched. When searching for the travel path, it is assumed that a plurality of travel path candidates are transmitted from the management system 440 in advance, and the work robot 412 selects one of the path candidates. Further, the travel time for each past travel path recorded in the past travel history is referred to as the required time.

In step S2404, the work robot 412 determines whether or not a travel start instruction (outward path) has been received from the management system 440. If it is determined in step S2404 that the travel start instruction (outward path) has not been received (NO in step S2404), the controller waits until the travel start instruction (outward path) is received. Conversely, if it is determined in step S2404 that the travel start instruction (outward path) has been received (YES in step S2404), the process proceeds to step S2405.

In step S2405, the work robot 412 autonomously travels on the rail 422 in the travel space 110 and moves to the device space 120 via the vertical transfer rail 452.

In step S2406, the work robot 412 determines whether or not the device space 120 has been reached. If it is determined in step S2406 that the device space 120 has not been reached (NO in step S2406), the autonomous travel is continued. Conversely, if it is determined in step S2406 that the device space 120 has been reached (YES in step S2406), the process proceeds to step S2407.

In step S2407, the work robot 412 calculates the current position based on a signal from a transmitter 435 of a nearby substrate processing system or by capturing images of a marker 434 on the ceiling of the device space 120. Based on the calculated current position, the work robot 412 starts the autonomous travel according to the travel path (the travel path optimized in step S2403) to the position of the substrate processing system 142_2 on which maintenance work is to be performed.

In step S2408, the work robot 412 determines whether or not an obstacle is placed on the travel path. If it is determined in step S2408 that no obstacle is placed (NO in step S2408), the autonomous driving is continued, and the process proceeds to step S2410.

Conversely, if it is determined in step S2408 that an obstacle is placed (YES in step S2408), the process proceeds to step S2409.

In step S2409, the work robot 412 autonomously travels so as to avoid the obstacle. Incidentally, after avoiding the obstacle, the work robot 412 again resumes the autonomous travel according to the travel path to the position of the substrate processing system 142_2 on which maintenance work is to be performed while calculating the current position.

In step S2410, the work robot 412 determines whether or not the periphery of the substrate processing system 142_2 on which maintenance work is to be performed is included in the work area of the worker 482. If it is determined in step S2410 that the robot is included in the work area of the worker 482 (YES in step S2410), the process proceeds to step S2411.

In step S2411, the work robot 412 stops before the work area regardless of the position of the substrate processing system 142_2 on which maintenance work is to be performed and transmits to the management system 440 that the autonomous travel is completed.

Conversely, if it is determined in step S2411 that the robot is not included in the work area of the worker 482 (NO in step S2411), the process proceeds to step S2412.

In step S2412, the work robot 412 continues the autonomous travel up to the position of the substrate processing system 142_2 on which maintenance work is to be performed moves to the position of the substrate processing system 142_2 on which maintenance work is to be performed and then stops. The work robot 412 also transmits to the management system 440 that the autonomous travel is completed.

FIG. 24B is a fourth flowchart illustrating a flow of the movement processing of the work robot in the maintenance mode and a flowchart showing the flow of the movement processing when returning from the substrate processing system 142_2 on which maintenance work is to be performed to the preparation space 111.

In step S2421, the work robot 412 receives an instruction corresponding to the tasks from the management system 440.

In step S2422, the work robot 412 acquires information about the work area of the worker 482 from the instruction corresponding to the tasks. The information about the work area of the worker 482 at this time is information about the work area where the work by the worker 482 is still being performed at the time when the maintenance work by the work robot 412 is completed. Note that the instruction corresponding to the tasks received by the work robot 412 in step S2421 includes a travel path (inward path) to the substrate processing system 142_2, which is the object of the maintenance work. The travel path (inward path) also includes information about the work area of the worker 482 as an incidental state.

In step S2423, the work robot 412 optimizes the travel path in the device space 120. More specifically, as a travel path from the position of the substrate processing system 142_2 where the maintenance work has been completed to the position of the vertical transfer rail 452, a path with the shortest required time is searched while avoiding the work area of the worker 482.

In step S2424, the work robot 412 determines whether or not a travel start instruction (inward path) has been received from the management system 440. If it is determined in step S2424 that the travel start instruction (inward path) has not been received (NO in step S2424), it waits until the travel start instruction (inward path) is received. Conversely, if it is determined in step S2424 that the travel start instruction (inward path) has been received (YES in step S2424), the process proceeds to step S2425.

In step S2425, the work robot 412 calculates the current position based on a signal from the transmitter 435 of the nearby substrate processing system or by capturing images of a marker 434 on the ceiling of the device space 120. Based on the calculated current position, the work robot 412 starts autonomous travel along the travel path to the position of the vertical transfer rail 452 (the optimized travel path in step S2423).

In step S2426, the work robot 412 determines whether or not an obstacle is placed on the travel path. If it is determined in step S2426 that no obstacle is placed (NO in step S2426), the robot continues autonomous travel and proceeds to step S2428.

Conversely, if it is determined in step S2426 that the obstacle is placed (YES in step S2426), the process proceeds to step S2427.

In step S2427, the work robot 412 autonomously travels to avoid the obstacle. After avoiding the obstacle, the work robot 412 again resumes the autonomous travel to the position of the vertical transfer rail 452 while calculating the current position.

In step S2428, the work robot 412 determines whether cleaning on or around the travel path is necessary. If it is determined in step S2428 that cleaning is unnecessary (NO in step S2428), the process proceeds to step S2430.

Conversely, if it is determined in step S2428 that cleaning is necessary (YES in step S2428), the process proceeds to step S2429.

In step S2429, the work robot 412 moves while cleaning on or around the travel path while autonomously traveling according to the optimized travel path. Thus, the work robot 412 performs cleaning when traveling in the device space 120 on the way back to the preparation space 111 after the completion of the maintenance work, and removes dust and dirt caused by the maintenance work.

In step S2430, the work robot 412 determines whether or not it has reached the position of the vertical transfer rail 452. If it is determined in step S2430 that it has not reached the position of the vertical transfer rail 452 (NO in step S2430), the process returns to step S2426. Conversely, if it is determined in step S2430 that it has reached the position of the vertical transfer rail 452 (YES in step S2430), the process proceeds to step S2431.

In step S2431, the work robot 412 moves to the travel space 110 via the vertical transfer rail 452, and then moves to the preparation space 111 by autonomously traveling on the rail 422 in the travel space 110.

In step S2432, the work robot 412 determines whether or not the preparation space 111 has been reached. If it is determined in step S2432 that the preparation space 111 has not been reached (NO in step S2432), the autonomous travel is continued.

Conversely, if it is determined in step S2432 that the preparation space 111 has been reached (YES in step S2432), the process proceeds to step S2433.

In step S2433, the work robot 412 transmits to the management system 440 that the maintenance work has been completed.

### (5) Maintenance Work Processing of Work Robot

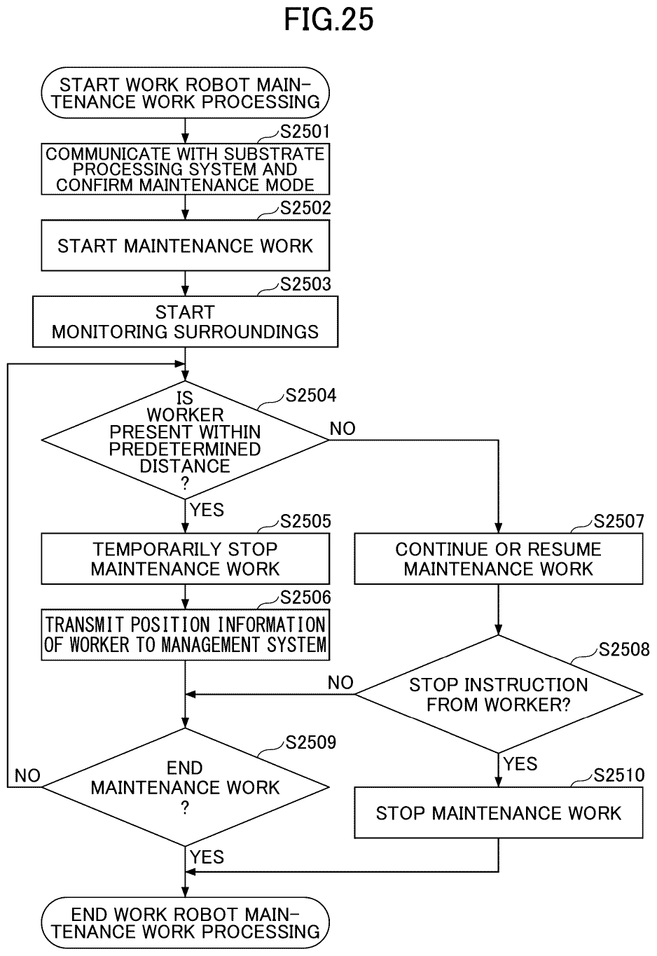

Next, a flow of a case where the work robot 412 performs maintenance work processing on the substrate processing system 142_2 on which maintenance work is to be performed will be described. FIG. 25 is a flowchart illustrating a flow of maintenance work processing of the work robot in the maintenance mode.

In step S2501, the work robot 412 communicates with the substrate processing system 142_2 of the maintenance work object and confirms that the substrate processing system 142_2 of the maintenance work object has entered the maintenance mode.

In step S2502, the work robot 412 starts the maintenance work.

In step S2503, the work robot 412 starts monitoring its surroundings.

In step S2504, the work robot 412 determines whether or not the worker 482 is present within a predetermined distance from its own robot. If it is determined in step S2504 that the worker 482 is present (in a case of YES in step S2504), the process proceeds to step S2505.

In step S2505, the work robot 412 temporarily stops the maintenance work. Alternatively, the work robot 412 decelerates the work speed of the maintenance work.

In step S2506, the work robot 412 transmits the position information of the worker 482 within a predetermined distance from itself to the management system 440.

Conversely, if it is determined in step S2504 that the worker 482 is not present (NO in step S2504) and the maintenance work is being executed, the maintenance work is continued. If it is determined that the worker 482 is absent (NO in step S2504) and the maintenance work has been temporarily stopped or the operation speed has been reduced, the normal maintenance work is resumed.

In step S2508, the work robot 412 determines whether or not a voice instruction has been received from the worker 482 via the portable terminal 460.

If it is determined in step S2508 that the voice instruction has not been received (NO in step S2508), the process proceeds to step S2509. Conversely, if it is determined in step S2508 that the voice instruction has been received (YES in step S2508), the process proceeds to step S2510.

In step S2509, the work robot 412 determines whether or not to end the maintenance work. If it is determined in step S2509 that the maintenance work is not yet ended (NO in step S2509), the process returns to step S2504.

Conversely, if it is determined in step S2509 that the maintenance work has been ended (YES in step S2509), the maintenance work processing is ended, and the completion of the maintenance work is transmitted to the management system 440.

In step S2510, the work robot 412 stops the maintenance work and ends the maintenance work processing.

### <Description of Inspection Robot>

Next, the configuration of the inspection robot 414 will be described. The inspection robot 414 has a configuration similar to that of the moving body 2100b of the work robot 412 (see FIG. 21A), and a sensor for inspecting the rail 422 is attached to the moving body 2100b.

### (1) Functional Configuration of Inspection Robot

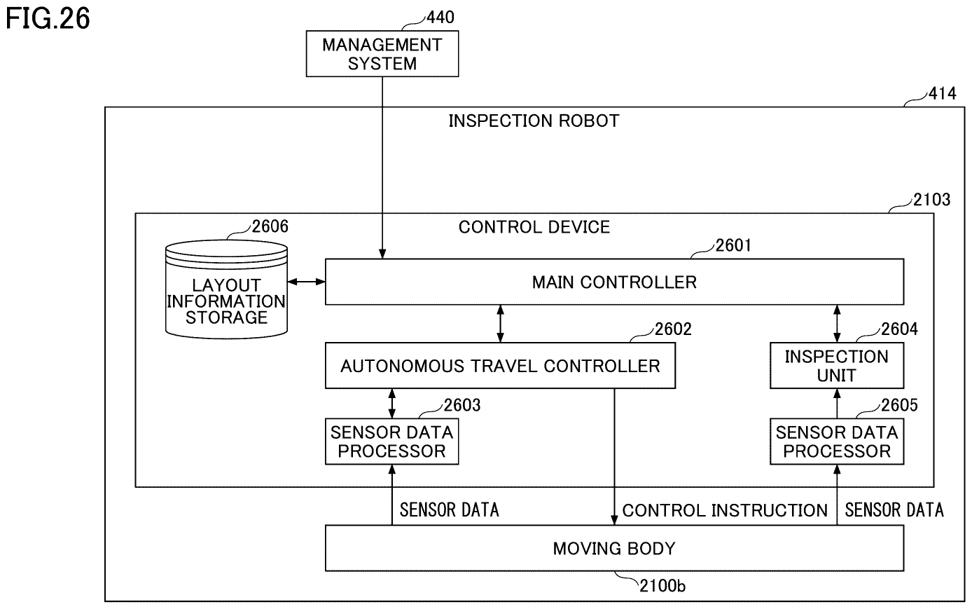

First, as a functional configuration of the inspection robot 414, a functional configuration of the control device 2103 of the inspection robot 414 will be described. FIG. 26 is a drawing illustrating an example of a functional configuration of an inspection robot. It should be noted that, like the work robot 412, the control device 2103 is arranged inside the moving body 2100b, but in the example of FIG. 26, it is shown outside the moving body 2100b for convenience of explanation. Therefore, the moving body 2100b shown in FIG. 26 refers to a moving body excluding the control device 2103.

A control program is installed in the control device 2103. When the control program is executed, the control device 2103 functions as a main controller 2601, an autonomous travel controller 2602, a sensor data processor 2603, an inspection unit 2604, and a sensor data processor 2605, as shown in FIG. 26.

The main controller 2601 controls entirety of the inspection robot 414 while communicating with the management system 440.

The autonomous travel controller 2602 generates a control instruction for causing the inspection robot 414 to autonomously travel on the rail 422 on which inspection work is to be performed based on:
the main controller 2601 receives an instruction according to the task from the management system 440;
sensor data notified from the sensor data processor 2603; and
layout information of the first substrate processing plant 100 stored in a layout information storage 2606.
   The autonomous travel controller 2602 transmits the generated control instruction to the moving body 2100b.

The sensor data processor 2603 processes the sensor data notified from the sensor of the moving body 2100b to, for example, specify the current position and notify the autonomous travel controller 2602 thereof. Here, the sensor of the moving body 2100b is, for example, an imaging apparatus and a laser range finder (not shown) mounted on the support pedestal 2101, and the sensor data notified from the sensor refers to image data, distance data, and the like.

The inspection unit 2604 determines whether or not a defect occurs in the rail 422 based on the sensor data notified from the sensor data processor 2605 and transmits the inspection result including the presence or absence of the defect to the management system 440 via the main controller 2601.

The sensor data processor 2605 processes the sensor data notified from the sensor of the moving body 2100b to detect a defect in the rail 422 and notify the inspection unit 2604 thereof. Here, the sensor of the moving body 2100b is, for example, an imaging apparatus mounted on the support pedestal 2101 for capturing images of the rail during travel, and the sensor data notified from the sensor refers to image data, and the like.

### (2) Inspection Processing of Inspection Robot

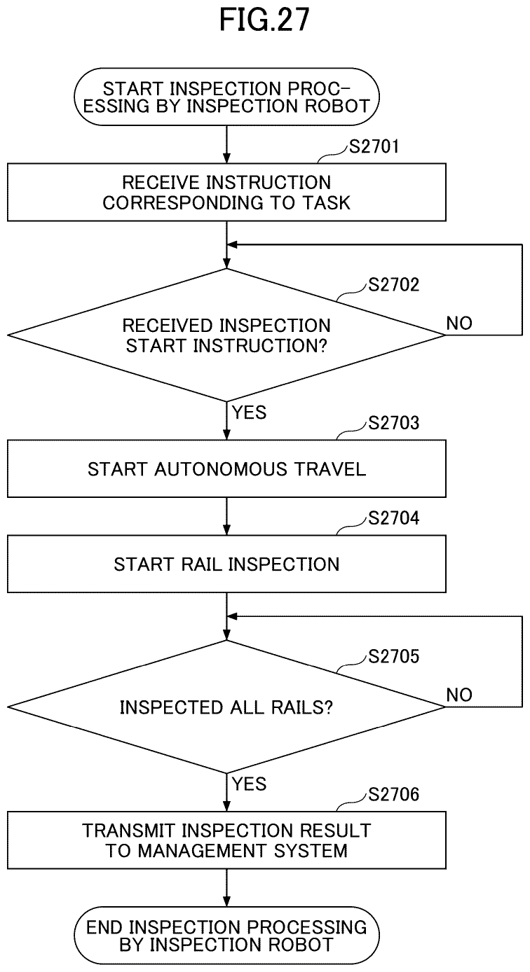

Next, a flow of processing in which the inspection robot 414 inspects the rail 422 in the travel space 110 will be described. FIG. 27 is a flowchart illustrating a flow of inspection processing of the inspection robot in the normal mode.

In step S2701, the inspection robot 414 receives an instruction corresponding to the tasks from the management system 440.

In step S2702, the inspection robot 414 determines whether or not an inspection start instruction has been received from the management system 440. If it is determined in step S2702 that no inspection start instruction has been received (NO in step S2702), the inspection robot waits until an inspection start instruction is received. Conversely, if it is determined in step S2702 that an inspection start instruction has been received (YES in step S2702), the process proceeds to step S2703.

In step S2703, the inspection robot 414 moves to the position of the rail on which inspection work is to be performed among the rails 422 in the travel space 110 and starts the autonomous traveling.

In step S2704, the inspection robot 414 starts the inspection of the rail on which inspection work is to be performed.

In step S2705, the inspection robot 414 determines whether or not all the rails on which inspection work is to be performed have been inspected. In step S2705, if it is determined that there is a rail not inspected (NO in step S2705), the autonomous traveling and inspection are continued. Conversely, in step S2705, if it is determined that all the rails have been inspected (YES in step S2705), the process proceeds to step S2706.

In step S2706, the inspection robot 414 transmits the inspection result to the management system 440.

### <Hardware Configuration of Control Devices>

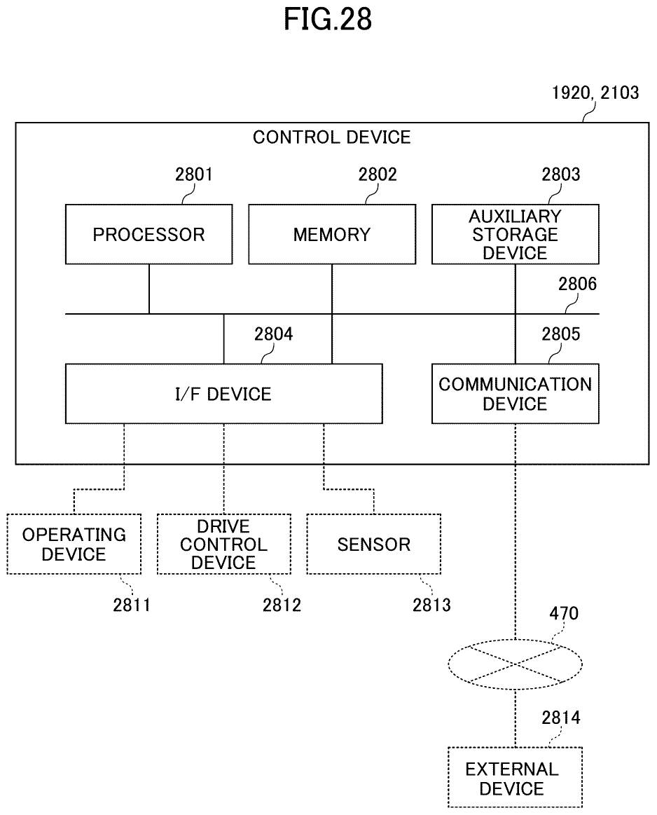

Next, hardware configurations of the control device 1920 included in the replacement unit 411 and the control devices 2103 included in the work robot 412 and the inspection robot 414 will be described. Since these control devices have similar hardware configurations, they will be described collectively with reference to FIG. 28.

FIG. 28 is a drawing illustrating an example of a hardware configuration of a control device. As shown in FIG. 28, the control devices 1920 and 2103 include a processor 2801, a memory 2802, an auxiliary storage device 2803, an I/F (interface) device 2804, and a communication device 2805. The hardware included in the control devices 1920 and 2103 is connected to each other via a bus 2806.

The processor 2801 includes various computing devices such as a CPU (Central Processing Unit) and a GPU (Graphics Processing Unit). The processor 2801 reads various programs (e.g., a control program) from the memory 2802 and executes them.

The memory 2802 has a main storage device such as ROM (Read Only Memory) and RAM (Random Access Memory). The processor 2801 and the memory 2802 form what is called a computer, and the computer achieves various functions by executing various programs read from the memory 2802 by the processor 2801.

The auxiliary storage device 2803 stores various programs and various information used when the various programs are executed by the processor 2801.

The I/F device 2804 is a connection device for connecting to an external device (e.g., operating device 2811, drive control device 2812, sensor 2813). The I/F device 2804 receives operations on the replacement unit 411, the work robot 412, and the inspection robot 414 via the operating device 2811. Here, the operating device 2811 includes a power ON and OFF operation switch and an emergency stop operation switch of the replacement unit 411, the work robot 412, and the inspection robot 414.

The I/F device 2804 outputs control instructions from the control devices 1920 and 2103 to the drive control device 2812. The drive control device 2812 includes a device for controlling the operation of the replacement unit 411, the work robot 412, and the inspection robot 414 based on a control instruction in the movement processing of the inspection robot, the maintenance work processing of the work robot 412, and the like.

Further, the I/F device 2804 receives sensor data from the sensor 2813. Here, the sensor 2813 includes any sensors of the replacement unit 411, the work robot 412, and the inspection robot 414.

The communication device 2805 is a communication device for communicating with an external device 2814 (e.g., management system 440) via the network 470.

Various programs installed in the auxiliary storage device 2803 are installed, for example, by being downloaded from the network 470 via the communication device 2805.

### <Summary>

As is clear from the above description, the maintenance work system 400 according to the first embodiment has the following features:
the maintenance work system 400 is applied to a substrate processing plant in which the travel space 110 for the work body 410 and the device space 120, in which the substrate processing system is installed and the worker 482 performs work, are formed as separate spaces, thereby reducing opportunities for contact between the traveling work body 410 and the worker 482;
the maintenance work system 400 includes replacement units 411 and autonomously replaces the replacement units 411 on a unit-by-unit basis, thereby reducing opportunities for contact between the replacement units 411 and the worker 482 in the device space 120; and
the maintenance work system 400 includes a function of preventing the work robot 412 from entering a work area of the worker 482 when the work robot 412 travels in the device space 120, and further includes a function of alerting or temporarily stopping maintenance work when the worker 482 approaches the work robot 412 during the maintenance work in the device space 120, as well as a function of stopping the maintenance work in response to a voice instruction from the worker 482, thereby reducing opportunities for contact between the work robot 412 and the worker 482 in the device space 120 and ensuring safety of the worker 482.

As described above, according to the maintenance work system 400 according to the first embodiment, it is possible to improve the safety of the worker 482 during the maintenance work by the work body 410.

### Second Embodiment

In the first embodiment described above, it is assumed that the replacement unit 411 autonomously separates and connects. However, the separation of the replacement unit 411 from the substrate processing system 142_2 and the coupling to the substrate processing system 142_2 may be performed with the assistance of the work robot 412.

For example, the work robot 412 may assist the separation of the replacement unit 411 or the coupling of the replacement unit 411 in the substrate processing system on which maintenance work is to be performed.

Further, although the timing of inspection of the rail 422 by the inspection robot 414 is not mentioned in the first embodiment described above, the inspection may be performed at any timing in the normal mode. Alternatively, it may be performed periodically at a predetermined date and time such as once a day, once a week, once a month, and the like.

Further, in the first embodiment, the details of the method of sending an alert to the portable terminal 460 of the worker 482 when the work robot 412 detects the presence of the worker 482 in the work area during the maintenance work of the work robot 412 are not mentioned. However, the method of sending an alert to the portable terminal 460 of the worker 482 is optional.

For example, the management system 440 acquires the position information of each worker by a position detection function and a position information transmission function mounted on the portable terminal 460 carried by each worker. The management system 440 may specify the worker 482 detected by the work robot 412 from the position information of the work robot 412 and send an alert to the portable terminal 460 of the specified worker 482.

Alternatively, the worker 482 is specified from the image data taken by the image pickup device provided in the work robot 412 and the specified worker 482 is notified to the management system 440. The management system 440 may send an alert to the portable terminal 460 of the specified worker 482.

In the first embodiment described above, when an obstacle or the like is detected while the work robot 412 is traveling in the device space 120, the work robot 412 travels avoiding the obstacle or the like. However, the processing of the work robot 412 when the obstacle or the like is detected is not limited to this. For example, when the obstacle or the like is a person, the travel may be stopped.

In the first embodiment described above, when the work robot 412 accesses the substrate processing system, the substrate processing system is in an atmospheric state. However, the work robot 412 may be accommodated in a storage so that the work robot 412 can access the substrate processing system even when the substrate processing system is in a vacuum state.

In the first embodiment described above, each work body 410 has been described as being provided as a single unit; however, each work body 410 may be provided in a plurality of units. For example, when a unit replacement work is performed instead of performing maintenance work inside the substrate processing system, the replacement work may be performed by cooperative control of the plural work bodies.

Further, the present invention is not limited to these embodiments, and various variations and modifications may be made without departing from the scope of the present invention.

According to the present disclosure, it is possible to improve the safety of the worker during maintenance work by the robot.

What is claimed is

1. A maintenance work system for a substrate processing plant including a device space in which a substrate processing system is installed, and a travel space in which a work body involved in maintenance work on the substrate processing system travels, the travel space being located above or below the device space, the maintenance work system comprising:
the work body; and
a vertical transfer mechanism configured to move the work body up or down between the travel space and the device space, the work body having travelled to a position above and horizontally proximate to the substrate processing system on which the maintenance work is to be performed or a position below and horizontally proximate to the substrate processing system on which the maintenance work is to be performed.

2. The maintenance work system according to claim 1, wherein:
the work body includes a replacement unit configured to replace a constituent unit of the substrate processing system; and
the replacement unit has a function of autonomously traveling in the travel space and is configured to be coupled with the substrate processing system at a position where the unit which is the constituent of the substrate processing system has been removed.

3. The maintenance work system according to claim 2, wherein:
the work body includes a work robot;
the work robot has a function of autonomously traveling in the travel space and is moved up or down by the vertical transfer mechanism to perform the maintenance work on the substrate processing system installed in the device space by being moved up or down by the vertical transfer mechanism; or
the work robot is configured to assist the replacement unit moved up or down by the vertical transfer mechanism to be coupled with the substrate processing system at the position where the constituent unit has been removed.

4. The maintenance work system according to claim 3, wherein:
the work robot is configured to generate the replacement unit by performing maintenance work on a unit removed from the substrate processing system; and
the substrate processing plant includes a preparation space used by the work robot to generate the replacement unit.

5. The maintenance work system according to claim 3, further comprising a travel mechanism installed in the travel space and configured to enable the work body to autonomously travel to the position above and horizontally proximate to the substrate processing system on which the maintenance work is to be performed or the position below and horizontally proximate to the substrate processing system on which the maintenance work is to be performed.

6. The maintenance work system according to claim 5, wherein:
the substrate processing plant is provided with a management system configured to output one or more instructions related to the maintenance work based on information from the substrate processing system and information from the work body; and
processing at the substrate processing system and operations of the work body, the travel mechanism, and the vertical transfer mechanism are controlled based on the one or more instructions from the management system.

7. The maintenance work system according to claim 5, wherein:
the travel mechanism includes:
a rail; and
a changing mechanism configured to change a position of the rail in accordance with a position of the vertical transfer mechanism; and
the work body is configured to autonomously travel on the rail in the travel space.

8. The maintenance work system according to claim 2, further comprising a crane mechanism installed in the device space and configured to convey the replacement unit to the position above and horizontally proximate to the substrate processing system on which the maintenance work is to be performed,
wherein the replacement unit is configured to be coupled with the substrate processing system at the position where the constituent unit has been removed by being moved up or down by the crane mechanism.

9. The maintenance work system according to claim 6, wherein the work robot is configured to travel in the travel space or the device space according to a path instructed by the management system.

10. The maintenance work system according to claim 6, wherein, after being moved up or down, the work robot is configured to:
monitor presence of a worker around the work robot; and
when detecting the presence of the worker, notify the management system, the management system being capable of alerting the worker.

11. The maintenance work system according to claim 10, wherein when detecting the presence of the worker, the work robot is configured to:
stop traveling;
reduce a work speed of the maintenance work;
stop the maintenance work; or
warn the worker.

12. The maintenance work system according to claim 9, wherein:
a marker is installed on a ceiling or a floor of the device space; and
the work robot is configured to calculate a position within the device space by capturing an image of the marker.

13. The maintenance work system according to claim 9, wherein the work robot is configured to calculate a position within the device space by communicating with the substrate processing system.

14. The maintenance work system according to claim 9, wherein when traveling in the device space, the work robot is configured to select a path based on past movement times and paths recorded in a movement history.

15. The maintenance work system according to claim 6, wherein the substrate processing system is configured to transition into a maintenance mode triggered by:
an inquiry from the management system; or
a request from the substrate processing system.

16. The maintenance work system according to claim 15, wherein the work body is configured to:
communicate with the substrate processing system;
determine whether a transition into the maintenance mode is completed; and
start the maintenance work when the transition into the maintenance mode is determined to be completed.

17. The maintenance work system according to claim 6, wherein the substrate processing system is configured to receive, from the management system, a determination result as to whether replacement is necessary in response to transmission of information concerning a degree of wear of one or more components.

18. The maintenance work system according to claim 17, wherein the substrate processing system is configured to receive a determination result regarding a unit of the replacement unit from the management system in response to transmission of information concerning one or more components that needs to be replaced.

19. The maintenance work system according to claim 15, wherein the substrate processing system is configured to:
manage inventory of one or more components used for the maintenance work; and
order the one or more components based on a maintenance schedule.

20. The maintenance work system according to claim 6, further comprising a terminal configured to:
be carried by an apparatus administrator who administers the substrate processing system; and
communicate with the substrate processing system.
